(19) United States
(12) Patent Application Publication
(10) Pub. No.: US 2016/0351569 A1
(43) Pub. Date: Dec. 1, 2016

(54) SEMICONDUCTOR DEVICE AND METHOD FOR MANUFACTURING THE SAME

(71) Applicant: Samsung Electronics Co., Ltd., Suwon-si (KR)

(72) Inventors: Jae-yeol SONG, Seoul (KR); Moon-kyu PARK, Hwaseong-si (KR); Sang-jin HYUN, Suwon-si (KR); Hu-yong LEE, Seoul (KR); Hoon-joo NA, Hwaseong-si (KR); Hye-lan LEE, Hwaseong-si (KR)

(21) Appl. No.: 15/164,396

(22) Filed: May 25, 2016

(30) Foreign Application Priority Data
May 28, 2015 (KR) 10-2015-0075370

(51) Int. Cl. H01L 27/092; H01L 29/161; H01L 29/16; H01L 21/8238; H01L 29/78; H01L 29/49; H01L 27/11; H01L 29/08; H01L 29/165

(52) U.S. Cl. CPC H01L 27/0922; H01L 27/0924; H01L 29/0847; H01L 29/161; H01L 29/1608; H01L 29/165; H01L 29/7848; H01L 29/4966; H01L 27/1104; H01L 27/1116; H01L 21/823821; H01L 21/823814; H01L 21/823842

(57) ABSTRACT

Provided are a semiconductor device in which a multi-threshold voltage is embodied by controlling a work function, and a method of manufacturing the same. The device includes a semiconductor substrate including a first region and a second region, a first active region formed in an upper portion of the first region of the semiconductor substrate, a second active region formed in an upper portion of the second region of the semiconductor substrate, a first gate structure formed on the semiconductor substrate across the first active region, the first gate structure including an interfacial layer, a high-k dielectric layer, a capping metal layer, and a work function metal layer that are stacked sequentially, and a second gate structure formed on the semiconductor substrate across the second active region, the second gate structure including the interfacial layer, the high-k dielectric layer, the capping metal layer, a dielectric layer, and the work function metal layer that are stacked sequentially.

### CROSS-REFERENCE TO RELATED APPLICATION

This application claims the benefit of priority under 35 U.S.C. §119 to Korean Patent Application No. 10-2015-0075370, filed on May 28, 2015, in the Korean Intellectual Property Office, the content of which is incorporated herein in its entirety by reference.

### BACKGROUND

The present disclosure relates to a semiconductor device, and more particularly, to a semiconductor device including a gate structure and a method of manufacturing the same.

Semiconductor devices may be downscaled, multifunctional, and/or manufactured at low cost and thus, have become strongly relied upon as a significant element in the electronic industry. Semiconductor devices may be classified into a semiconductor memory device configured to store logic data, a semiconductor logic device configured to operate the logic data, and a hybrid semiconductor device including a memory element and a logic element. With continuous developments in electronic industries, the demand for improved characteristics of semiconductor devices has gradually increased. For example, highly reliable, high-speed, and/or multi-functional semiconductor devices have become increasingly in demand. To meet these demands, structures of the semiconductor devices have become increasingly complicated, and the semiconductor devices have become highly integrated.

### SUMMARY

Embodiments of the disclosed concept provide a semiconductor device in which a multi-threshold voltage (multi-Vth) is embodied by controlling a work function, and a method of manufacturing the same.

Also, embodiments of the disclosed concepts provide a semiconductor device including at least two transistors, which may be easily patterned, minimize damage to a high-k dielectric layer during a patterning process, and have different threshold voltages, and a method of manufacturing the same.

In some exemplary embodiments, the present disclosure is directed to a semiconductor device comprising: a semiconductor substrate including a first region and a second region; a first active region formed in an upper portion of the first region of the semiconductor substrate; a second active region formed in an upper portion of the second region of the semiconductor substrate; a first gate structure on the semiconductor substrate extending across the first active region, the first gate structure comprising a high-k dielectric layer, a capping metal layer on the high-k dielectric layer, and a work function metal layer on the capping metal layer; and a second gate structure on the semiconductor substrate extending across the second active region, the second gate structure comprising the high-k dielectric layer, the capping metal layer on the high-k dielectric layer, a dielectric layer, and the work function metal layer on the dielectric layer, wherein the first gate structure does not include the dielectric layer interposed between the high-k dielectric layer and the work function metal layer.

In some embodiments, the present disclosure may further include wherein the dielectric layer of the second gate structure is formed of a material that inhibits migration of electrons between the capping metal layer of the second gate structure and the work function metal layer of the second gate structure.

In some embodiments, the present disclosure may further include wherein the dielectric layer of the second gate structure has a bandgap of 4.0 eV or more.

In some embodiments, the present disclosure may further include wherein the dielectric layer of the second gate structure is formed to have a thickness that inhibits migration of electrons between the capping metal layer of the second gate structure and the work function metal layer of the second gate structure and minimizes a resistance of the second gate structure.

In some embodiments, the present disclosure may further include wherein the dielectric layer of the second gate structure has a thickness of 2 nm or less.

In some embodiments, the present disclosure may further include wherein the dielectric layer extends over topmost portions of the capping metal layer.

In some embodiments, the present disclosure may further include wherein the capping metal layer of the second gate structure has a thickness of 3 nm or less.

In some embodiments, the present disclosure may further include wherein the capping metal layer of the second gate structure is formed of a material having a larger work function than the work function metal layer of the second gate structure.

In some embodiments, the present disclosure may further include wherein the capping metal layer includes at least one of a metal nitride, a metal carbide, a metal silicide, a metal silicon nitride, and a metal silicon carbide, which contains at least one of titanium (Ti) and tantalum (Ta).

In some embodiments, the present disclosure may further include wherein the work function metal layer comprises a combination of: an aluminum (Al) compound containing titanium and/or tantalum, and at least one of Mo, Pd, Ru, Pt, TiN, WN, TaN, Ir, TaC, RuN, and MoN.

In some embodiments, the present disclosure may further include a third gate structure comprising the high-k dielectric layer, the capping metal layer on the high-k dielectric layer, and the work function metal layer on the capping metal layer, wherein the first gate structure does not include the dielectric layer interposed between the high-k dielectric layer and the work function metal layer; and a fourth gate structure comprising the high-k dielectric layer, the capping metal layer on the high-k dielectric layer, the dielectric layer on the capping metal layer, and the work function metal layer on the dielectric layer, wherein the first and third gate structures and/or the second and fourth gate structures are parts of transistors having two different threshold voltages.

In some embodiments, the present disclosure may further include wherein the work function metal layers of the first gate structure and the second gate structure comprise one of the following: respective portions of first and second NMOS transistor gate electrodes, and respective portions of first and second PMOS transistor gate electrodes.

In some embodiments, the present disclosure may further include wherein at least one of the first gate structure and the second gate structure comprises a work function metal layer comprising an aluminum (Al) compound containing titanium and/or tantalum, and a barrier metal comprising at least one of Mo, Pd, Ru, Pt, TiN, WN, TaN, Ir, TaC, RuN, and MoN.

In some embodiments, the present disclosure may further include wherein each of the first active region and second active region has a fin shape protruding from the semiconductor substrate, wherein the first gate structure covers a top surface and side surfaces of a portion of the first active region, and wherein the second gate structure covers a top surface and side surfaces of a portion of the second active region.

In some exemplary embodiments, the present disclosure is directed to a semiconductor device comprising: a semiconductor substrate including a first region and a second region; at least one fin protruding on the semiconductor substrate and extending in a first direction; a first gate structure formed in the first region of the semiconductor substrate and extending in a second direction to cover top and side surfaces of the at least one fin, the first gate structure comprising a high-k dielectric layer, a capping metal layer on the high-k dielectric layer, and a work function metal layer on the capping metal layer; and a second gate structure formed in the second region of the semiconductor substrate and extending in the second direction to cover the top and side surfaces of the at least one fin, the second gate structure comprising the high-k dielectric layer, the capping metal layer on the high-k dielectric layer, a dielectric layer on the capping metal layer, and the work function metal layer on the dielectric layer, wherein the first gate structure does not include the dielectric layer interposed between the high-k dielectric layer and the work function metal layer.

In some embodiments, the present disclosure may further include wherein the dielectric layer of the second gate structure is formed of a material that inhibits migration of electrons between the capping metal layer of the second gate structure and the work function metal layer of the second gate structure or reduces a variation in work function of the work function metal layer of the second gate structure caused by the capping metal layer.

In some embodiments, the present disclosure may further include wherein the dielectric layer of the second gate structure is formed to have a thickness that minimizes a resistance of the second gate structure.

In some embodiments, the present disclosure may further include wherein the dielectric layer of the second gate structure has a bandgap that inhibits migration of electrons between the capping metal layer of the second gate structure and the work function metal layer of the second gate structure.

In some embodiments, the present disclosure may further include wherein the dielectric layer extends over topmost portions of the capping metal layer of the second gate structure, and wherein each of the work function metal layer and a gap-fill metal layer formed on the capping metal layer of the second gate structure includes a stepped portion.

In some embodiments, the present disclosure may further include wherein the capping metal layer of the second gate structure has a larger work function than the work function metal layer and includes any one of a metal nitride, a metal carbide, a metal silicide, a metal silicon nitride, and a metal silicon carbide, which contains at least one of titanium and tantalum.

In some embodiments, the present disclosure may further include a third gate structure comprising the high-k dielectric layer, the capping metal layer on the high-k dielectric layer, and the work function metal layer on the capping metal layer, wherein the first gate structure does not include the dielectric layer interposed between the high-k dielectric layer and the work function metal layer; and a fourth gate structure comprising the high-k dielectric layer, the capping metal layer on the high-k dielectric layer, the dielectric layer on the capping metal layer, and the work function metal layer on the dielectric layer, wherein the first and third gate structures and/or the second and fourth gate structures are parts of transistors having two different threshold voltages.

In some exemplary embodiments, the present disclosure is directed to a method of manufacturing a semiconductor device, the method comprising: forming a dummy gate structure on a semiconductor substrate that includes a first region and a second region, wherein the dummy gate structure extends in a first direction and includes a dummy insulating layer and a dummy gate electrode; forming spacers on sidewalls of the dummy gate structure; forming an interlayer insulating layer to cover the semiconductor substrate and a resultant structure formed on the semiconductor substrate; planarizing the interlayer insulating layer to expose a top surface of the dummy gate structure; removing the dummy gate structure and sequentially forming a high-k dielectric layer, a capping metal layer, and a dielectric layer on a portion from which the dummy gate structure is removed and on the interlayer insulating layer; removing the dielectric layer from the first region; forming a work function metal layer on the capping metal layer of the first region and the dielectric layer of the second region; and forming a first gate structure in the first region and forming a second gate structure in the second region, wherein the first gate structure comprises the high-k dielectric layer, the capping metal layer on the high-k dielectric layer, and the work function metal layer on the capping metal layer, and the second gate structure comprises the high-k dielectric layer, the capping metal layer on the high-k dielectric layer, the dielectric layer on the capping metal layer, and the work function metal layer on the dielectric layer, wherein the first gate structure does not include the dielectric layer interposed between the high-k dielectric layer and the work function metal layer.

In some embodiments, the present disclosure may further include wherein the dielectric layer of the second gate structure is formed of a material that inhibits migration of electrons between the capping metal layer of the second gate structure and the work function metal layer of the second gate structure or reduces a variation in work function of the work function metal layer of the second gate structure due to the capping metal layer of the second gate structure.

In some embodiments, the present disclosure may further include wherein the dielectric layer of the second gate structure is formed of a material having a bandgap of 4.0 eV or more and a thickness of 2 nm or less.

In some embodiments, the present disclosure may further include wherein the dielectric layer extends over topmost portions of the capping metal layer of the second gate structure, and wherein each of the work function metal layer and a gap-fill metal layer formed on the capping metal layer of the second gate structure includes a stepped portion.

In some embodiments, the present disclosure may further include wherein the forming of the first gate structure and the second gate structure further comprises: forming a gap-fill metal layer on the work function metal layer; and performing a planarization process to expose the interlayer insulating layer to electrically isolate the first gate structure and the second gate structure from each other.

In some exemplary embodiments, the present disclosure is directed to a method of manufacturing a semiconductor device, the method comprising: forming trenches by etching a semiconductor substrate including a first region and a second region, and forming a protruding structure between the trenches, the protruding structure protruding from the semiconductor substrate and extending in a first direction; forming a device isolation layer by filling a lower portion of each of the trenches with an insulating material such that an upper portion of the protruding structure protrudes, and defining at least one fin, each fin including a lower fin portion and an upper fin portion; forming a first gate structure and a second gate structure, the first gate structure extending across the first region of the semiconductor substrate in a second direction and covering a top surface and side surfaces of the at least one fin, the first gate structure comprising a high-k dielectric layer, a capping metal layer on the high-k dielectric layer, and a work function metal layer on the capping metal layer, the second gate structure extending across the second region of the semiconductor substrate in the second direction and covering the top surface and the side surfaces of the at least one fin, the second gate structure comprising the high-k dielectric layer, the capping metal layer on the high-k dielectric layer, a dielectric layer on the capping metal layer, and the work function metal layer on the dielectric layer, wherein the first gate structure does not include the dielectric layer interposed between the high-k dielectric layer and the work function metal layer.

In some embodiments, the present disclosure may further include wherein the forming the first gate structure and second gate structure comprises: forming a dummy gate structure including a dummy insulating layer and a dummy gate structure, the dummy gate structure covering the semiconductor substrate, the device isolation layer, and a portion of the at least one fin and extending in the second direction; forming spacers on side surfaces of the dummy gate structure; forming an interlayer insulating layer to cover the semiconductor substrate and a resultant structure formed on the semiconductor substrate; planarizing the interlayer insulating layer to expose a top surface of the dummy gate structure; removing the dummy gate structure and sequentially forming the high-k dielectric layer, the capping metal layer, and the dielectric layer on a portion from which the dummy gate structure is removed and on the interlayer insulating layer; removing the dielectric layer from the first region; forming a work function metal layer on the capping metal layer of the first region and the dielectric layer of the second region; and completing the first gate structure formed on the first region and the second gate structure formed on the second region.

In some embodiments, the present disclosure may further include wherein the dielectric layer of the second gate structure is formed of a material that inhibits migration of electrons between the capping metal layer of the second gate structure and the work function metal layer of the second gate structure.

In some embodiments, the present disclosure may further include wherein the dielectric layer of the second gate structure is formed of a material having a bandgap of 4.0 eV or more.

In some embodiments, the present disclosure may further include wherein the dielectric layer extends over topmost portions of the capping metal layer of the second gate structure.

In some embodiments, the present disclosure may further include wherein the completing the first gate structure and the second gate structure comprises: forming a gap-fill metal layer on the work function metal layer; and electrically isolating the first gate structure and the second gate structure from each other.

In some exemplary embodiments, the present disclosure is directed to a semiconductor device comprising: a semiconductor substrate including a first region and a second region; a first active region formed in the first region of the semiconductor substrate; a second active region formed in the second region of the semiconductor substrate; a first gate structure formed on the semiconductor substrate across the first active region, the first gate structure comprising a high-k dielectric layer, a capping metal layer formed on the high-k dielectric layer, and a work function metal layer formed on the capping metal layer; and a second gate structure formed on the semiconductor substrate across the second active region, the second gate structure comprising the high-k dielectric layer, the capping metal layer formed on the high-k dielectric layer, a dielectric layer formed on the capping metal layer, and the work function metal layer formed on the dielectric layer, wherein a work function of the capping metal layer of the second gate structure is larger than a work function of the work function metal layer of the second gate structure.

In some embodiments, the present disclosure may further include wherein the dielectric layer of the second gate structure has a bandgap of 4.0 eV or more.

In some embodiments, the present disclosure may further include wherein the dielectric layer of the second gate structure is formed to have a thickness that inhibits migration of electrons between the capping metal layer of the second gate structure and the work function metal layer of the second gate structure and minimizes a resistance of the second gate structure.

In some embodiments, the present disclosure may further include wherein the dielectric layer of the second gate structure has a thickness of 2 nm or less.

In some embodiments, the present disclosure may further include wherein the capping metal layer of the second gate structure has a thickness of 3 nm or less.

In some embodiments, the present disclosure may further include wherein the capping metal layer of the second gate structure is formed of a material having a larger work function than the work function metal layer of the second gate structure.

In some embodiments, the present disclosure may further include wherein the capping metal layer includes at least one of a metal nitride, a metal carbide, a metal silicide, a metal silicon nitride, and a metal silicon carbide, which contains at least one of titanium (Ti) and tantalum (Ta).

In some embodiments, the present disclosure may further include wherein each of the first active region and second active region has a fin shape protruding from the semiconductor substrate, wherein the first gate structure covers a top surface and side surfaces of a portion of the first active region, and wherein the second gate structure covers a top surface and side surfaces of a portion of the second active region.

In some embodiments, the present disclosure may further include wherein the dielectric layer of the second gate structure inhibits migration of electrons between the capping metal layer of the second gate structure and the work function metal layer of the second gate structure.

According to an aspect of the disclosed concept, there is provided a semiconductor device including a semiconductor substrate in which a first region and a second region are defined, a first active region formed in an upper portion of the first region of the semiconductor substrate, a second active region formed in an upper portion of the second region of the semiconductor substrate, a first gate structure extending on the semiconductor substrate across the first active region, the first gate structure including an interfacial layer, a high-k dielectric layer, a capping metal layer, and a work function metal layer that are sequentially stacked, and a second gate structure extending on the semiconductor substrate across the second active region, the second gate structure in which the interfacial layer, the high-k dielectric layer, the capping metal layer, a dielectric layer, and the work function metal layer are sequentially stacked.

According to another aspect of the disclosed concept, there is provided a semiconductor device including a semiconductor substrate in which a first region and a second region are defined, at least one fin protruding on the semiconductor substrate and extending in a first direction, a first gate structure positioned in the first region of the semiconductor substrate and extending in a second direction to cover top and side surfaces of the at least one fin, the first gate structure including an interfacial layer, a high-k dielectric layer, a capping metal layer, and a work function metal layer that are sequentially stacked, and a second gate structure positioned in the second region of the semiconductor substrate and extending in the second direction to cover the top and side surfaces of the at least one fin, the second gate structure including the interfacial layer, the high-k dielectric layer, the capping metal layer, a dielectric layer, and the work function metal layer that are sequentially stacked.

According to another aspect of the disclosed concept, there is provided a method of manufacturing a semiconductor device. The method includes forming a dummy gate structure on a semiconductor substrate in which a first region and a second region are defined, the dummy gate structure extending in one direction and including a dummy insulating layer and a dummy gate electrode, forming spacers on sidewalls of the dummy gate structure, forming an interlayer insulating layer to cover the semiconductor substrate and the resultant structure formed on the semiconductor substrate and planarizing the interlayer insulating layer to expose a top surface of the dummy gate structure, removing the dummy gate structure and sequentially forming an interfacial layer, a high-k dielectric layer, a capping metal layer, and a dielectric layer on a portion from which the dummy gate structure is removed and on the interlayer insulating layer, removing the dielectric layer from the first region, forming a work function metal layer on the capping metal layer of the first region and the dielectric layer of the second region, and forming a first gate structure in the first region and forming a second gate structure in the second region, the first gate structure in which the interfacial layer, the high-k dielectric layer, the capping metal layer, and the work function metal layer are sequentially stacked, the second gate structure in which the interfacial layer, the high-k dielectric layer, the capping metal layer, a dielectric layer, and the work function metal layer are sequentially stacked.

According to another aspect of the disclosed concept, there is provided a method of manufacturing a semiconductor device. The method includes forming trenches by etching a semiconductor substrate in which a first region and a second region are defined, and forming a protruding structure between the trenches, the protruding structure protruding from the semiconductor substrate and extending in a first direction, forming a device isolation layer by filling a lower portion of each of the trenches with an insulating material such that an upper portion of the protruding structure protrudes, and defining at least one fin, each fin including a lower fin portion and an upper fin portion, and forming a first gate structure and a second gate structure, the first gate structure extending on the first region of the semiconductor substrate in a second direction and covering a top surface and side surfaces of the at least one fin, the first gate structure including an interfacial layer, a high-k dielectric layer, a capping metal layer, and a work function metal layer that are sequentially stacked, the second gate structure extending on the second region of the semiconductor substrate in the second direction and covering the top and side surfaces of the at least one fin, the second gate structure including the interfacial layer, the high-k dielectric layer, the capping metal layer, a dielectric layer, and the work function metal layer that are sequentially stacked.

In an exemplary embodiment, the formation of the first gate structure and second gate structure may include forming a dummy gate structure including a dummy insulating layer and a dummy gate structure, the dummy gate structure covering the semiconductor substrate, the device isolation layer, and a portion of the at least one fin and extending in the second direction, forming spacers on side surfaces of the dummy gate structure, forming an interlayer insulating layer to cover the semiconductor substrate and the resultant structure formed on the semiconductor substrate, planarizing the interlayer insulating layer to expose a top surface of the dummy gate structure, removing the dummy gate structure and sequentially forming the interfacial layer, the high-k dielectric layer, the capping metal layer, and the dielectric layer on a portion from which the dummy gate structure is removed and the interlayer insulating layer, removing the dielectric layer from the first region, forming a work function metal layer on the capping metal layer of the first region and the dielectric layer of the second region, and completing the first gate structure formed on the first region and the second gate structure formed on the second region.

### BRIEF DESCRIPTION OF THE DRAWINGS

The above and other objects and features will be more clearly understood from the following detailed description taken in conjunction with the accompanying drawings in which:

FIG. 1 is a conceptual cross-sectional view of an exemplary semiconductor device in which a multi-threshold voltage is embodied by controlling a work function, according to certain disclosed embodiments;

FIGS. 2A and 2B are graphs showing exemplary results of threshold voltage shift due to insertion of a dielectric layer between a capping metal layer and a work function metal layer, according to certain disclosed embodiments;

FIG. 3 is a plan view of an exemplary semiconductor device in which a multi-threshold voltage is embodied by controlling a work function, according to certain disclosed embodiments;

FIGS. 4A and 4B are cross-sectional views of the exemplary semiconductor device of FIG. 3, according to certain disclosed embodiments;

FIGS. 5 to 12 are cross-sectional views of exemplary semiconductor devices, which correspond to FIG. 4A, according to certain disclosed embodiments;

FIG. 13 is a cross-sectional view of exemplary semiconductor devices, according to certain disclosed embodiments;

FIG. 14 is a perspective view of an exemplary semiconductor device, according to certain disclosed embodiments;

FIGS. 15A and 15B are cross-sectional views of the exemplary semiconductor device of FIG. 14, according to certain disclosed embodiments;

FIGS. 16 to 23 are cross-sectional views of exemplary semiconductor devices, which correspond to the cross-sectional view of FIG. 15A, according to certain disclosed embodiments;

FIG. 24 is a cross-sectional view of an exemplary semiconductor device, according to certain disclosed embodiments;

FIG. 25 is a plan view of an exemplary memory module, according to certain disclosed embodiments;

FIG. 26 is a schematic block diagram of an exemplary display driver integrated circuit (DDI) and a display device including the DDI, according to certain disclosed embodiments;

FIG. 27 is a circuit diagram of an exemplary complementary metal-oxide semiconductor (CMOS) inverter, according to certain disclosed embodiments;

FIG. 28 is a circuit diagram of an exemplary CMOS static random access memory (SRAM) device, according to certain disclosed embodiments;

FIG. 29 is a circuit diagram of an exemplary CMOS NAND circuit, according to certain disclosed embodiments;

FIG. 30 is a block diagram of an exemplary electronic system, according to certain disclosed embodiments;

FIG. 31 is a block diagram of an exemplary electronic system, according to certain disclosed embodiments;

FIGS. 32A to 32G are cross-sectional views of an exemplary method of manufacturing the semiconductor device of FIG. 4A, according to certain disclosed embodiments;

FIGS. 33A and 33B are cross-sectional views of an exemplary method of manufacturing the semiconductor device of FIG. 12, according to certain disclosed embodiments; and

FIGS. 34A to 41C are a perspective view and cross-sectional views of an exemplary method of fabricating the semiconductor device of FIG. 14, according to certain disclosed embodiments.

### DETAILED DESCRIPTION OF THE EMBODIMENTS

Advantages and features of the disclosed embodiments and methods of accomplishing them will be made apparent with reference to the accompanying drawings and some embodiments to be described below. The disclosed embodiments may, however, be embodied in various different forms, and should be construed as limited, not by the embodiments set forth herein, but only by the accompanying claims. Accordingly, known processes, elements, and techniques are not described with respect to some of the disclosed embodiments. Unless otherwise noted, like reference numerals denote like elements throughout the attached drawings and written description, and thus descriptions will not be repeated. In the drawings, the sizes and relative sizes of layers and regions may be exaggerated for clarity. It will be understood that, although the terms “first”, “second”, “third”, etc., may be used herein to describe various elements, components, regions, layers and/or sections, these elements, components, regions, layers and/or sections should not be limited by these terms. Unless indicated otherwise, these terms are only used to distinguish one element, component, region, layer and/or section from another element, component, region, layer and/or section. Thus, a first element, component, region, layer and/or section discussed below could be termed a second element, component, region, layer and/or section without departing from the teachings of the disclosure.

The terminology used herein is for the purpose of describing particular examples and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, components, and/or groups, and do not preclude the presence or addition of one or more other features, integers, steps, operations, elements, components, and/or groups.

It will be understood that when an element or layer is referred to as being “on,” “connected to,” “in contact with,” and/or “coupled to” another element or layer, it can be directly on, connected to, in contact with and/or coupled to the other element or layer or intervening elements or layers may be present. In contrast, when an element is referred to as being “directly on,” “directly connected to,” or “directly coupled to” another element or layer or as “contacting” another element or layer, there are no intervening elements or layers present. Like reference numerals throughout this specification denote like elements. As used herein, the term “and/or” includes any and all combinations of one or more of the associated listed items. Also, the term “exemplary” is intended to refer to an example or illustration.

Spatially relative terms, such as “beneath,” “below,” “lower,” “above,” “upper,” and the like, may be used herein for ease of description in describing one element's or feature's relationship to another/other element(s) or feature(s) as illustrated in the figures. It will be understood that spatially relative terms are intended to encompass different orientations of the device in use or operation in addition to the orientation depicted in the figures. For example, if the device in the figures is turned over, elements described as “below” or “beneath” another/other element(s) or feature(s) would then be oriented “above,” “on,” or “on top of” the another/other element(s) or feature(s). Thus, the term “below” can encompass both an orientation of above and below. The device may be otherwise oriented (rotated 90 degrees or at other orientations) and the spatially relative descriptors used herein may be interpreted accordingly. In addition, it will also be understood that when a layer is referred to as being “between” two layers, it can be the only layer between the two layers, or one or more intervening layers may also be present.

Also these spatially relative terms such as “above” and “below” as used herein have their ordinary broad meanings—for example element A can be above element B even if when looking down on the two elements there is no overlap between them (just as something in the sky is generally above something on the ground, even if it is not directly above).

Terms such as “same,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning.

The semiconductor devices described herein may be part of an electronic device, such as a semiconductor memory chip or semiconductor logic chip, a stack of such chips, a semiconductor package including a package substrate and one or more semiconductor chips, a package-on-package device, or a semiconductor memory module, for example. In the case of memory, the semiconductor device may be part of a volatile or non-volatile memory. A chip or package that includes the semiconductor devices, such as the fin structures described herein, may also be referred to generally as a semiconductor device.

The exemplary embodiments will be described with reference to cross-sectional views and/or plan views, which are ideal exemplary views. Thicknesses of layers and areas are exaggerated for effective description of the technical contents in the drawings. Forms of the embodiments may be modified by the manufacturing technology and/or tolerance. Therefore, the disclosed embodiments are not intended to be limited to illustrated specific forms, and may include modifications of forms generated according to manufacturing processes. For example, an etching area illustrated at a right angle may be round or have a predetermined curvature. Therefore, areas illustrated in the drawings have overview properties, and shapes of the areas are illustrated special forms of the areas of a device, and are not intended to be limited to the scope of the disclosed embodiments.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Although the figures described herein may be referred to using language such as “one embodiment” or “certain embodiments,” the figures and their corresponding descriptions are not intended to be mutually exclusive from other figures or descriptions, unless the context so indicates. Therefore, certain aspects from certain figures may be the same as features in other figures and/or certain aspects from certain figures may be different representations or different portions of particular exemplary embodiments.

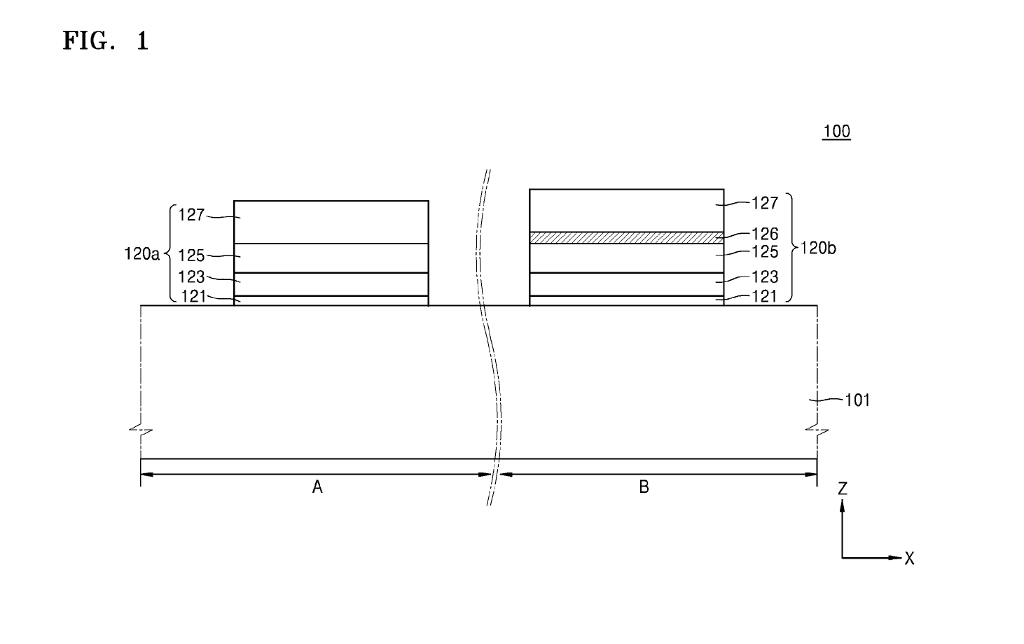

In the disclosed embodiments, a nonvolatile memory device may be used as an example of a storage device or an electronic device to describe features and functions of certain concepts. However, other features and functions of the disclosed concepts may be easily understood according to information disclosed herein. Furthermore, the disclosed concepts may be implemented through other embodiments or applied thereto. Also, it will be apparent to those skilled in the art that various changes and modifications may be made without departing from the spirit and scope of the disclosure. FIG. 1 is a schematic cross-sectional view in which a multi-threshold voltage Vth is embodied by controlling a work function, according to an exemplary embodiment.

Referring to FIG. 1, the semiconductor device 100 according to the present embodiment may include a semiconductor substrate 101 and first and second gate structures 120a and 120b. The semiconductor substrate 101 may include a first region A and a second region B. The first gate structure 120a may be positioned on the first region A of the semiconductor substrate 101, and the second gate structure 120b may be positioned on the second region B of the semiconductor substrate 101. The first gate structure 120a and the second gate structure 120b may constitute transistors positioned in the first and second regions A and B, respectively.

Here, the first region A and the second region B may be regions connected to each other or regions separated from each other. In some embodiments, the first region A and the second region B may be regions that perform the same function. In other exemplary embodiments, the first region A and the second region B may be regions that perform different functions. For example, the first region A may be a portion of a logic region, while the second region B may be another portion of the logic region. For example, the first region A may be any one of a memory region and a non-memory region, and the second region B may be the other one of the memory region and the non-memory region. Here, the memory region may include a static random access memory (SRAM) region, a dynamic RAM (DRAM) region, a magnetic RAM (MRAM) region, a resistive RAM (RRAM) region, or a phase-change RAM (PRAM) region, and the non-memory region may include a logic region.

The semiconductor substrate 101 may be based on a silicon bulk wafer or a silicon-on-insulator (SOI) wafer, but a material of the semiconductor substrate 101 is not limited to silicon. For example, the semiconductor substrate 101 may include a Group IV semiconductor such as germanium (Ge), a Group IV-IV compound semiconductor such as silicon germanium (SiGe) or silicon carbide (SiC), or a Group III-V compound semiconductor such as gallium arsenide (GaAs), indium arsenide (InAs), or indium phosphide (InP). Also, the semiconductor substrate 101 may be based on a SiGe wafer, an epitaxial wafer, a polished wafer, or an annealed wafer.

Although not illustrated in FIG. 1, the semiconductor substrate 101 may be a p-type substrate or an n-type substrate. For example, the semiconductor substrate 101 may be a p-type substrate containing p-type impurity ions or an n-type substrate containing n-type impurity ions. The semiconductor substrate 101 may include an active region defined by a device isolation layer, such as a shallow trench isolation (STI), which is formed in an upper portion thereof. The active region may include an impurity region formed by implanting impurity ions (i.e., a dopant) at a high concentration into the semiconductor substrate 101. For example, the active region may include source and drain regions formed by implanting a dopant at a concentration of about 1E²⁰/cm³ or more into the semiconductor substrate 101 on two sides of each of the first and second gate structures 120a and 120b.

Each of the first and second gate structures 120a and 120b may extend on the semiconductor substrate 101 across the active region. Meanwhile, although not shown in FIG. 1, an interlayer insulating layer may be formed on two sides of each of the first and second gate structures 120a and 120b, and spacers may be interposed between the first and second gate structure 120a and 120b and the interlayer insulating layer.

In the following description, when terms such as “first” and “second” are not used herein to distinguish one gate structure from another gate structure, a gate structure denoted by a reference alphanumeric designator including the letter ‘a’ may refer to a gate structure formed in the first region A, and a gate structure denoted by a reference alphanumeric numeric designator including the letter ‘b’ may refer to a gate structure formed in the second region B.

The first gate structure 120a may include an interfacial layer 121, a high-k dielectric layer 123, a capping metal layer 125, and a work function metal layer 127. Also, the second gate structure 120b may include an interfacial layer 121, a high-k dielectric layer 123, a capping metal layer 125, a dielectric layer 126, and a work function metal layer 127.

The interfacial layer 121 may be formed on the semiconductor substrate 101. The interfacial layer 121 may be formed of an insulating material, such as, for example, an oxide layer, a nitride layer, or an oxynitride layer. For instance, the interfacial layer 121 may be formed of silicon oxide (SiO2) or silicon oxynitride (SiON). The interfacial layer 121 and the high-k dielectric layer 123 may constitute a gate oxide layer.

The high-k dielectric layer 123, which is referred to as a high-k layer, may be formed of a dielectric material having a high dielectric constant ‘k’. The high-k dielectric layer 123 may be formed, for example, of a hafnium (Hf)-based material or a zirconium (Zr)-based material. For instance, the high-k dielectric layer 123 may include hafnium oxide (HfO₂), hafnium silicon oxide (HfSiO), hafnium silicon oxynitride (HfSiON), hafnium oxynitride (HfON), hafnium aluminum oxide (HfAlO), hafnium lanthanum oxide (HfLaO), zirconium oxide (ZrO₂), or zirconium silicon oxide (ZrSiO).

In addition, the high-k dielectric layer 123 is not limited to the hafnium-based material or the zirconium-based material but may include a different materials, such as, for example, lanthanum oxide (La₂O₃), lanthanum aluminum oxide (LaAlO₃), tantalum oxide (Ta₂O₅), titanium oxide (TiO₂), strontium titanium oxide (SrTiO₃), yttrium oxide (Y₂O₃), aluminum oxide (Al₂O₃), lead scandium tantalum oxide (PbSc_{0.5}Ta_{0.5}O₃), or lead zinc niobate (PbZnNbO₃).

The high-k dielectric layer 123 may be formed by using various deposition methods, such as atomic layer deposition (ALD), chemical vapor deposition (CVD), or physical vapor deposition (PVD).

The capping metal layer 125 may be formed on the high-k dielectric layer 123 and may include at least one of titanium (Ti) and tantalum (Ta). For example, the capping metal layer 125 may be formed of a metal nitride (e.g., titanium nitride (TiN) and tantalum nitride (TaN)), a metal carbide, a metal silicide, a metal silicon nitride, and a metal silicon carbide.

The capping metal layer 125 may be formed to a relatively small thickness by using various deposition methods, such as, for example, atomic layer deposition (ALD), chemical vapor deposition (CVD), and physical vapor deposition (PVD). For example, the capping metal layer 125 may be formed to a thickness of about 3 nm or less. In some embodiments, since the second gate structure 120b further includes the dielectric layer 126, the capping metal layer 125 formed under the dielectric layer 126 may be formed to a thickness small enough that the second gate structure 120b may have about the same height as the first gate structure 120a.

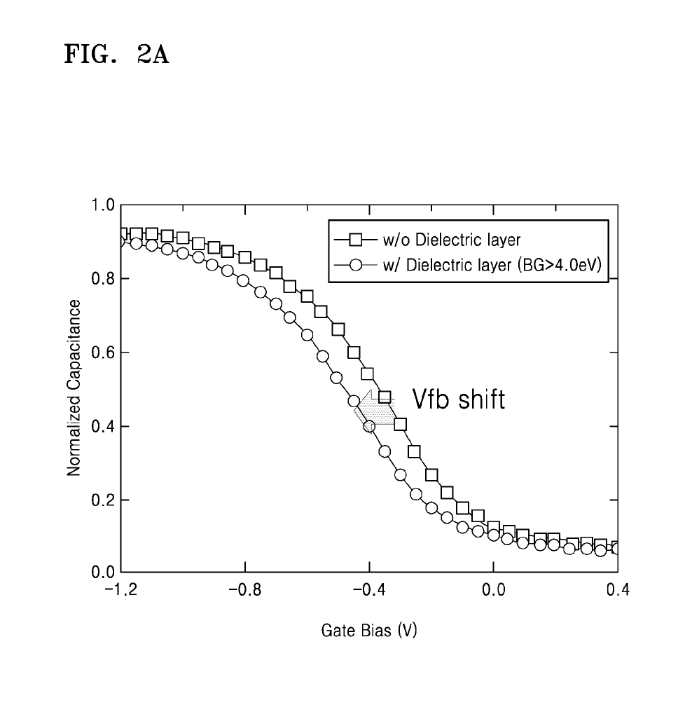

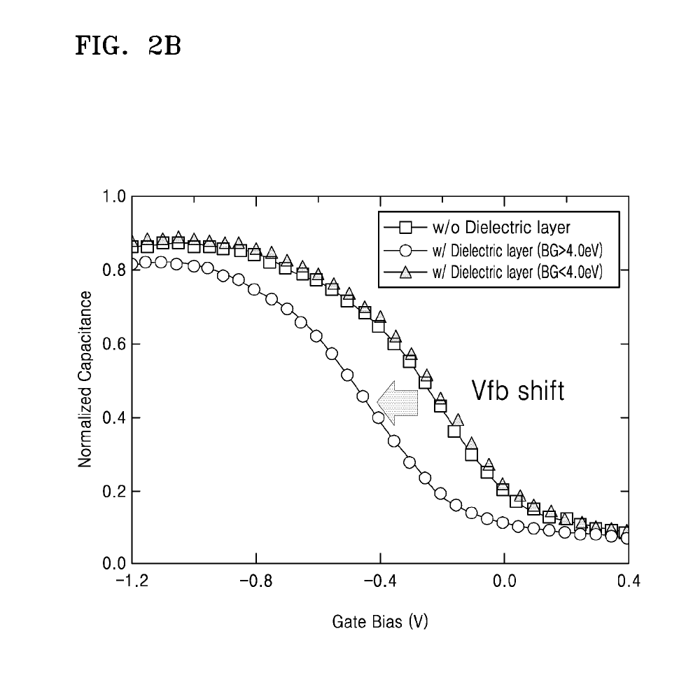

Along with the work function metal layer 127, the capping metal layer 125 may constitute metal electrodes of the first and second gate structures 120a and 120b, and the capping metal layer 125 may function to control a work function of the metal electrodes. Thus, the capping metal layer 125 may be also referred to as a work function control layer. A work function control function of the capping metal layer 125 will be described in further detail in connection with FIGS. 2A and 2B. In addition to controlling a work function, the capping metal layer 125 may also prevent diffusion of atoms or ions of the high-k dielectric layer 123, which is formed under the capping metal layer 125, into the work function metal layer 127, which is formed on the capping metal layer 125.

The work function metal layer 127 may be formed of an n-type metal or a p-type metal on the capping metal layer 125. For reference, “n-type metal” as used herein refers to a metal conventionally constituting an NMOS transistor gate electrode, and “p-type metal” as used herein refers to a metal conventionally constituting a PMOS transistor gate electrode. As disclosed in embodiments herein, however, n-type metal may be used as part of a PMOS transistor gate electrodes according to certain embodiments and p-type metal may be used as part of NMOS transistor gate electrodes according to certain embodiments. When the work function metal layer 127 is formed of the n-type metal, the work function metal layer 127 may include an aluminum (Al) compound containing titanium and/or tantalum. For example, the work function metal layer 127 may include an aluminum (Al) compound such as titanium aluminum carbide (TiAlC), titanium aluminum nitride (TiAlN), titanium aluminum carbon nitride (TiAlC—N), titanium aluminide (TiAl), and tantalum aluminum carbide (TaAlC), tantalum aluminum nitride (TaAlN), tantalum aluminum carbon nitride TaAlC—N, tantalum aluminide (TaAl). As one of skill in the art may appreciate, the n-type metal forming the work function metal layer 127 is not limited to the above-described materials, and the work function metal layer 127 formed of the n-type metal may be not limited to a single layer but may be a multi-layered structure including at least two layers.

In some embodiments, the work function metal layer 127 may be formed of a p-type metal. When the work function metal layer 127 is formed of the p-type metal, the work function metal layer 127 may include, for example, a metal nitride and/or a metal, such as at least one of Mo, Pd, Ru, Pt, TiN, WN, TaN, Ir, TaC, RuN, and MoN. As one of skill in the art may appreciate, the p-type metal forming the work function metal layer 127 is not limited to the above-described materials. Also, the work function metal layer 127 formed of the p-type metal may be not only a single layer but may be a multi-layered structure including at least two layers.

In some embodiments, the dielectric layer 126 may remain only in the second gate structure 120b. For example, the dielectric layer 126 may be interposed between the capping metal layer 125 and the work function metal layer 127, and may block migration of electrons between the capping metal layer 125 and the work function metal layer 127. The dielectric layer 126 may reduce or inhibit a work function control effect of the capping metal layer 125. Accordingly, the dielectric layer 126 may be formed of a material capable of effectively inhibiting migration of electrons between the capping metal layer 125 and the work function metal layer 127. In some embodiments, the dielectric layer 126 may be formed of a material capable of minimizing a variation in work function of the work function metal layer 127 due to the capping metal layer 125. For example, the dielectric layer 126 may be formed of a material having a bandgap of about 4.0 eV or more and a low dielectric constant k. In general, a material having a low dielectric constant k may have similar characteristics to a non-conductor and a high bandgap. In contrast, a material having a high dielectric constant k may have similar characteristics to a conductor (e.g., a metal) and a low bandgap.

Since the dielectric layer 126 is not a conductive layer, the dielectric layer 126 may function to increase a resistance of a gate electrode in the second gate structure 120b. For example, when the dielectric layer 126 is formed to a relatively greater thickness, a delay time of the gate electrode may increase. Accordingly, the dielectric layer 126 may be formed to a relatively smaller thickness, for example, a thickness of about 2 nm or less. Also, as described, the dielectric layer 126 may have a thickness sufficient to inhibit migration of electrons and minimize a variation in work function of the work function metal layer 127. As a result, the dielectric layer 126 may be formed to have a thickness that falls within a range of thicknesses that minimizes a resistance and inhibits migration of electrons.

Although not shown, in some embodiments, a gap-fill metal layer may be formed on the work function metal layer 127. When a gate structure has a replacement metal gate (RMG) structure, the gap-fill metal layer may be a metal layer configured to fill a gap that remains after other metal layers are formed. In some cases, the gap-fill metal layer may form an uppermost metal layer in a planar gate structure. The gap-fill metal layer may include for example, tungsten (W). However, a material of the gap-fill metal layer is not limited to tungsten. The gap-fill metal layer may be formed of one or more of various metals suitable for filling the gap. For example, the gap-fill metal layer may include a material selected from the group including a metal nitride (e.g., titanium nitride (TiN) and tantalum nitride (TaN)), aluminum (Al), a metal carbide, a metal silicide, a metal aluminum carbide, a metal aluminum nitride, and a metal silicon nitride. Alternatively, the gap-fill metal layer may be omitted.

In the semiconductor device 100 according to the present embodiment, the capping metal layer 125 of the first gate structure 120a may be formed of the same material as or a different material from that of the capping metal layer 125 of the second gate structure 120b. Similarly, the work function metal layer 127 of the first gate structure 120a may be formed of the same material as or a different material from that of the work function metal layer 127 of the second gate structure 120b.

In the semiconductor device 100 according to the present embodiment, the first gate structure 120a and the second gate structure 120b may be formed at the same time, and layers of the first gate structure 120a and layers of the second gate structure 120b corresponding respectively thereto may be substantially simultaneously formed by a one-time process. For example, the interfacial layer 121, the high-k dielectric layer 123, the capping metal layer 125, and the work function metal layer 127 of the first gate structure 120a may be respectively formed simultaneously with the interfacial layer 121, the high-k dielectric layer 123, the capping metal layer 125, and the work function metal layer 127 of the second gate structure 120b. Thus, layers of the first gate structure 120a may be formed of the same materials as layers of the second gate structure 120b corresponding thereto. In some embodiments, layers of the first gate structure 120a and the corresponding layers of the second gate structure 120b can be formed simultaneously. For example, each of the interfacial layer 121, the high-k dielectric layer 123, the capping metal layer 125, and the work function metal layer 127 of the first gate structure 120a and each of the interfacial layer 121, the high-k dielectric layer 123, the capping metal layer 125, and the work function metal layer 127 of the second gate structure 120b may be subjected to the same etching process to form the first gate structure 120a and the second gate structure 120b via patterning such material layers, whether using a single etchant or multiple etchants. For instance, the single etchant process may occur in situ in the same process chamber without a vacuum break.

In addition, when layers of the first gate structure 120a are formed of the same materials as layers of the second gate structure 120b corresponding respectively thereto, as described above, the second gate structure 120b may further include the dielectric layer 126 and inhibit a work function control function of the capping metal layer 125. Thus, a threshold voltage Vth of the first gate structure 120a may be different from a threshold voltage Vth of the second gate structure 120b.

Alternatively, layers of the first gate structure 120a may be formed of different materials from layers of the corresponding second gate structure 120b. In this case, threshold voltages of the first gate structure 120a and the second gate structure 120b may be variously changed. For instance, a threshold voltage Vth of the first gate structure 120a may be independent of a threshold voltage Vth of the second gate structure 120b.

In some embodiments, the work function metal layer 127 of the first gate structure 120a may be formed of a material having a different work function from that of the work function metal layer 127 of the second gate structure 120b so that the first gate structure 120a and the second gate structure 120b may have different threshold voltages. Also, a threshold voltage Vth of the second gate structure 120b, which includes the dielectric layer 126, may be changed by variously modifying a material, a thickness, and a structure of the dielectric layer 126. However, the disclosed concepts are not limited thereto, and threshold voltages of the first gate structure 120a and the second gate structure 120b may be changed by forming the interfacial layer 121, the dielectric layer 123, or the capping metal layer 125 of the first gate structure 120a by using a different material from the interfacial layer 121, the high-k dielectric layer 123, and/or the capping metal layer 125 of the second gate structure 120b. In some embodiments, since forming the corresponding layers at the same time using a one-step process may be advantageous in terms of process efficiency and costs, process efficiency, costs, and diversification of threshold voltages may be considered when determining the materials that form the layers.

For reference, a threshold voltage Vth of a transistor may be obtained by the following equation:

Vth=φms−(Qox+Qd)/Cox+2φf, Equation 1:

wherein φms denotes a work function (potential) difference between a metal forming a gate and a semiconductor forming a channel, Qox denotes a fixed charge in a surface of a gate oxide layer, Qd denotes a positive charge in an ionic layer, Cox denotes a capacitance per unit area of the gate, and φf denotes a potential difference between an intrinsic Fermi level Ei and a Fermi level Ef of a semiconductor.

According to Equation 1, any of the following methods may be performed to control the threshold voltage Vth of the transistor. First, a method of controlling the work function difference φms may be used to control the threshold voltage Vth. Second, a method of controlling the fixed charge Qox may be used to control the threshold voltage Vth. Third, a method of controlling the potential difference φf may be used to control the threshold voltage Vth.

For example, the first method may be realized by doping ions into the semiconductor or by using a metal having a desired work function. That is, a work function of the semiconductor may be increased or reduced by doping ions to thereby correspondingly increase or reduce a difference in work function between the semiconductor and metal. Alternatively, a difference in work function between the semiconductor and the metal may be increased or reduced by using a metal having the desired work function.

The second method may be realized by increasing or reducing the fixed charge Qox. As shown in Equation 1, as the fixed charge Qox decreases, the threshold voltage Vth may decrease, whereas as the fixed charge Qox increases, the threshold voltage Vth may increase. Meanwhile, the fixed charge Qox may be expressed by the following equation:

Qox=∈₀∈_{R}/tox, Equation 2:

wherein ∈_{R} denotes a dielectric constant of the gate oxide layer and tox denotes a thickness of the gate oxide layer. Thus, to reduce the fixed charge Qox, the thickness tox of the gate oxide layer may be increased and/or a material having a low dielectric constant may be used. Also, the third method may be realized by doping ions into the semiconductor. For example, when a semiconductor layer is a p-type substrate, the potential difference φf may be increased by doping arsenide (As) into the p-type substrate.

As semiconductor devices become more highly integrated, channel regions may be further scaled. Thus, in an ion doping method, a distribution of threshold voltages may be degraded due to a non-uniform dopant distribution, and mobility may be degraded due to an increase in dopant concentration in a channel region. As a result, reliability and performance of the semiconductor devices may deteriorate. Thus, an ion implantation process may approach or reach a technical limit to controlling the threshold voltage Vth of the transistor. Also, in the method of using the metal with the desired work function, when forming transistors having different threshold voltages, for example, when a plurality of metal-oxide-semiconductor field-effect transistors (MOSFETs) having different threshold voltages are formed in a logic device, during a process of patterning a metal layer, it may be difficult to ensure an etch selectivity and a damage may be incurred to the gate oxide layer positioned under the metal layer.

Alternatively, the threshold voltage Vth of the transistor may be controlled by forming a metal electrode of a gate using several metal layers having different work functions. In some embodiments, each of the several metal layers may have a different work function, or some metal layers may have a same work function while other metal layers have different work functions. For instance, the threshold voltage Vth of the transistor may be controlled by forming the metal electrode by using a multi-layered structure including the capping metal layer 125 and the work function metal layer 127, such as the exemplary embodiments of the above-described first and second gate structures 120a and 120b. Included in the above-described method of using the metal having the desired work function, the threshold voltage Vth of the transistor may be controlled by forming the metal layer using several metal layers. Furthermore, a threshold voltage Vth of the second gate structure 120b may be further changed by forming the dielectric layer 126 between the capping metal layer 125 and the work function metal layer 127. Thus, for example, included in the method of using the metal having the desired work function, a threshold voltage Vth may be controlled by using the dielectric layer 126 because a work function of the metal electrode may be changed.

In the semiconductor device 100 according to the present embodiment, the first gate structure 120a, which does not include the dielectric layer 126, may be positioned in the first region A, and the second gate structure 120b including the dielectric layer 126 may be positioned in the second region B. When layers of the first gate structure 120a are formed of the same materials as layers of the second gate structure 120b corresponding respectively thereto, because the second gate structure 120b includes the dielectric layer 126, the threshold voltage Vth of the first gate structure 120a may be different from the threshold voltage Vth of the second gate structure 120b. Thus, the semiconductor device 100 according to the present embodiment may embody a logic device including transistors having various or multiple threshold voltages.

In the semiconductor device 100 according to the present embodiment, layers of the first gate structure 120a and respectively corresponding layers of the second gate structure 120b may be formed simultaneously by a one-time process, and transistors having different threshold voltages may be formed. Thus, the semiconductor device 100 according to the present embodiment may facilitate the manufacture of a logic device at lower costs and simpler processes.

Furthermore, in the semiconductor device 100 according to the present embodiment, any one layer (e.g., the work function metal layer 127) of the first gate structure 120a may be formed of a different material from that of the second gate structure 120b. Thus, threshold voltages of transistors may be variously changed, and a logic device including the transistors having varied or multiple threshold voltages may be embodied.

FIGS. 2A and 2B are graphs showing results of a shift of a threshold voltage Vth due to insertion of a dielectric layer between a capping metal layer and a work function metal layer. FIG. 2A shows a case in which the inserted dielectric layer is formed of lanthanum oxide (LaO), and FIG. 2b shows a case in which the inserted dielectric layer is formed of hafnium oxide (HfO) and titanium oxide (TiO). In FIGS. 2A and 2B, BG denotes a bandgap.

Referring to FIG. 2A, the flatband voltage Vfb when the dielectric layer is absent is illustrated by the symbol “-□-”, and the flatband voltage Vfb when a dielectric layer formed of LaO is used is illustrated by the symbol “-∘-”. As shown in FIG. 2A, when the dielectric layer formed of LaO is used, a flatband voltage Vfb is shifted leftward (illustrated by the leftward pointing arrow). The shift of the flatband voltage Vfb may be interpreted as a shift of a threshold voltage Vth.

For reference, a concept of a flatband voltage Vfb and a relationship between the flatband voltage Vfb and a threshold voltage Vth will now be briefly described. The flatband voltage Vfb refers to a gate bias voltage (i.e., denoted on the x-axis as “Gate Bias (V)”) to be applied to a gate electrode to flatten an energy band over a silicon substrate (i.e., denoted on the y-axis as “Normalized Capacitance”). In an ideal MOS structure, a flatband voltage Vfb may correspond to a work function difference φms between a gate electrode and silicon. However, in an actual MOS device, a voltage affected by a surface state between silicon and a gate oxide layer should be considered. For example, the flatband voltage Vfb of the actual MOS device may be obtained by subtracting a difference ΔVox between voltages of two ends of a MOS capacitor due to the surface state from an ideal flatband voltage φms.

Further, the flatband voltage Vfb may include the work function difference φms as a basic factor. Also, in view of the threshold voltage Vth being included in the work function difference φms as a basic factor in Equation 1, the flatband voltage Vfb may be proportional to the threshold voltage Vth to some extent. For example, as the flatband voltage Vfb increases, the threshold voltage Vth may increase, whereas as the flatband voltage Vfb decreases, the threshold voltage Vth may decrease.

The reason the flatband voltage Vfb (i.e., the threshold voltage Vth) is shifted due to the use of the dielectric layer will now be described. When the dielectric layer is not used, electrons may migrate between the capping metal layer and the work function control layer. Due to the migration of the electrons, the capping metal layer may serve a work function control function so that a threshold voltage Vth of the entire metal electrode may be controlled and determined. For example, the work function metal layer may be formed of a material having a relatively low work function, and the capping metal layer may be formed of a material having a relatively high work function. When the capping metal layer and the work function metal layer are stacked and in contact with each other, a work function of the work function metal layer may increase due to the migration of electrons. Thus, the threshold voltage Vth of the entire metal electrode may increase. In contrast, when the dielectric layer is used, the migration of electrons between the capping metal layer and the work function control layer may be prevented so that a work function control function of the capping metal layer may be reduced or inhibited. As in the above-described example, when the work function metal layer is formed of a material having a relatively low work function and the capping metal layer is formed of a material having a relatively high work function, the work function of the work function metal layer may not vary or may vary minutely. Thus, the threshold voltage of the entire metal electrode may be maintained at a low level. Thus, as shown in the example of FIG. 2A, when the dielectric layer is used, a threshold voltage Vth of a gate structure may be shifted leftward.

The shift of the flatband voltage Vfb or the threshold voltage Vth may depend on how much the dielectric layer effectively prevents the migration of electrons. For example, when the dielectric layer is formed of a material having a low bandgap, the migration of electrons may be prevented to a limited degree and the threshold voltage Vth may be shifted barely. In contrast, when the dielectric layer is formed of a material having a high bandgap, the migration of electrons may be effectively prevented so that the threshold voltage Vth may be shifted to a larger degree. For example, when the dielectric layer is formed of LaO having a high bandgap of about 4.0 eV, such as in the example of FIG. 2A, the flatband voltage Vfb may be shifted by as much as about 0.1 V or more.

Further, an electron blocking function of the dielectric layer may be understood to be a dielectric constant “k” of the dielectric layer instead of a bandgap of the dielectric layer. For example, when the dielectric layer is formed of a material having a high dielectric constant “k” (e.g., the dielectric layer has high conductive characteristics like a metal), the migration of electrons may be prevented to a limited degree and the threshold voltage Vth may be shifted barely. In contrast, when the dielectric layer is formed of a material having a low dielectric constant “k” (e.g., the dielectric layer has high non-conducting characteristics), the migration of electrons may be prevented effectively so that the threshold voltage Vth may be shifted to a larger degree.

FIG. 2B shows the shift of a flatband voltage Vfb in a case when an HfO dielectric layer is used (illustrated in FIG. 2B by “-◯-”) and a case in a TiO dielectric layer is used (illustrated in FIG. 2B by “-▴-”) as compared with a case in which the dielectric layer is absent (illustrated in FIG. 2B by “-□-”). Referring to FIG. 2B, when the HfO dielectric layer is used, the flatband voltage Vfb may be shifted by as much as about 0.2 V or more, as illustrated by the leftward pointing arrow. In contrast, when the TiO dielectric layer is used, as shown in FIG. 2B, the flatband voltage Vfb is shifted barely. Since the HfO dielectric layer has a very high bandgap (i.e., about 5.1 eV to about 5.5 eV), the migration of electrons may be prevented effectively and thereby inhibit or minimize a work function control function of the capping metal layer. Thus, the threshold voltage Vth may be shifted by a relatively large amount. In contrast, since the TiO dielectric layer has a relatively low bandgap (i.e., about 3.0 eV to about 3.5 eV), the migration of electrons may not be prevented effectively, and a work function control function of the capping metal layer may be maintained. Accordingly, the threshold voltage Vth may be shifted by a small amount.

Based on the above-described results, in the semiconductor device 100 according to the present embodiment, the dielectric layer 126 included in the second gate structure 120b may be formed of a material having a bandgap of about 4.0 eV or more. Also, since the dielectric layer 126 is formed of the material having the bandgap of about 4.0 eV or more, a threshold voltage Vth of the second gate structure 120b may be shifted an effective amount. Thus, the semiconductor device 100 according to the present embodiment may easily embody a logic device including transistors having various or multiple threshold voltages.

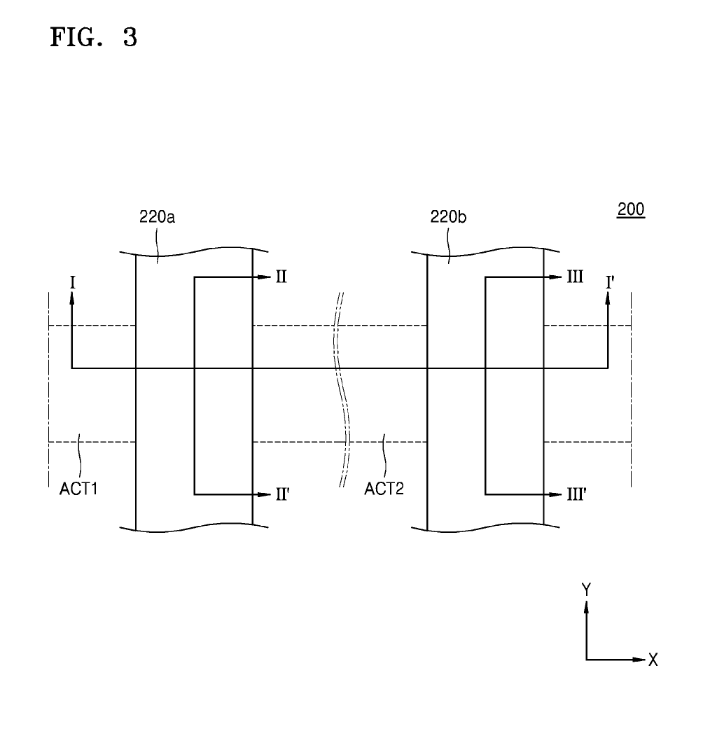

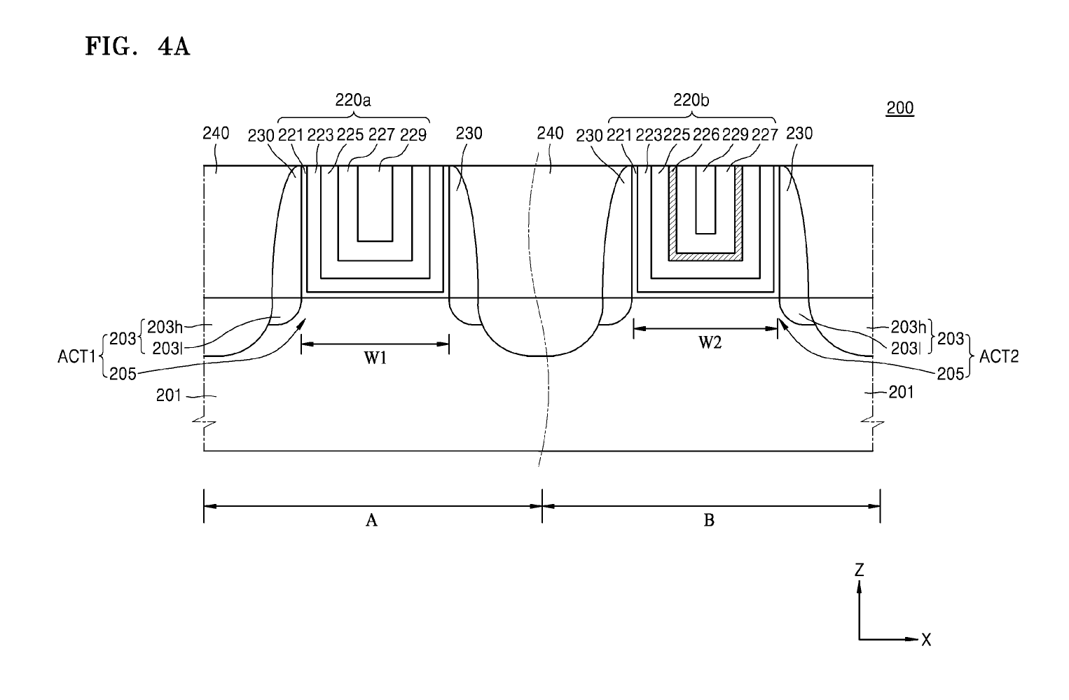

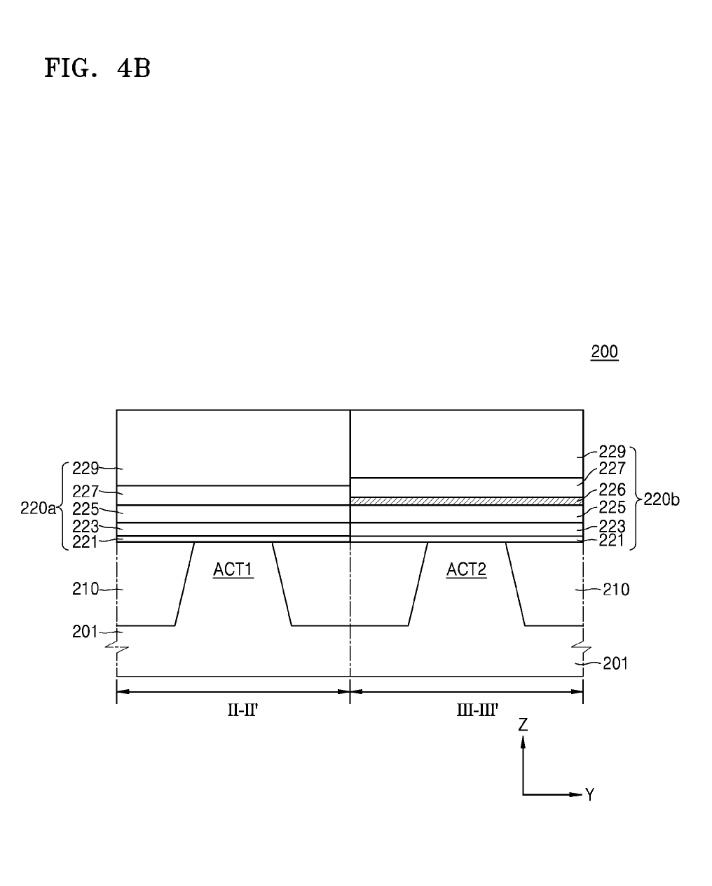

FIG. 3 is a plan view of a semiconductor device 200 in which a multi-threshold voltage Vth is embodied by controlling a work function, according to exemplary embodiments. FIG. 4A is a cross-sectional view of the semiconductor device 200 of FIG. 3 taken along a line I-I′ of FIG. 3. FIG. 4B is a cross-sectional view of the semiconductor device of FIG. 3 taken along lines and of FIG. 4. The same descriptions as in FIG. 1 will be simplified or omitted for brevity.

Referring to FIGS. 3, 4A, and 4B, a semiconductor device 200 according to the present embodiment may include a semiconductor substrate 201 and first and second gate structures 220a and 220b. The semiconductor substrate 201 may include a first region A and a second region B. Also, first and second active regions ACT1 and ACT2 extending in a first direction (e.g., x-direction) may be defined by a device isolation layer 210 on an upper region of the semiconductor substrate 201. The first and second active regions ACT1 and ACT2 may include the first active region ACT1 of the first region A and the second active region ACT2 of the second region B.

The first and second gate structures 220a and 220b may extend in a second direction (e.g., y-direction), and may be arranged on the semiconductor substrate 201 across the first and second active regions ACT1 and ACT2 corresponding thereto. For example, the gate structures 220a and 220b may include a first gate structure 220a of the first region A and a second gate structure 220b of the second region B. Thus, the first gate structure 220a may be arranged on the semiconductor substrate 201 across the first active region ACT1, and the second gate structure 220b may be arranged on the semiconductor substrate 201 across the second active region ACT2.

As illustrated in FIG. 3, the first and second active regions ACT1 and ACT2 may intersect their respectively corresponding first and second gate structures 220a and 220b at right angles. However, the first and second active regions ACT1 and ACT2 may intersect their respectively corresponding first and second gate structures 220a and 220b at angle other than a right angle. Also, in FIG. 3, a single first active region ACT1 may intersect a single first gate structure 220a, and a single second active region ACT2 may intersect a single second gate structure 220b, but the disclosed concepts are not limited thereto. For example, a plurality of first gate structures 220a may intersect a single first active region ACT1, while a plurality of second gate structures 220b may intersect a single second active region ACT2. Also, a plurality of first active regions ACT1 may intersect a single first gate structure 220a, while a plurality of second active regions ACT2 may intersect a single second gate structure 220b. Furthermore, although the first active region ACT1 of the first region A and the second active region ACT2 of the second region B extend in the same first direction (e.g., x-direction), the first active region ACT1 of the first region A and the second active region ACT2 of the second region B may extend in other and/or different directions. Also, the first gate structure 220a of the first region A and the second gate structure 220b of the second region B may extend in other and/or different directions.

The semiconductor substrate 201 may be the same as the semiconductor substrate 101, as disclosed and described in connection with FIG. 1.

As described above, the device isolation layer 210 may be formed to define the first and second active regions ACT1 and ACT2 and surround the active regions ACT1 and ACT2. Also, the device isolation layer 210 may be interposed between the first and second active regions ACT1 and ACT2 and electrically isolate the first and second active regions ACT1 and ACT2 from each other. The device isolation layer 210 may include for example, at least one of silicon oxide layer, silicon nitride layer, silicon oxynitride layer, or a combination thereof. Meanwhile, each of the active regions ACT1 and ACT2 may include source and drain regions 203 and a channel region 205. The source and drain regions 203 may include a heavily doped region 203h and a lightly doped region 203l.

Unlike the semiconductor device 100 of FIG. 1, the semiconductor device 200 according to the present embodiment may include first and second gate structures 220a and 220b, which are replacement metal gate (RMG) structures. The formation of an RMG structure may include forming source and drain regions 203 by using a dummy gate structure and forming a metal gate in a portion from which the dummy gate structure is removed. The RMG structure also may be referred to as a gate-last structure.

More specifically, spacers 230 may be formed on both sidewalls of each of the first gate structure 220a and the second gate structure 220b. Also, the spacers 230 may be surrounded by an interlayer insulating layer 240. The spacers 230 may be formed of an insulating layer, such as a nitride layer or an oxynitride layer. For example, the spacers 230 may include a silicon nitride layer or a silicon oxynitride layer. In some embodiments, although not illustrated in FIG. 4A, each of the spacers 230 may be formed to have an L-shape cross section (with respect to a cross sectional view taken in the vertical direction). Also, the spacers 230 may include a single layer, but the disclosed concepts are not limited thereto and the spacers 230 may have a multi-layered structure.

Meanwhile, the interlayer insulating layer 240 may be formed on portions of the semiconductor substrate 201 on which the gate structures 220a and 220b and the spacers 230 are not formed. Thus, the interlayer insulating layer 240 may surround side surfaces of the spacers 230. For example, the interlayer insulating layer 240 may extend from the side surface of a first spacer 230 to the side surface of a second or other spacer 230. The interlayer insulating layer 240 may include at least one of a silicon oxide layer, a silicon nitride layer, a silicon oxynitride layer, or a combination thereof, and may be formed of a material having an etch selectivity with respect to the spacers 230.

The first gate structure 220a may include an interfacial layer 221, a high-k dielectric layer 223, a capping metal layer 225, a work function metal layer 227, and a gap-fill metal layer 229. A layered structure of the first gate structure 220a may be substantially similar to that of the first gate structure 120a of the semiconductor device 100 of FIG. 1. However, since the first gate structure 220a is the RMG structure, each of layers forming the first gate structure 220a may be formed to surround a top surface of the semiconductor substrate 201 and side surfaces of the spacers 230. For example, the interfacial layer 221 may be formed on the top surface of the semiconductor substrate 201 and the side surfaces of the spacers 230, and the high-k dielectric layer 223 may be formed on a top surface of a bottom portion and both side surfaces of the interfacial layer 221. Also, the capping metal layer 225, the work function metal layer 227, and the gap-fill metal layer 229 may be sequentially formed on a top surface of a bottom portion and both side surfaces of the underlying layer thereof. Materials and functions of respective layers forming the first gate structure 220a may be the same as in the semiconductor device 100 described in connection with FIG. 1. Further, as illustrated in FIG. 4A, the gap-fill metal layer 229 may fill a trench or a gap that remains after the work function metal layer 227 is formed.

The second gate structure 220b may include an interfacial layer 221, a high-k dielectric layer 223, a capping metal layer 225, a dielectric layer 226, a work function metal layer 227, and a gap-fill metal layer 229. A layered structure of the second gate structure 220b may also be generally similar to that of the second gate structure 120b of the semiconductor device 100 of FIG. 1. However, since the second gate structure 220b is the RMG structure, each of layers forming the second gate structure 220b may surround the top surface of the semiconductor substrate 201 and side surfaces of the spacers 230. For example, the interfacial layer 221 may be formed on the top surface of the semiconductor substrate 201 and the side surfaces of the spacers 230, while the high-k dielectric layer 223 may be formed on the top surface of a bottom portion and both side surfaces of the interfacial layer 221. Similarly, the capping metal layer 225, the dielectric layer 226, the work function metal layer 227, and the gap-fill metal layer 229 may be sequentially formed on a top surface of a bottom portion and both side surfaces of the underlying layer thereof. Further, since the second gate structure 220b further includes the dielectric layer 226, a width of the gap-fill metal layer 229 of the second gate structure 220b may be less than a width of the gap-fill metal layer 229 of the first gate structure 220a. In some embodiments, although not illustrated in FIGS. 4A and 4B, the gap-fill metal layer 229 of the second gate structure 220b may be omitted. In addition, materials or functions of respective layers constituting the second gate structure 220b may be the same as in the semiconductor device 100 described in connection with FIG. 1.

Referring again to FIG. 4A, the first gate structure 220a may have a gate width of a first width W1, and the second gate structure 220b may have a gate width of a second width W2. Here, a gate width corresponds to a distance as measured between the two spacers 230 formed on either side of the gate structure, and may be substantially equal to a channel length. Further, according to the layout of the semiconductor device 200, the gate width of first gate structure 220a may be in the same direction as, or a different direction from, the gate width of the second gate structure 220b. Also, the first width W1 of the first gate structure 220a may be equal to or different from the second width W2 of the second gate structure 220b. For example, the first width W1 of the first gate structure 220a may be greater or less than the second width W2 of the second gate structure 220b. When the first width W1 of the first gate structure 220a is equal to the second width W2 of the second gate structure 220b, since the second gate structure 220b further includes the dielectric layer 226 as described above, a width of the gap-fill metal layer 229 of the second gate structure 220b may be less than a width of the gap-fill metal layer 229 of the first gate structure 220a.

In the semiconductor device 200 according to the present embodiment, the first gate structure 220a in which the dielectric layer 226 is not formed may be positioned in the first region A, and the second gate structure 220b including the dielectric layer 226 may be positioned in the second region B. Also, when layers of the first gate structure 220a are formed of the same materials as layers of the second gate structure 220b corresponding respectively thereto, since the second gate structure 220b includes the dielectric layer 226, a threshold voltage Vth of the first gate structure 220a may be different from a threshold voltage Vth of the second gate structure 220b. Thus, the semiconductor device 200 according to the present embodiment may easily embody a logic device including transistors having various or multiple threshold voltages.

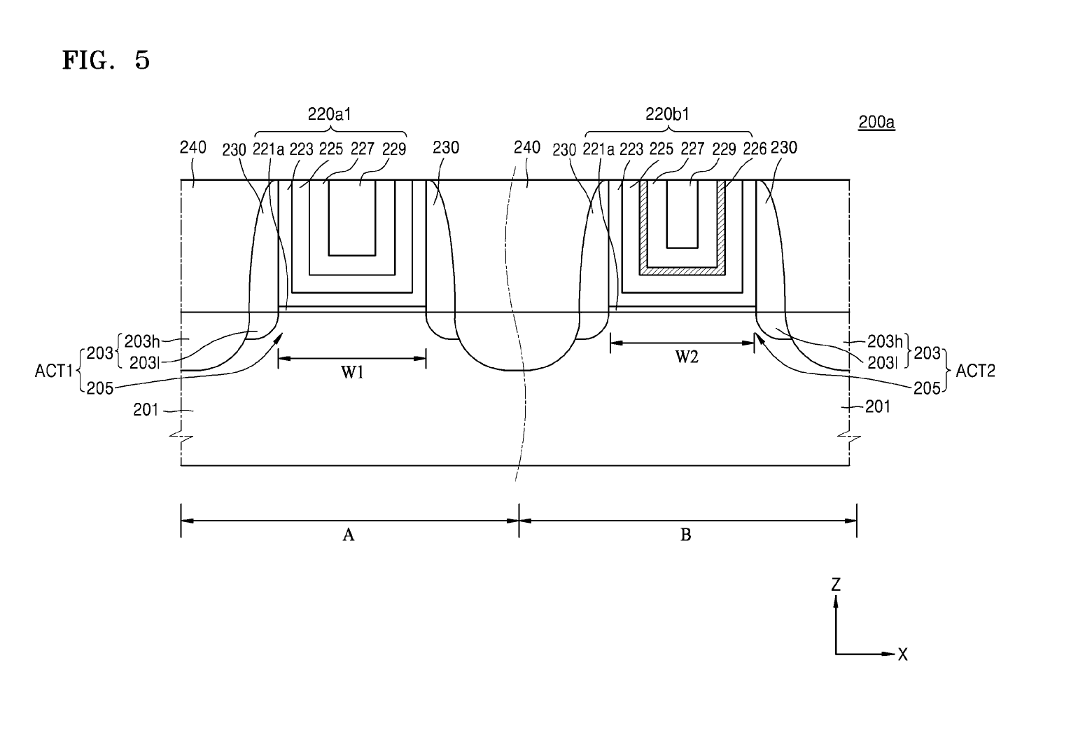

FIGS. 5 to 12 are cross-sectional views of semiconductor devices according to exemplary embodiments, which correspond to FIG. 4A. The same descriptions as in FIGS. 1, 3, 4A, and 4B will be simplified or omitted for brevity.

Referring to FIG. 5, a semiconductor device 200a according to the present embodiment may be the same as the semiconductor device 200 of FIG. 4A except for a structure of an interfacial layer 221a. In the semiconductor device 200a according to the present embodiment, the interfacial layer 221a of each of the first gate structure 220a1 and a second gate structure 220b1 may be formed only on a top surface of a semiconductor substrate 201 but not formed on side surfaces of spacers 230. However, in an alternative example of FIG. 5, the interfacial layer may also be formed on the side surfaces of spacer 230. A dummy insulating layer of a dummy gate structure may not be removed, but may be used as an interfacial layer to form the interfacial layer 221a. Since the interfacial layer 221a is formed only on the semiconductor substrate 201 and does not extend upward, for the same sized width between sidewall spacers 230 (here, W1 and W2), the distance between corresponding side surfaces of respective layers constituting each of the first gate structure 220a1 and the second gate structure 220b1 may increase (as compared to their locations as shown in FIG. 4A) and thereby allow for an increased width or thickness of the gap-fill metal layer 229. For instance, when interfacial layer 221a is formed only on the semiconductor substrate 201, the width of gap-fill metal layer 229 may be increased without causing a corresponding increase in the first width W1 and the second W2.

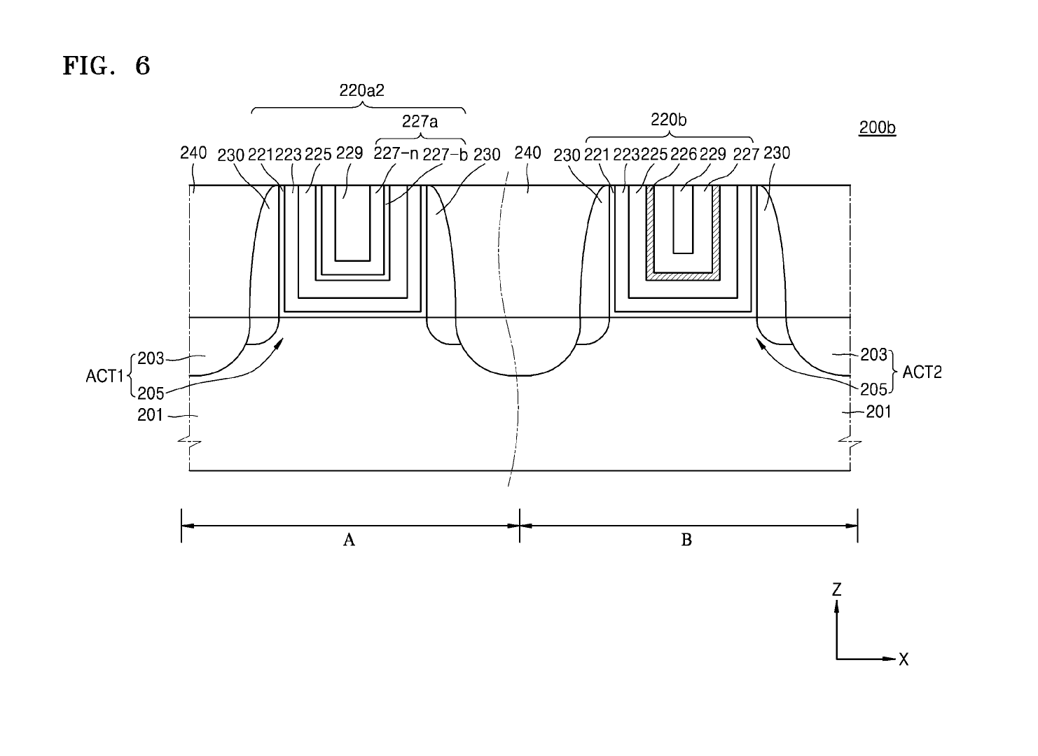

Referring to FIG. 6, a semiconductor device 200b according to the present embodiment may differ from the semiconductor device 200 of FIG. 4A in that a work function metal layer 227a of a first gate structure 220a2 includes a barrier metal layer 227-b and an n-type metal layer 227-n. The barrier metal layer 227-b may be formed of a material having a large work function. For example, the barrier metal layer 227-b may be formed of a p-type metal having a large work function. The barrier metal layer 227-b may prevent diffusion of atoms or ions between the capping metal layer 225 and the n-type metal layer 227-n. Also, the barrier metal layer 227-b may inhibit a work function of the work function metal layer 227a from excessively increasing due to the capping metal layer 225. For instance, the n-type metal layer 227-n, the barrier metal layer 227-b, and the capping metal layer 225 may have sequentially higher work functions. Accordingly, the barrier metal layer 227-b may buffer a work function control function of the capping metal layer 225.

The barrier metal layer 227-b may include at least one metal selected from Ti, Ta, W, Ru, Nb, Mo, and Hf or a metal nitride. The barrier metal layer 227-b may have a thickness of several nm or less. The barrier metal layer 227-b may include a single layer or a multi-layered structure including at least two layers.

For reference, since the barrier metal layer 227-b is formed of a metal, the barrier metal layer 227-b may not effectively prevent migration of electrons unlike the dielectric layer 226 of the second gate structure 220b. Thus, the barrier metal layer 227-b may function to prevent diffusion of atoms or ions between the capping metal layer 225 and the n-type metal layer 227-n while still allowing the migration of electrons.

Typically, when an n-type metal layer and a p-type metal layer are stacked, a lower metal layer may serve as a work function metal layer more significantly than an upper metal layer. Accordingly, when the barrier metal layer 227-b is formed of a p-type metal, the barrier metal layer 227-b may serve to control a work function of the work function metal layer 227a. However, in the semiconductor device 200b according to the present embodiment, since the barrier metal layer 227-b positioned in the first gate structure 220a2 is formed to a very small thickness, even if the barrier metal layer 227-b is formed of the p-type metal, the barrier metal layer 227-b may not serve to control the work function of the work function metal layer 227a to the same extent as in the above-described case in which the n-type metal layer and the p-type metal layer are stacked.

Meanwhile, the work function metal layer 227 of the second gate structure 220b may be formed of an n-type metal and may be formed of the same material as the work function metal layer 227-n of the first gate structure 220a2. Accordingly, the work function metal layer 227 of the second gate structure 220b and the n-type metal layer 227-n of the first gate structure 220a2 may be simultaneously formed from the same deposited metal layer using a one-time process. However, a material of the work function metal layer 227 of the second gate structure 220b may not be limited to the n-type metal. For example, in some embodiments, the work function metal layer 227 of the second gate structure 220b may be formed of a p-type metal. In certain embodiments, even if the work function metal layer 227 of the second gate structure 220b is formed of an n-type metal, the work function metal layer 227 may be formed of a material having a different work function from the work function metal layer 227-n of the first gate structure 220a2.

In addition, although not shown, a barrier metal layer may be formed between the work function metal layer 227 and the gap-fill metal layer 229. In some cases, the barrier metal layer may take the place of the gap-fill metal layer 229. In this case, an additional gap-fill metal layer may not be formed. Also, in some embodiments, a barrier metal layer may be formed between the high-k dielectric layer 223 and the capping metal layer 225. When the barrier metal layer is formed between the high-k dielectric layer 223 and the capping metal layer 225, however, it may prevent diffusion of atoms or ions of the capping metal layer 225 into the high-k dielectric layer 223.

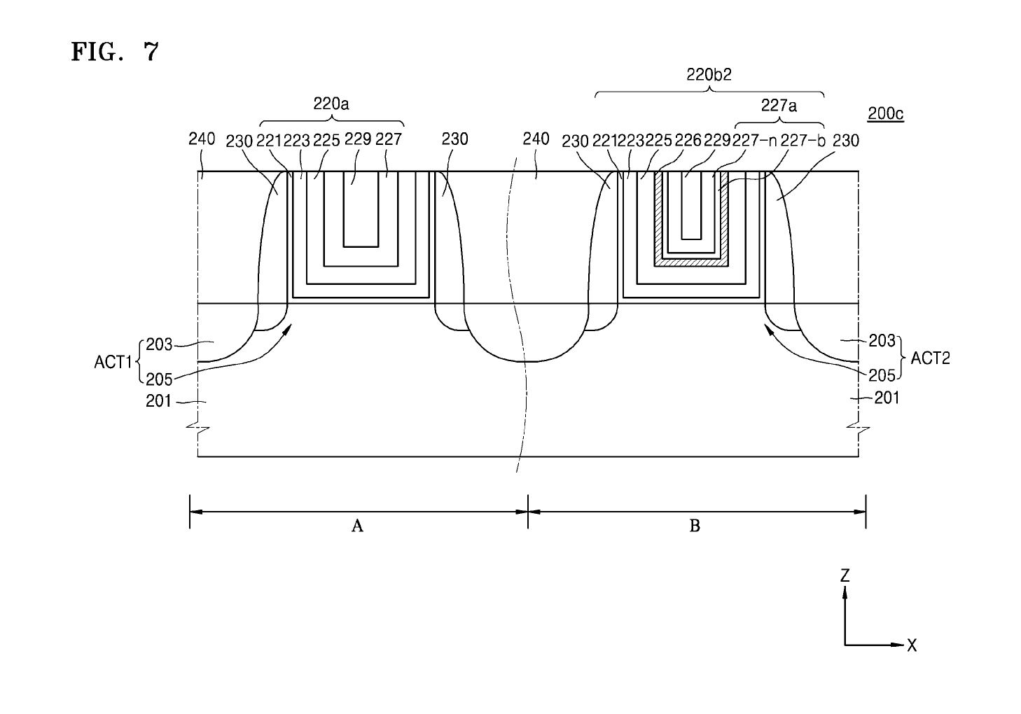

Referring to FIG. 7, a semiconductor device 200c according to the present embodiment may differ from the semiconductor device 200 of FIG. 4A in that a work function metal layer 227a of a second gate structure 220b2 includes a barrier metal layer 227-b and an n-type metal layer 227-n. Materials and functions of the barrier metal layer 227-b and the n-type metal layer 227-n may be the same as the barrier metal layer 227-b and the n-type metal layer 227-n of the semiconductor device 200b of FIG. 6. However, in the second gate structure 220b2, the barrier metal layer 227-b may be interposed between the dielectric layer 226 and the n-type metal layer 227-n. Thus, the barrier metal layer 227-b of FIG. 7 may prevent diffusion of atoms or ions of the n-type metal layer 227-n into the dielectric layer 226, rather than diffusion of atoms or ions between the capping metal layer 225 and the n-type metal layer 227-n.

As described above, since the second gate structure 220b2 includes the barrier metal layer 227-b, a function of the dielectric layer 226 may be maintained in better form. Accordingly, a shift of a threshold voltage in the second gate structure 220b2 may be distinctly achieved. Also, a thickness of the dielectric layer 226 may be reduced due to the presence of the barrier metal layer 227-b to minimize an action of the dielectric layer 226 as a resistor.

Further, the work function metal layer 227 of the first gate structure 220a and the n-type metal layer 227-n of the second gate structure 220b2 may both be formed of an n-type metal. However, in some embodiments, a material of the work function metal layer 227 of the first gate structure 220a is not limited to an n-type metal. Also, in certain embodiments, even if the work function metal layer 227 of the first gate structure 220a is formed of an n-type metal, the work function metal layer 227 may be formed of a different material from the n-type metal layer 227-n of the second gate structure 220b2. Thus, the work function metal layer 227 and the n-type metal layer 227-n may have different work functions.

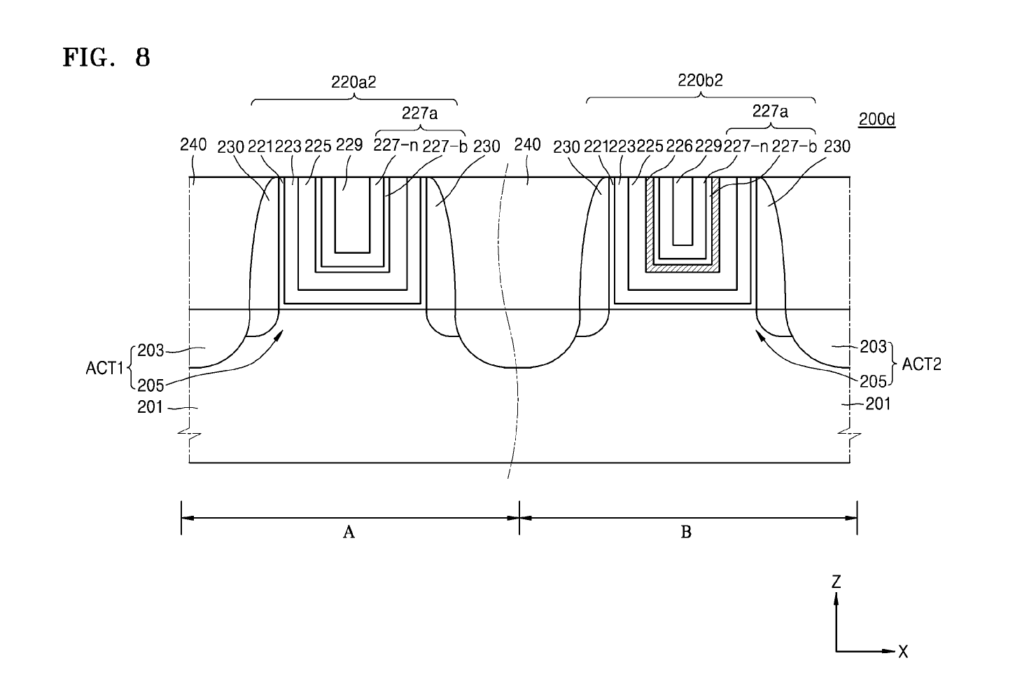

Referring to FIG. 8, a semiconductor device 200d according to the present embodiment may differ from the semiconductor device 200 of FIG. 4A in that a work function metal layer 227a of a first gate structure 220a2 includes a barrier metal layer 227-b and an n-type metal layer 227-n and a work function metal layer 227a of a second gate structure 220b2 includes a barrier metal layer 227-b and an n-type metal layer 227-n. The semiconductor device 200d according to the present embodiment may be interpreted as a combination of the first gate structure 220a2 of the semiconductor device 200b of FIG. 6 and the second gate structure 220b2 of the semiconductor device 200c of FIG. 7.

Thus, the work function metal layer 227a of the first gate structure 220a2 may be the same as the work function metal layer 227a of the first gate structure 220a2 of the semiconductor device 200b that is described in connection with FIG. 6, and the work function metal layer 227a of the second gate structure 220b2 may be the same as the work function metal layer 227a of the second gate structure 220b2 of the semiconductor device 200c that is described in connection with FIG. 7.

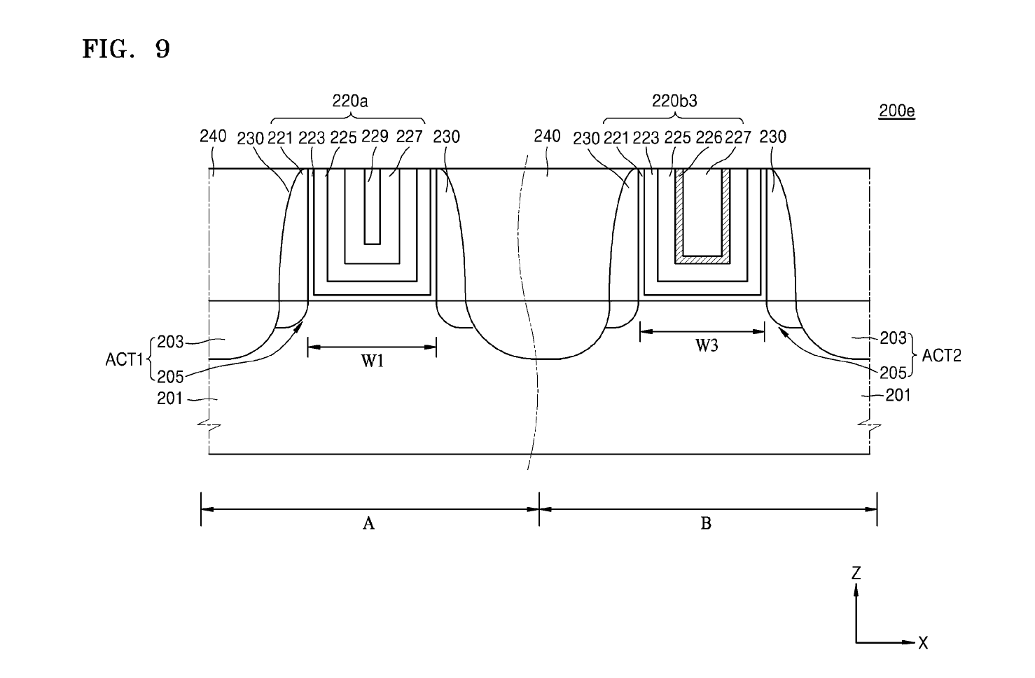

Referring to FIG. 9, a semiconductor device 200e according to the present embodiment may differ from the semiconductor device 200 of FIG. 4A in that a second gate structure 220b3 does not include a gap-fill metal layer 229. In other words, the second gate structure 220b3 may include an interfacial layer 221, a high-k dielectric layer 223, a capping metal layer 225, a dielectric layer 226, and a work function metal layer 227. Meanwhile, the first gate structure 220a may be the same as the first gate structure 220a of FIG. 4A. For example, the first gate structure 220a may include a gap-fill metal layer 229.

In the semiconductor device 200e according to the present embodiment, a gate width of the second gate structure 220b3 may have a third width W3. The third width W3 of the second gate structure 220b3 may be less than the first width W1 of the first gate structure 220a. Also, since the second gate structure 220b3 includes the dielectric layer 226, when the work function metal layer 227 is formed on the dielectric layer 226, a gap may be completely filled and the gap-fill metal layer 229 may not be formed.

In some embodiments, the first gate structure 220a may have the third width W3 equal to the third gate width W3 of the second gate structure 220b3. However, since the first gate structure 220a does not include the dielectric layer 226, the first gate structure 220a may still include the gap-fill metal layer 229. Although not illustrated in FIG. 9, in some cases, the first gate structure 220a may not include the gap-fill metal layer 229.

In addition, a barrier metal layer 227 may be formed between the work function metal layer 227 and the gap-fill metal layer 229 of the first gate structure 220a. In this case, the second gate structure 220b3 may include only the barrier metal layer 227 formed on the work function metal layer 227 but may not include a gap-fill metal layer 229.

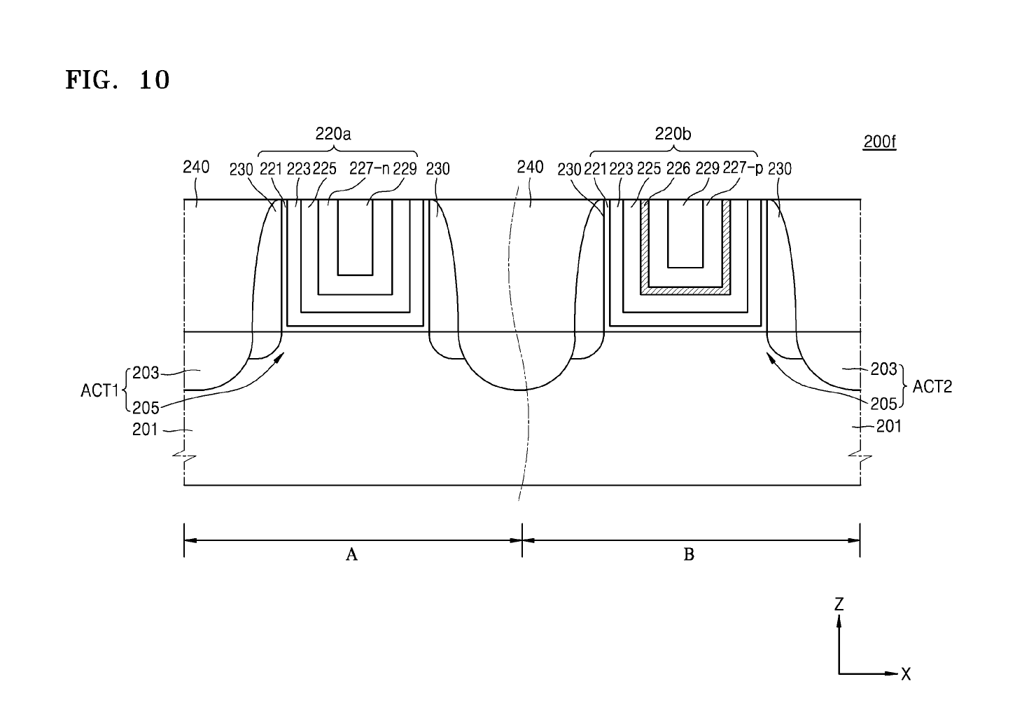

Referring to FIG. 10, in the semiconductor device 200f according to the present embodiment, the work function metal layer 227-n of the first gate structure 220a may be formed of an n-type metal, and the work function metal layer 227-p of the second gate structure 220b may be formed of a p-type metal. Accordingly, the first gate structure 220a may constitute an NMOS transistor, while the second gate structure 220b may constitute a PMOS transistor. Characteristics or kinds of the n-type metal and the p-type metal may be the same as those of the semiconductor device 100, as disclosed and described in connection with FIG. 1.

In the semiconductor device 200f according to the present embodiment, the second gate structure 220b may include a dielectric layer 226 interposed between the capping metal layer 225 and the work function metal layer 227-p. Accordingly, a threshold voltage Vth of the second gate structure 220b may be not only different from a threshold voltage Vth of the first gate structure 220a but also different from a threshold voltage Vth of another gate structure constituting a PMOS transistor.

As described above, in the semiconductor device 200f according to the present embodiment, the work function metal layers 227 of respective gate structures may be formed of different materials, and each of the gate structures may selectively include the dielectric layer 226 so that transistors having various or multiple threshold voltages may be formed. Thus, the semiconductor device 200f according to the present embodiment may be usefully applied to logic devices that demand transistors having various or multiple threshold voltages.

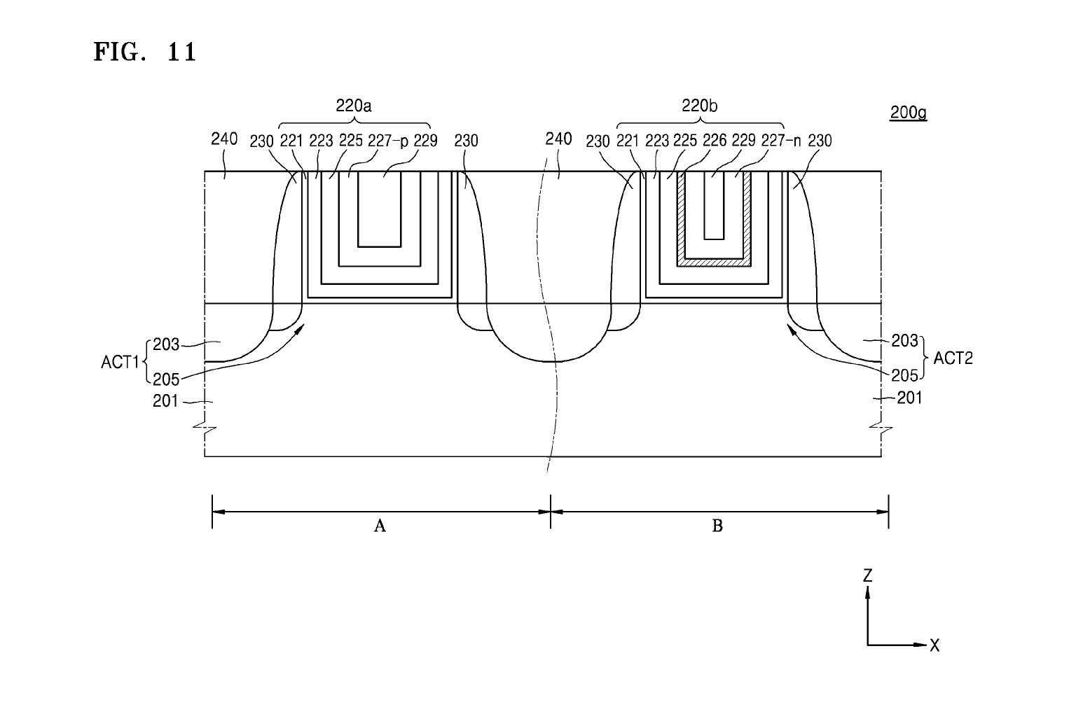

Referring to FIG. 11, a semiconductor device 200g according to the present embodiment may be different from the semiconductor device 200f of FIG. 10 in that a work function metal layer 227-p of a first gate structure 220a is formed of a p-type metal and a work function metal layer 227-n of a second gate structure 220b is formed of an n-type metal. In other words, in contrast to the semiconductor device 200f of FIG. 10, in the semiconductor device 200g according to the present embodiment, the first gate structure 220a may constitute a PMOS transistor, while the second gate structure 220b may constitute an NMOS transistor.

The semiconductor device 200g according to the present embodiment may be usefully applied to embody transistors having various or multiple threshold voltages, similar to the semiconductor device 200f of FIG. 10. For example, since the second gate structure 220b includes the dielectric layer 226 interposed between the capping metal layer 225 and the work function metal layer 227-n, a threshold voltage Vth of the second gate structure 220b may be not only different from a threshold voltage Vth of the first gate structure 220a but also different from a threshold voltage Vth of another gate structure constituting an NMOS transistor.

Meanwhile, FIGS. 10 and 11 show the semiconductor devices 200f and 200g in which work function metal layers of the first gate structure 220a and the second gate structure 220b (e.g., 227-p and 227-n) are formed of different materials, but the disclosed concepts are not limited thereto. For example, different threshold voltages may be embodied by varying materials of the high-k dielectric layer 223 or the capping metal layer 225.

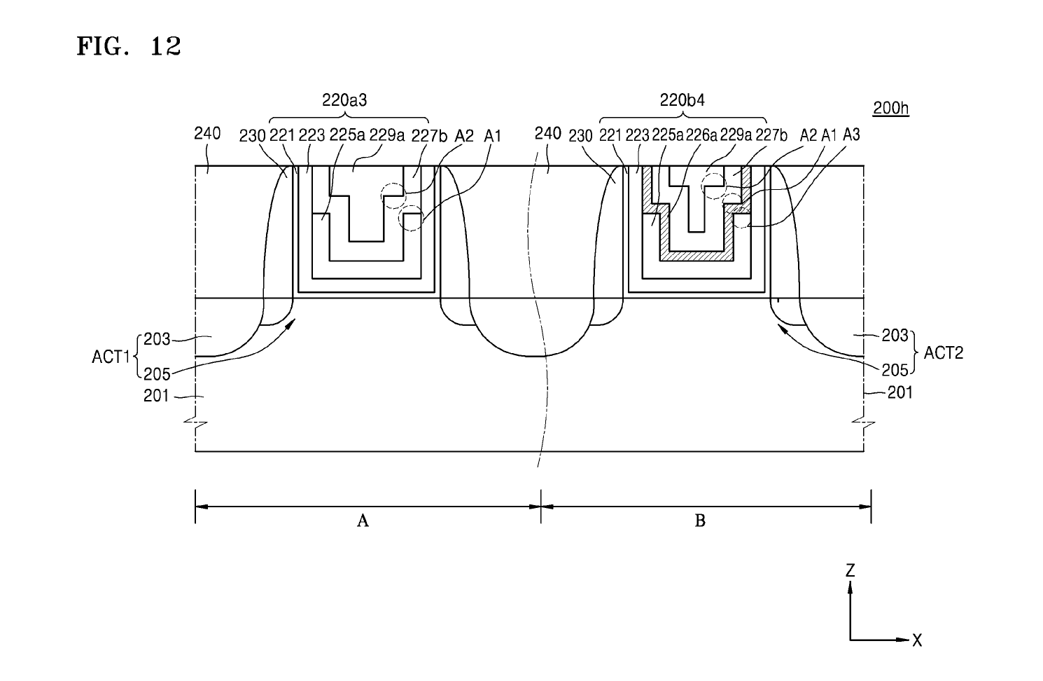

Referring to FIG. 12, a semiconductor device 200h according to the present embodiment may be different from the semiconductor devices according to the above-described embodiments in structures of a first gate structure 220a3 and a second gate structure 220b4. Specifically, a capping metal layer 225a of each of the first gate structure 220a3 and the second gate structure 220b4 may not be formed on the entire bottom and side surfaces of a high-k dielectric layer 223 but formed only on portions of bottom and side surfaces of the high-k dielectric layer 223. Thus, a top surface of a side portion of the capping metal layer 225a may be at a lower level than a top surface of a side portion of the high-k dielectric layer 223 and may not be exposed.

In the first gate structure 220a3, first and second stepped portions A1 and A2 (illustrated in FIG. 12 as being formed on a single side of the first gate structure 220a3) may be respectively formed on side surfaces of a work function metal layer 227b and a gap-fill metal layer 229a formed on the capping metal layer 225a due to a structure of the capping metal layer 225a. In other words, in the first gate structure 220a3, the side surface of the work function metal layer 227b may include the first stepped portion A1, which extends upward along the side surface of the capping metal layer 225a and covers a top surface of the side portion of the capping metal layer 225a, and extend again upward along the side surface of the high-k dielectric layer 223. Also, the gap-fill metal layer 229a of the first gate structure 220a3 may have the second stepped portion A2 and may be formed on the work function metal layer 227b. Further, although illustrated as being formed on the right side of the first gate structure 220a3, first and second stepped portions A1 and A2 may be formed on both sides of the first gate structure 220a3. The gap-fill metal layer 229a of the first gate structure 220a3 may be naturally formed to fill a gap that remains after the work function metal layer 227b is formed.

Further, the second gate structure 220b4 may include a dielectric layer 226a, which may have a third stepped portion A3 due to a structure of the capping metal layer 225a. For example, second gate structure 220b4 may include first stepped portion A1, second stepped portion A2, and third stepped portion A3. Although illustrated as being formed on the right side of the second gate structure 220b4, first, second and third stepped portions A1, A2 and A3 may be formed on both sides of the second gate structure 220b4. Also, the work function metal layer 227b and the gap-fill metal layer 229a formed on the dielectric layer 226a may respectively have a first stepped portion A1 and a second stepped portion A2 due to the third stepped portion A3 of the dielectric layer 226a.

In a structure of the semiconductor device 200h according to the present embodiment, a volume occupied by the gap-fill metal layer 229a in each of the first and second gate structures 220a3 and 220b4 may increase. Thus, resistances of the first and second gate structures 220a3 and 220b4 may be reduced and thereby contribute toward reducing a delay time of a gate electrode. In particular, the resistance of the second gate structure 220b4 may increase due to the use of the dielectric layer 226. However, since the second gate structure 220b4 is formed to have an increased or larger volume occupied by the gap-fill metal layer 229a, an increase in the delay time of the gate electrode due to an increase in resistance may be solved.

In addition, although the present embodiment describes an example in which a capping metal layer 225a has a buried structure being completely underneath the high-k dielectric layer 223, when a barrier metal layer is present between the high-k dielectric layer 223 and the capping metal layer 225a, the barrier metal layer 227b may have a buried structure, and upper layers including the capping metal layer 225a may have a stepped structure.

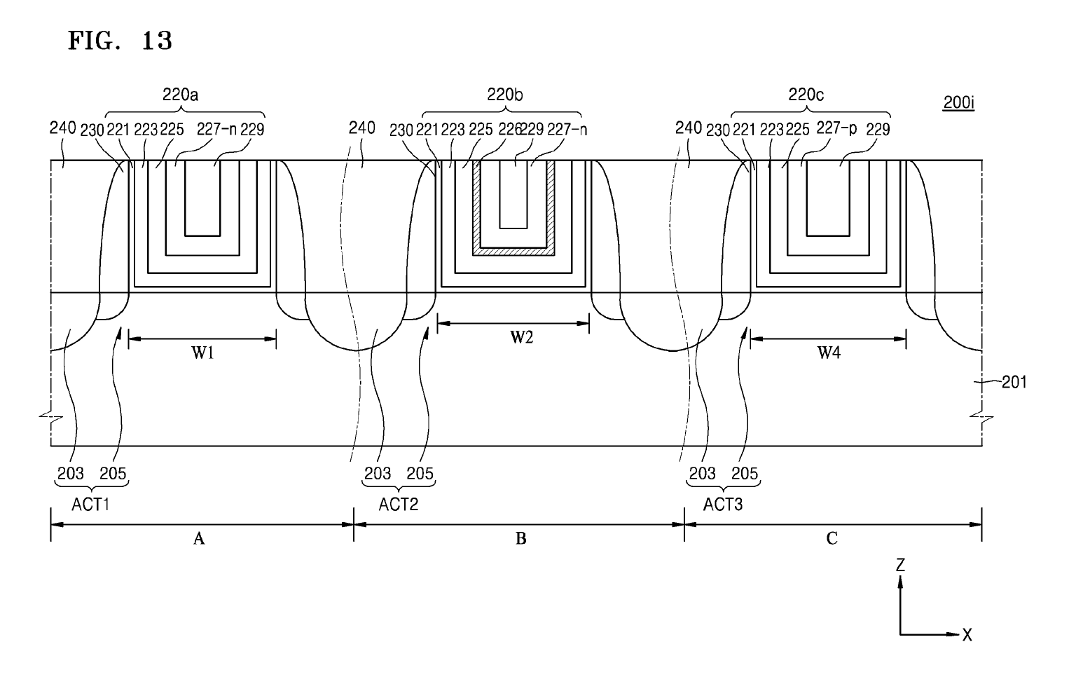

FIG. 13 is a cross-sectional view of semiconductor device according to an exemplary embodiment. Referring to FIG. 13, an exemplary semiconductor device 200i according to the present embodiment may include a semiconductor substrate 201 and gate structures (e.g., first, second, and third gate structures 220a, 220b, and 220c). The semiconductor substrate 201 may include a first region A, a second region B, and a third region C. Also, active regions (e.g., first, second, and third active regions ACT1, ACT2, and ACT3) may be defined by a device isolation layer 210 (not shown in FIG. 13) in an upper region of the semiconductor substrate 201. The active regions ACT1, ACT2, and ACT3 may include the first active region ACT1 of a first region A, the first active region ACT2 of a second region B, and the third active region ACT3 of a third region C.

The first, second, and third gate structures 220a, 220b, and 220c may be positioned respectively on the semiconductor substrate 201 across the first, second, and third active regions ACT1, ACT2, and ACT3. For example, the first, second, and third gate structures 220a, 220b, and 220c may include the first gate structure 220a of the first region A, the second gate structure 220b of the second region B, and the third gate structure 220c of the third region C.

The semiconductor substrate 201 may be the same as the semiconductor substrate 101, as disclosed and described in connection with FIG. 1. Further, each of the first, second, and third active regions ACT1, ACT2, and ACT3 may include source and drain regions 203 and a channel region 205. Also, although not shown, the source and drain regions 203 may include a heavily doped region (e.g., a heavily doped region 203h, such as that disclosed and described in connection with FIG. 4A) and a lightly doped region (e.g., a lightly doped region 203l, such as that disclosed and described in connection with FIG. 4A).

Spacers 230 may be formed on two side surfaces of each of the first gate structure 220a, the second gate structure 220b, and the third gate structure 220c. The spacers 230 may be surrounded with an interlayer insulating layer 240. Materials and shapes of the spacers 230 and the interlayer insulating layer 240 may be the same as, for example, the spacers 230 and interlayer insulating layer 240 of the semiconductor device 200, as described above in connection with FIG. 4A.

The first gate structure 220a may include an interfacial layer 221, a high-k dielectric layer 223, a capping metal layer 225, a work function metal layer 227-n, and a gap-fill metal layer 229. The work function metal layer 227-n of the first gate structure 220a may be formed of an n-type metal. Also, the second gate structure 220b may include the interfacial layer 221, the high-k dielectric layer 223, the capping metal layer 225, the dielectric layer 226, the work function metal layer 227-n, and the gap-fill metal layer 229. The work function metal layer 227-n of the second gate structure 220b may also be formed of an n-type metal. Meanwhile, the third gate structure 220c may include the interfacial layer 221, the high-k dielectric layer 223, the capping metal layer 225, a work function metal layer 227-p, and the gap-fill metal layer 229. The third gate structure 220c may be similar to the first gate structure 220a except that the work function metal layer 227-p is formed of a p-type metal.

The first gate structure 220a may have a gate width of a first width W1, the second gate structure 220b may have a gate width of a second width W2, and the third gate structure 220c may have a gate width of a fourth width W4. In some embodiments, the first width W1 of the first gate structure 220a, the second width W2 of the second gate structure 220b, and the fourth width W4 of the third gate structure 220c may be the same. Alternatively, in other embodiments, at least one of the first width W1 of the first gate structure 220a, the second width W2 of the second gate structure 220b, and the fourth width W4 of the third gate structure 220c may be different from one or more of the first width W1, second width W2, or third width W3. For example, the first width W1 of the first gate structure 220a may be equal to the second width W2 of the second gate structure 220b, and the fourth width W4 of the third gate structure 220c may be greater than the first width W1 of the first gate structure 220a. In some embodiments, when the first width W1 of the first gate structure 220a is equal to the second width W2 of the second gate structure 220b, since the second gate structure 220b further includes the dielectric layer 226, a width of the gap-fill metal layer 229 of the second gate structure 220b may be less than a width of the gap-fill metal layer 229 of the first gate structure 220a.

In the semiconductor device 200i according to the present embodiment, since the second gate structure 220b further includes the dielectric layer 226, a threshold voltage Vth of the second gate structure 220b may be different from a threshold voltage Vth of the first gate structure 220a. Also, the work function metal layers 227-n of the first gate structure 220a and the second gate structure 220b may be formed of an n-type metal, while the work function metal layer 227-p of the third gate structure 220c may be formed of a p-type metal. Thus, a threshold voltage Vth of the third gate structure 220c may be different from the threshold voltage Vth of the first gate structure 220a or a threshold voltage Vth of the second gate structure 220b. Accordingly, in the semiconductor device 200i according to the present embodiment, the first, second, and third gate structures 220a, 220b, and 220c (i.e., transistors) having three different threshold voltages may be embodied depending on whether or not the dielectric layer 226 is used and by varying a material of a work function metal layer.

In the semiconductor device 200i according to the present embodiment, the first, second, and third gate structures 220a, 220b, and 220c, respectively, having three different threshold voltages may be formed. However, the disclosed concepts are not limited thereto. In the semiconductor device 200i, gate structures having at least four different threshold voltages may be formed depending on, for example, whether or not the dielectric layer 226 is used or by varying a material of a work function metal layer. For example, similar to the third gate structure 220c, a fourth gate structure (not shown) in which a work function metal layer 227-p is formed of a p-type metal and a dielectric layer 226 is interposed between a capping metal layer 225 and a work function metal layer 227 may be further formed on a fourth region (e.g., fourth region D, not shown) of the semiconductor substrate 201. Since the fourth gate structure further may include the dielectric layer 226, a threshold voltage Vth of the fourth gate structure may be different from a threshold voltage Vth of the third gate structure 220c. Also, since the work function metal layer 227 of the fourth gate structure is formed of a p-type metal, the threshold voltage Vth of the fourth gate structure may be different from the threshold voltage Vth of the second gate structure 220b, which includes the work function metal layer 227-n formed of an n-type metal and the dielectric layer 226.

In addition, in the semiconductor device 200i of FIG. 13, a threshold voltage Vth of a gate structure may be varied by changing not only a material of a work function metal layer but also materials of a capping metal layer 225, a dielectric layer 226, and/or a high-k dielectric layer 223. However, the varying of the threshold voltage Vth of the gate structure may be performed in view of the fact that forming a plurality of gate structures using a one-time process at the same time is advantageous in terms of process efficiency and costs.

The semiconductor devices 100, 200, and 200a through 200i including various structures have been described thus far. However, the disclosed concepts are not limited to those embodiments. For example, a gate structure formed in one region may not include a dielectric layer 226 between a capping metal layer 225 and a work function metal layer 227, while a gate structure formed in another region may include the dielectric layer 226 between the capping metal layer 225 and the work function metal layer 227. In this case, it will be understood that both the gate structures may be formed according to the disclosed concepts irrespective of specific inner structures or materials of the gate structures. Also, since a capping metal layer 225 and a work function metal layer 227 are distinguished from each other only in the functional aspects, it will be understood that a structure of a gate structure in which a dielectric layer 226 is provided between two metal layers irrespective of the names of the metal layers may correspond to a second gate structure according to the disclosed concepts.

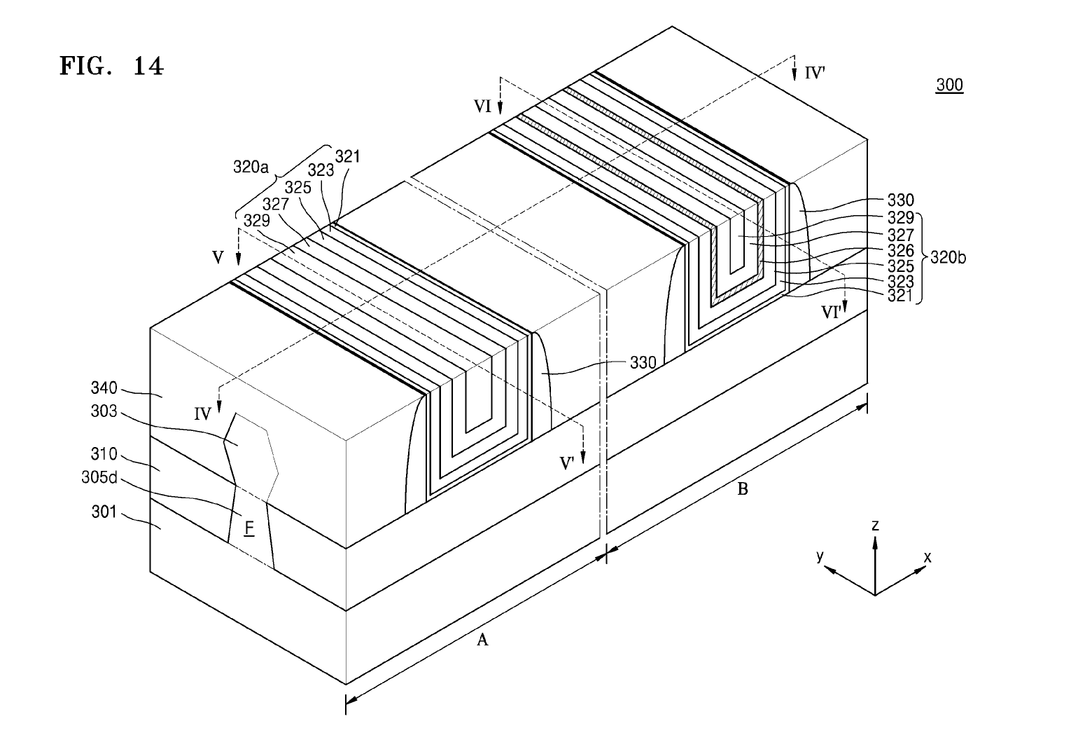

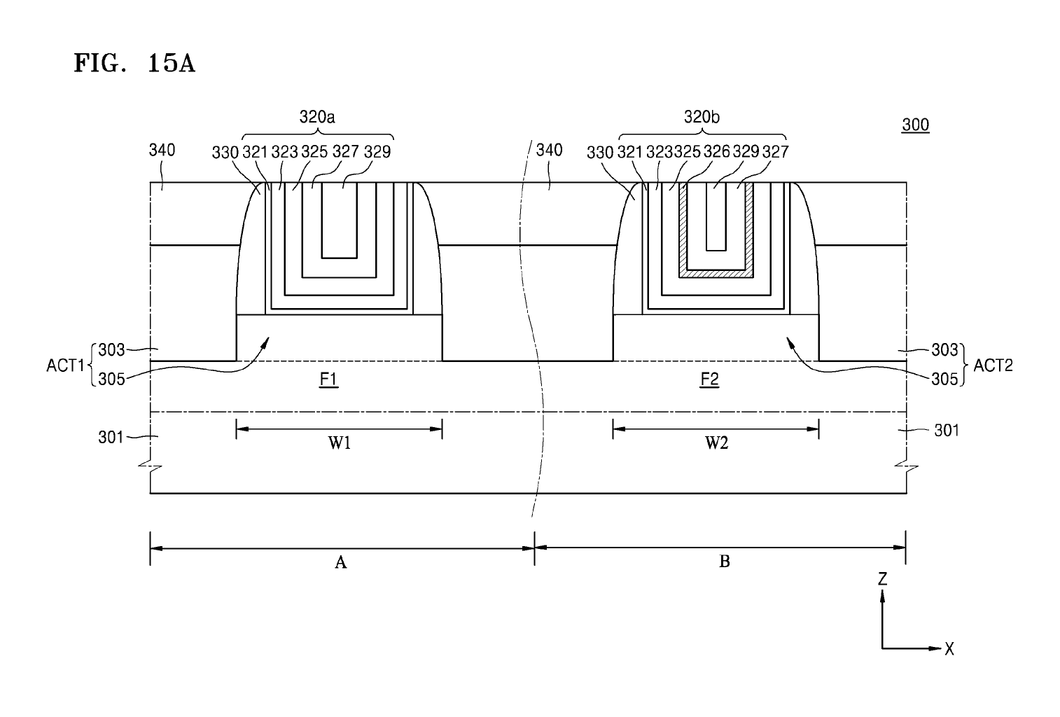

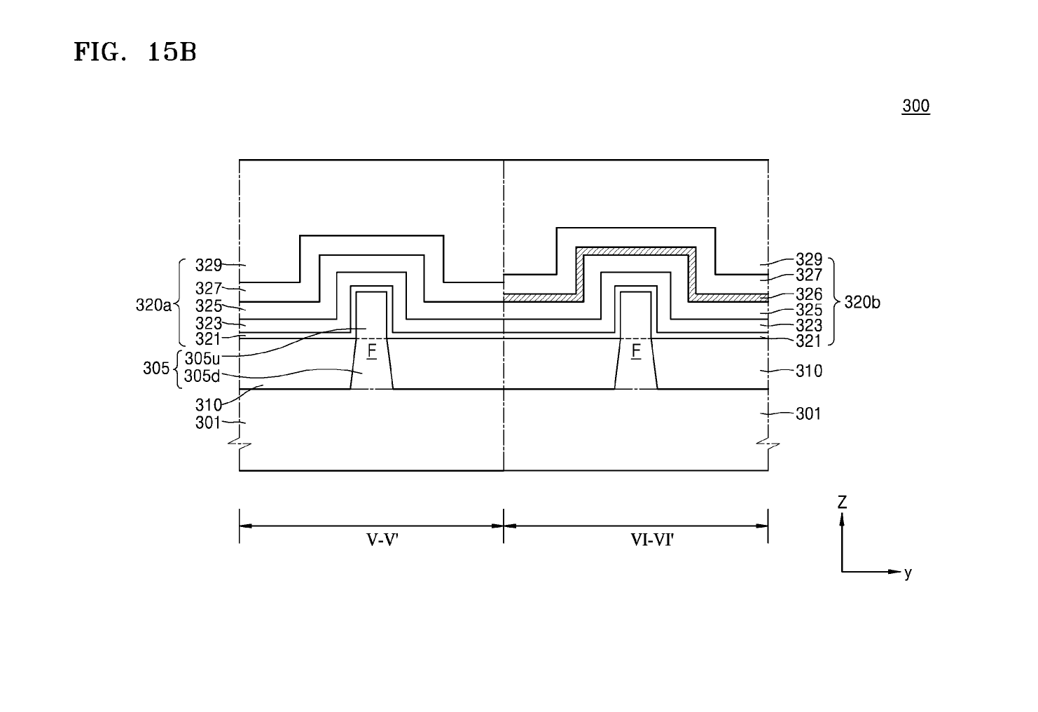

FIG. 14 is a perspective view of a semiconductor device according to an exemplary embodiment. FIG. 15A is a cross-sectional view of the exemplary semiconductor device of FIG. 14 taken along a line IV-IV′ of FIG. 14. FIG. 15B is a cross-sectional view of the exemplary semiconductor of FIG. 14 taken along lines V-V and VI-VI′ of FIG. 14.

Referring to FIGS. 14, 15A, and 15B, a semiconductor device 300 according to the present embodiment may include a semiconductor substrate 301, first and second fin (F)-type active regions ACT1 and ACT2 (hereinafter, referred to as “fin active regions”), and first and second gate structures 320a and 320b. More specifically, the semiconductor device 300 according to the present embodiment may include the semiconductor substrate 301, first and second fin active regions ACT1 and ACT2, a device isolation layer 310, first and second gate structures 320a and 320b, and an interlayer insulating layer 340.

The semiconductor substrate 301 may include a first region A and a second region B. The semiconductor substrate 301 may be similar to the semiconductor substrate 101 of the semiconductor device 100, as disclosed and described in FIG. 1. Thus, detailed descriptions of the semiconductor substrate 301 will be omitted.

The first and second fin active regions ACT1 and ACT2 may protrude from the semiconductor substrate 301 and extend in a first direction (e.g., x-direction). The first and second fin active regions ACT1 and ACT2 may include the first fin active region ACT1 of a first region A and a second fin active region ACT2 of a second region B. A plurality of first fin active regions ACT1 and a plurality of second fin active regions ACT2 may be formed on the semiconductor substrate 301 in a second direction (e.g., y-direction). The plurality of first fin active regions ACT1 and the plurality of second fin active regions ACT2 may be electrically insulated from one another by the device isolation layer 310.

FIG. 14 illustrates a case in which the first and second fin active regions ACT1 and ACT2 intersect at right angles the corresponding first and second gate structures 320a and 320b. However, the first and second fin active regions ACT1 and ACT2 may intersect the first and second gate structures 320a and 320b at angles other than a right angle. In some embodiments, one first fin active region ACT1 may intersect one first gate structure 320a, and one second fin active region ACT2 may intersect one second gate structure 320b, but the disclosed concepts are not limited thereto. For example, one first fin active region ACT1 may intersect a plurality of first gate structures 320a, and one second fin active region ACT2 may intersect a plurality of second gate structures 320b. As another example, one first gate structure 320a may intersect a plurality of first fin active regions ACT1, and one second gate structure 320b may intersect a plurality of second fin active regions ACT2. Furthermore, FIG. 14 illustrates a case in which the first fin active region ACT1 of the first region A and the second fin active region ACT2 of the second region B may extend in the same first direction (e.g., the x-direction), but it is anticipated that the first fin active region ACT1 of the first region A and the second fin active region ACT2 of the second region B may extend in different other and/or directions. Also, the first gate structures 320a of the first region A and the second gate structures 320b of the second region B may extend in different other and/or directions.

Each of the first fin active region ACT1 and the second fin active region ACT2 may include a fin 305 and source and drain regions 303. The fin 305 may include a lower fin portion 305d having two side surfaces surrounded with the device isolation layer 310 and an upper fin portion 305u protruding through a top surface of the device isolation layer 310. The upper fin portion 305u may be formed under the first and second gate structures 320a and 320b and constitute a channel region. The source and drain regions 303 may be formed on the lower fin portion 305d in both side surfaces of each of the first and second gate structures 320a and 320b.

The fin 305 may be formed based on the semiconductor substrate 301, and the source and drain regions 303 may be formed using an epi-layer grown from the lower fin portion 305d. In some cases, upper fin portions 305u may be formed in both side surfaces of the first and second gate structures 320a and 320b and constitute source and drain regions. For example, the source and drain regions may not be formed using an additional epi-layer growth process but formed using the upper fin portions 305u of the fin 305 like the channel region.

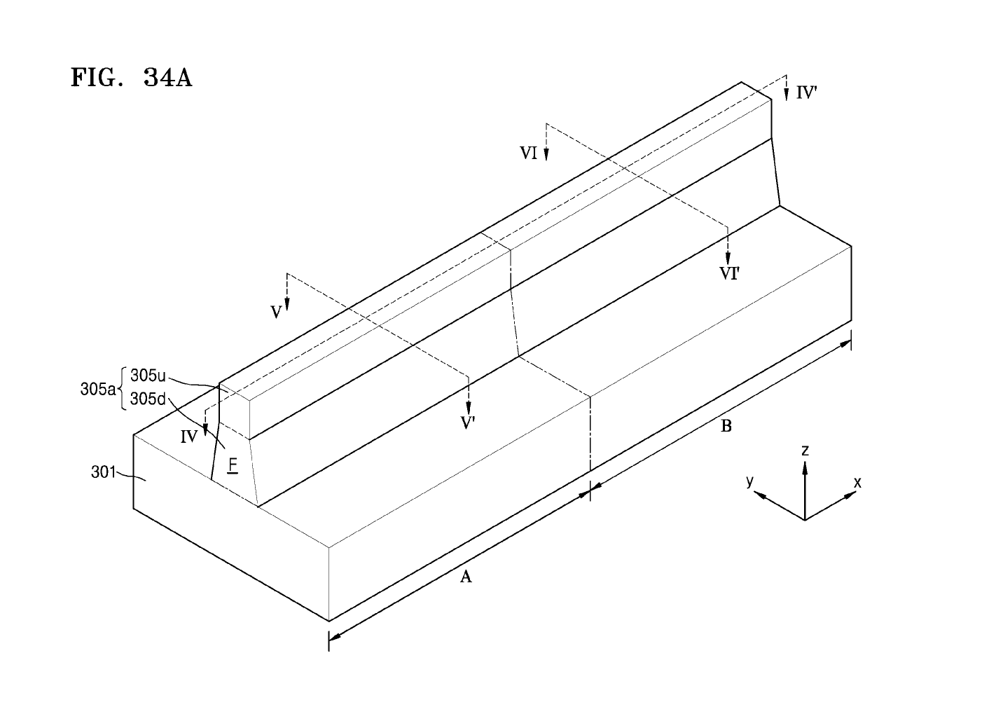

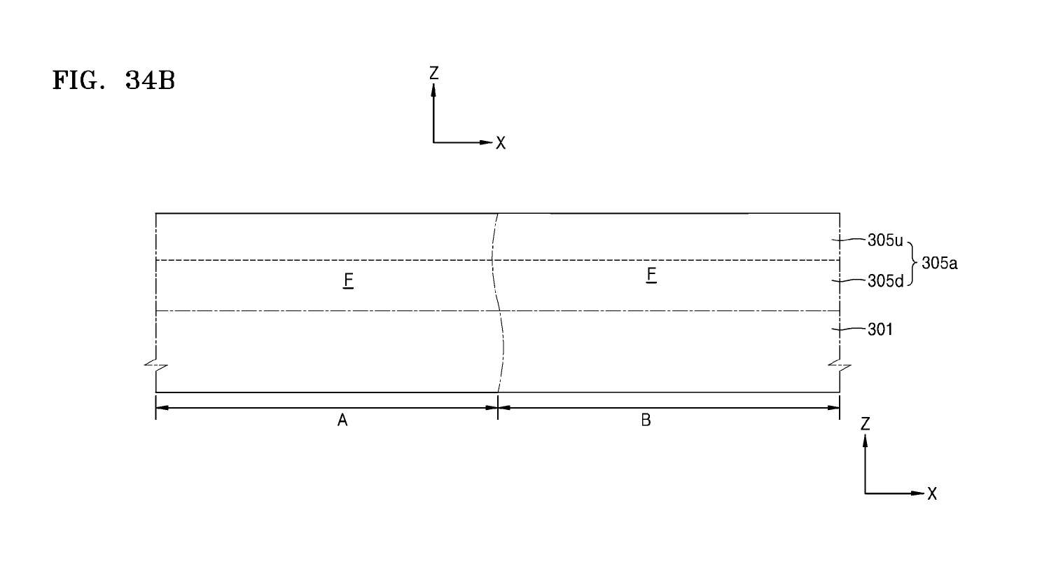

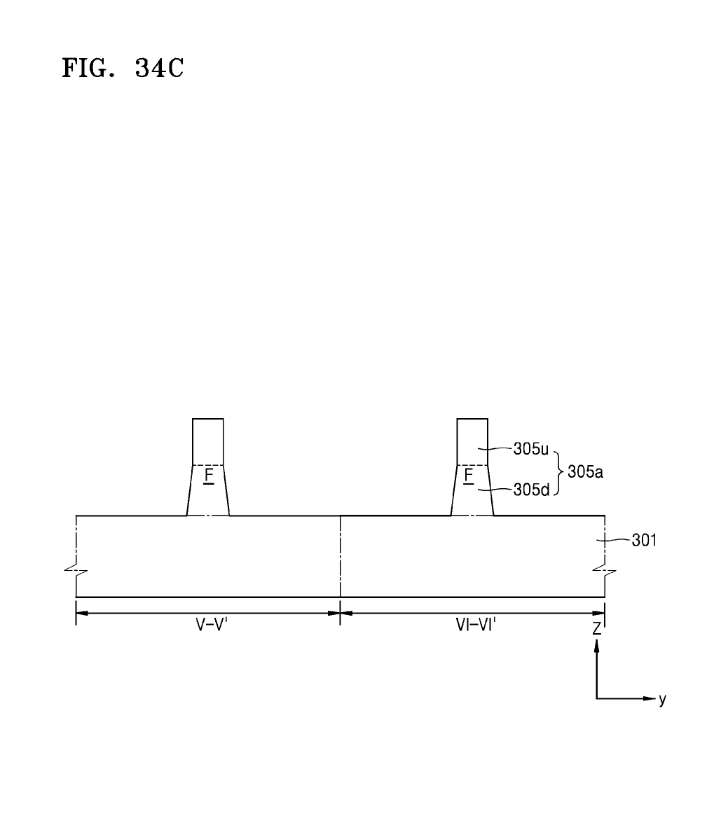

When the fin 305 is formed based on the semiconductor substrate 301, the fin 305 may include a semiconductor element, such as, for example, silicon or germanium. Also, the fin 305 may include a compound semiconductor, such as a Group IV-IV compound semiconductor or a Group III-V compound semiconductor. For example, the Group IV-IV compound semiconductor may be a binary compound or a ternary compound containing at least two of carbon (C), silicon (Si), germanium (Ge), and tin (Sn) or a compound formed by doping a Group IV element thereto. Also, the Group III-V compound semiconductor may be, for example, any one of a binary compound, a ternary compound, or a quaternary compound formed by combining at least one of Group III elements (e.g., aluminum (Al), gallium (Ga), and indium (In)) and one of Group V elements (e.g., phosphorus (P), arsenic (As), and antimony (Sb)). A structure and forming method of the fin 305 will be described in further detail below in connection with FIGS. 34A to 41C.

In some embodiments, when the source and drain regions 303 are formed by growing an epi-layer from the lower fin portions 305d or by using the fins 305, the source and drain regions 303 may be formed on the lower fin portions 305d on both sides of each of the first and second gate structures 320a and 320b and may include a compressive stress material or a tensile stress material according to a channel type of a desired transistor. For example, when a PMOS transistor is formed, the source and drain regions 303 formed on both side surface of each of the first and second gate structures 320a and 320b may include a compressive stress material. For instance, when the lower fin portions 305d are formed of silicon, the source and drain regions 303 may be formed of a compressive stress material, which is a material having a higher lattice constant than silicon (e.g., silicon germanium (SiGe)). As another example, when an NMOS is formed, the source and drain regions 303 formed on both side surfaces of each of the first and second gate structures 320a and 320b may include a tensile stress material. For instance, when the lower fin portions 305d are formed of silicon, the source and drain regions 303 may be formed of a tensile stress material, which is silicon or a material having a lower lattice constant than silicon (e.g., silicon carbide (SiC)).

In addition, in the semiconductor device 300 according to the present embodiment, the source and drain regions 303 may have various shapes. For example, each of the source and drain regions 303 may have a shape (e.g., a diamond, a circle, an ellipse, a polygon, etc.) that is formed on a cross-section perpendicular to the first direction (e.g., x-direction). FIG. 14 illustrates an example in which each of the source and drain regions 303 has a hexagonal diamond shape.

The device isolation layer 310 may be formed on the semiconductor substrate 301 to surround both side surfaces of the lower fin portion 305d of the fin 305. The device isolation layer 310 may correspond to the device isolation layer 110 of the semiconductor device 100, as disclosed and described in connection with FIG. 1, and may electrically isolate fins 305, which are positioned in a second direction (e.g., y-direction), from one another. The device isolation layer 310 may include, for example, at least one of a silicon, an oxide layer, a silicon nitride layer, a silicon oxynitride layer, and combinations thereof.

In certain embodiments, the upper fin portion 305u of the fin 305 may not be surrounded by the device isolation layer 310, but may have a protruding structure. Also, as can be seen in the exemplary illustrations of FIGS. 15A and 15B, the upper fin portion 305u of the fin 305 may be positioned only in a lower portion of each of the first and second gate structures 320a and 320b and may constitute a channel region.

Each of the first and second gate structures 320a and 320b may run or continue across the corresponding fin 305, and may extend on the device isolation layer 310 in a second direction (e.g., y-direction). For example, the first and second gate structures 320a and 320b may include the first gate structure 320a positioned in the first region A and the second gate structure 320b positioned in the second region B. As described above, in some embodiments, a plurality of first gate structures 320a may be positioned to correspond to one fin 305, and a plurality of second gate structures 320b may be positioned to correspond to one fin 305. The plurality of first gate structures 320a or the plurality of second gate structures 20a may be spaced apart from one another in the first direction (e.g., x-direction). Each of the first gate structure 320a and the second gate structure 320b may be formed to surround a top surface and side surfaces of the upper fin portion 305u of the fin 305.

In other exemplary embodiments, a plurality of fins 305 may be positioned to correspond to each of the first gate structure 320a and the second gate structure 320b. The plurality of fins 305 may be spaced apart from one another in the second direction (e.g., y-direction).

The first gate structure 320a and the second gate structure 320b may respectively correspond to the first gate structure 220a and the second gate structure 220b of the semiconductor device 200, as disclosed and described in FIGS. 3, 4A, and 4B. Thus, the first gate structure 320a may include an interfacial layer 321, a high-k dielectric layer 323, a capping metal layer 325, a work function metal layer 327, and a gap-fill metal layer 329. Also, the second gate structure 320b may include an interfacial layer 321, a high-k dielectric layer 323, a capping metal layer 325, a dielectric layer 326, a work function metal layer 327, and a gap-fill metal layer 329.

Materials and functions of respective layers forming the first gate structure 320a and the second gate structure 220b may be the same as those of the semiconductor device 100, as disclosed and described in FIG. 1, and the semiconductor device 200, as disclosed and described in FIGS. 3, 4A, and 4B. However, in the semiconductor device 300 according to the present embodiment, since each of the first and second gate structures 320a and 320b is formed to cover the fin 305, as illustrated in FIG. 15A, a sectional structure may be different from that of FIG. 4B. Also, as shown in FIG. 15A, since the source and drain regions 303 are formed on the lower fin portions 305d, the source and drain regions 303 formed on both side surfaces of each of the first and second gate structures 320a and 320b may be structurally different from the source and drain regions 203 of FIG. 4A.

The interlayer insulating layer 340 may be formed on the device isolation layer 310 to cover the source and drain regions 303. For example, the interlayer insulating layer 340 may surround top and side surfaces of the source and drain regions. The interlayer insulating layer 340 may correspond to the interlayer insulating layer 240 of the semiconductor device 200, as disclosed and described in FIGS. 3, 4A, and 4B. Accordingly, a material or structure of the interlayer insulating layer 340 may be the same as those of the semiconductor device 200, as disclosed and described in connection with FIGS. 3, 4A, and 4B.

Spacers 330 may be formed between the interlayer insulating layer 340 and the first and second gate structures 320a and 320b. The spacers 330 may surround both side surfaces of each of the first and second gate structures 320a and 320b and extend in a second direction (e.g., y-direction). Similar to the first and second gate structures 320a and 320b, the spacers 330 may run across the fin 305 and surround top and side surfaces of the upper fin portion 305u. For example, the spacers 330 may extend across the fin 305, and cover the top and side surfaces of the upper fin portion 305u. The spacers 330 may correspond to the spacers 230 of the semiconductor device 200, as disclosed and described in connection with FIGS. 3, 4A, and 4B. Accordingly, a material of the spacers 230 may be the same as in the semiconductor device 200 described in connection with FIGS. 3 to 4B.

In the semiconductor device 300, since the second gate structure 320b includes the dielectric layer 326, a threshold voltage Vth of the second gate structure 320b may be changed. For example, the threshold voltage Vth of the second gate structure 320b may be different from a threshold voltage Vth of the first gate structure 320a. As a result, the semiconductor device 300 according to the present embodiment may embody a logic device including multiple transistors, each of which includes a fin active region and a gate structure and each of which has multiple, various threshold voltages.

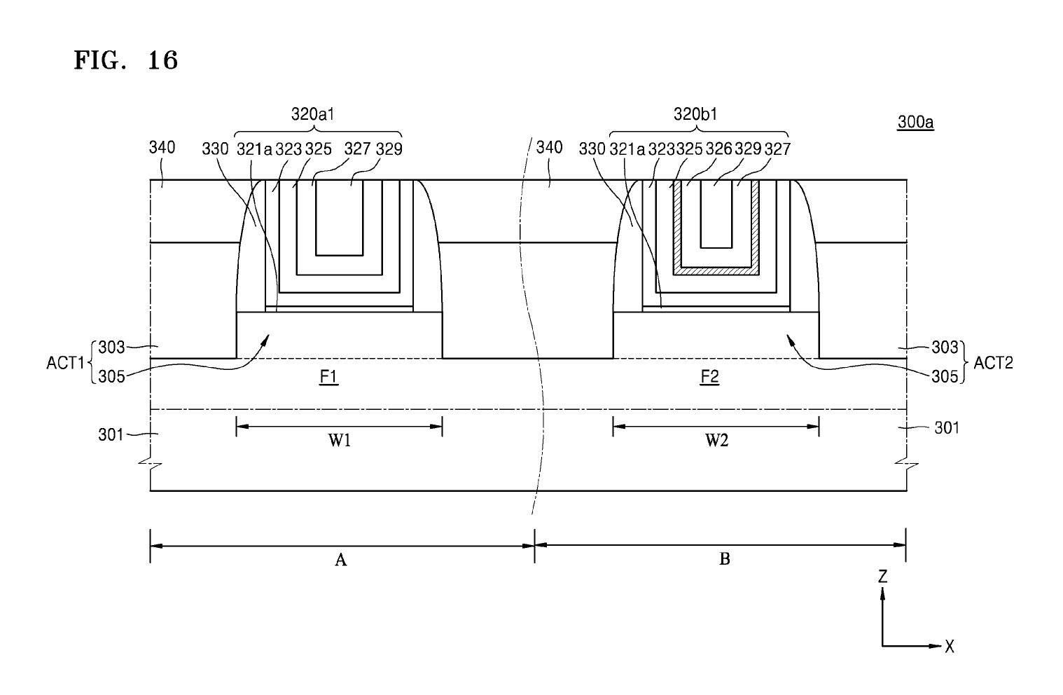

FIGS. 16 to 23 are cross-sectional views of semiconductor devices according to exemplary embodiments, which correspond to FIG. 15A.

Referring to FIG. 16, a semiconductor device 300a according to the present embodiment may be the same as the semiconductor device 300 of FIG. 15A except for a structure of an interfacial layer 321a. In the semiconductor device 300a according to the present embodiment, for example, an interfacial layer 321a of each of a first gate structure 320a1 and a second gate structure 320b1 may be formed only on a top surface of a semiconductor substrate 301 but not on side surfaces of spacers 330. In some embodiments, a dummy insulating layer of a dummy gate structure may not be removed but may be used as the interfacial layer 321a. Since the interfacial layer 321a is formed only on the semiconductor substrate 301 and does not extend upward, distances between corresponding side surfaces of layers of the first gate structure 320a1 and corresponding side surfaces of layers of the second gate structure 320b1 may increase and thereby allow for an increased width or thickness of a gap-fill metal layer 329. For instance, when interfacial layer 321a is formed only on the semiconductor substrate 301, the width of gap-fill metal layer 329 may be increased without causing a corresponding increase in the first width W1 and the second W2.

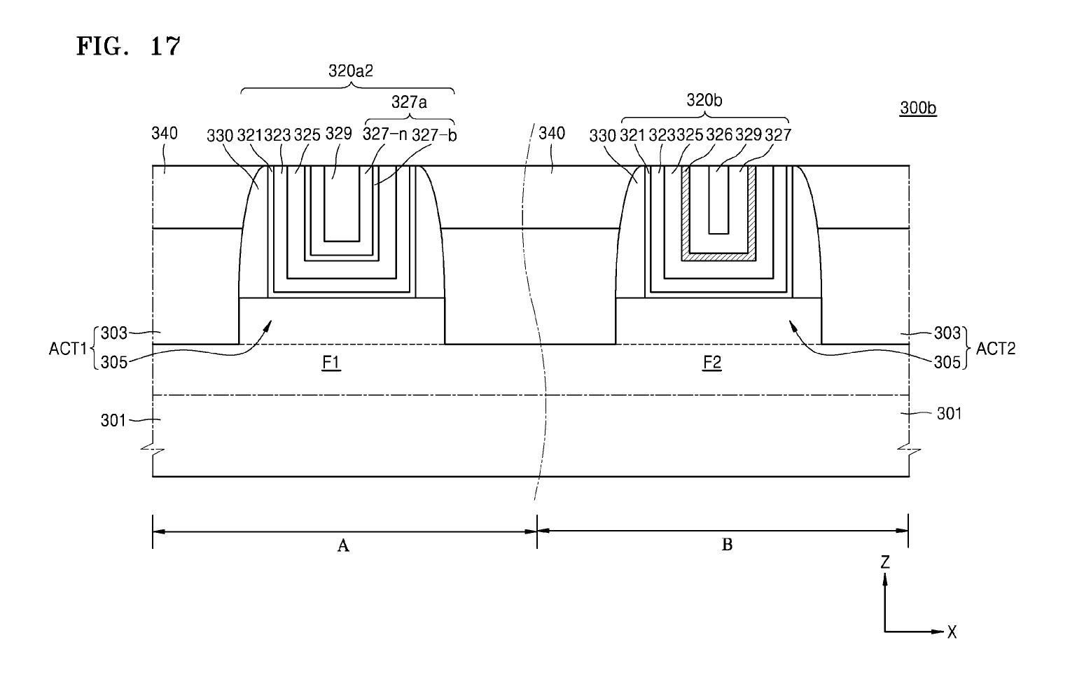

Referring to FIG. 17, a semiconductor device 300b according to the present embodiment may be different from the semiconductor device 200 of FIG. 15A in that a work function metal layer 327a of a first gate structure 320a2 includes a barrier metal layer 327-b and an n-type metal layer 327-n. Materials and functions of the barrier metal layer 327-b and the n-type metal layer 327-n may be the same as the barrier metal layer 227-b and the n-type metal layer 227-n of the semiconductor device 200b, as disclosed and described in connection with FIG. 6.

Further, a work function metal layer 327 of the second gate structure 320b may be formed of an n-type metal and formed of the same material as the work function metal layer 327-n of the first gate structure 320a2. Accordingly, the work function metal layer 327 of the second gate structure 320b and the n-type metal layer 327-n of the first gate structure 320a2 may be simultaneously formed using a one-time process. However, a material of the work function metal layer 327 of the second gate structure 320b is not limited to an n-type metal.

In addition, although not shown, a barrier metal layer may be formed also between the work function metal layer 327 and a gap-fill metal layer 329. In some cases, the barrier metal layer may take the place of the gap-fill metal layer 329. In this case, an additional gap-fill metal layer may not be formed. Furthermore, a barrier metal layer may be formed also between the high-k dielectric layer 323 and the capping metal layer 325. The barrier metal layer between the high-k dielectric layer 323 and the capping metal layer 325 may prevent atoms or ions of the capping metal layer 325 from diffusing into the high-k dielectric layer 323.

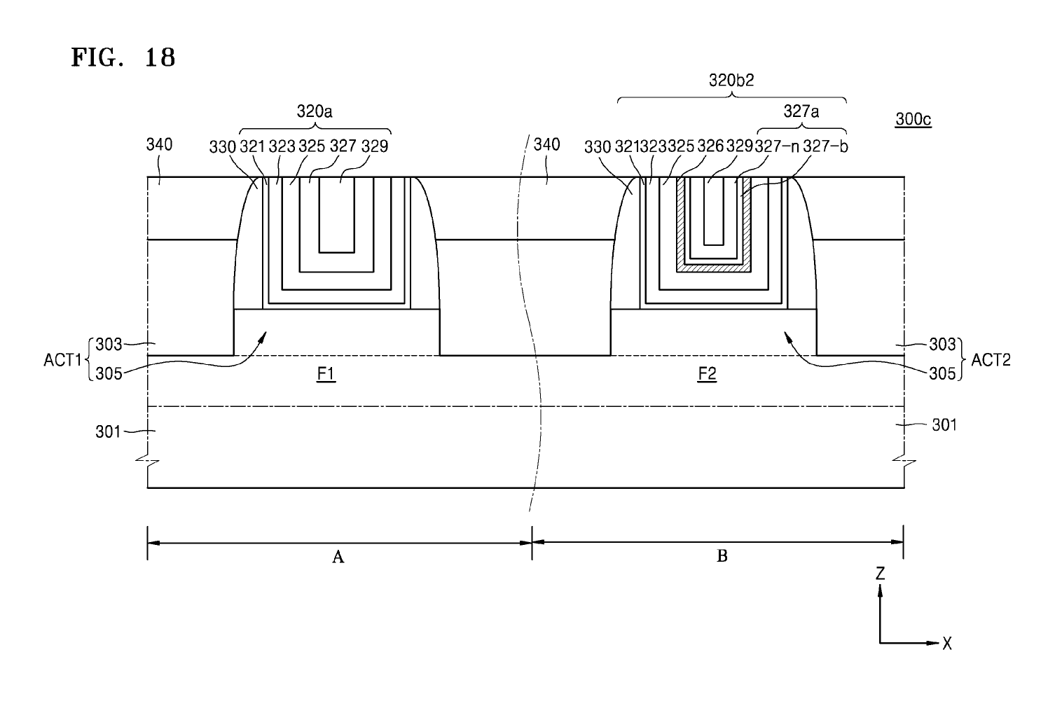

Referring to FIG. 18, a semiconductor device 300c according to the present embodiment may be different from the semiconductor device 300 of FIG. 15A in that a work function metal layer 327a of a second gate structure 320b2 includes a barrier metal layer 327-b and an n-type metal layer 327-n. Materials and functions of the barrier metal layer 327-b and the n-type metal layer 327-n may be the same as the barrier metal layer 227-b and the n-type metal layer 227-n of the semiconductor device 200b, as disclosed and described in connection with FIG. 6. However, the barrier metal layer 327-b of the second gate structure 320b2 may be interposed between a dielectric layer 326 and the n-type metal layer 327-n, and the resultant functions and effects of the barrier metal layer 327-b may be the same as in the semiconductor device 200c disclosed and described in connection with FIG. 7. For example, since the second gate structure 320b2 includes the barrier metal layer 327-b, a threshold voltage Vth shifting function of the dielectric layer 326 may be maintained, and a thickness of the dielectric layer 326 may be reduced to minimize the action of the dielectric layer 326 as a resistor.

Meanwhile, a work function metal layer 327 of the first gate structure 320a may be formed of an n-type metal like the n-type metal layer 327-n of the second gate structure 320b2. However, a material of the work function metal layer 327 of the first gate structure 320a is not limited to the n-type metal. Also, even if the work function metal layer 327 of the first gate structure 320a is formed of an n-type metal, the work function metal layer 327 of the first gate structure 320a may be formed of a different material from the n-type metal layer 327-n of the second gate structure 320b2.

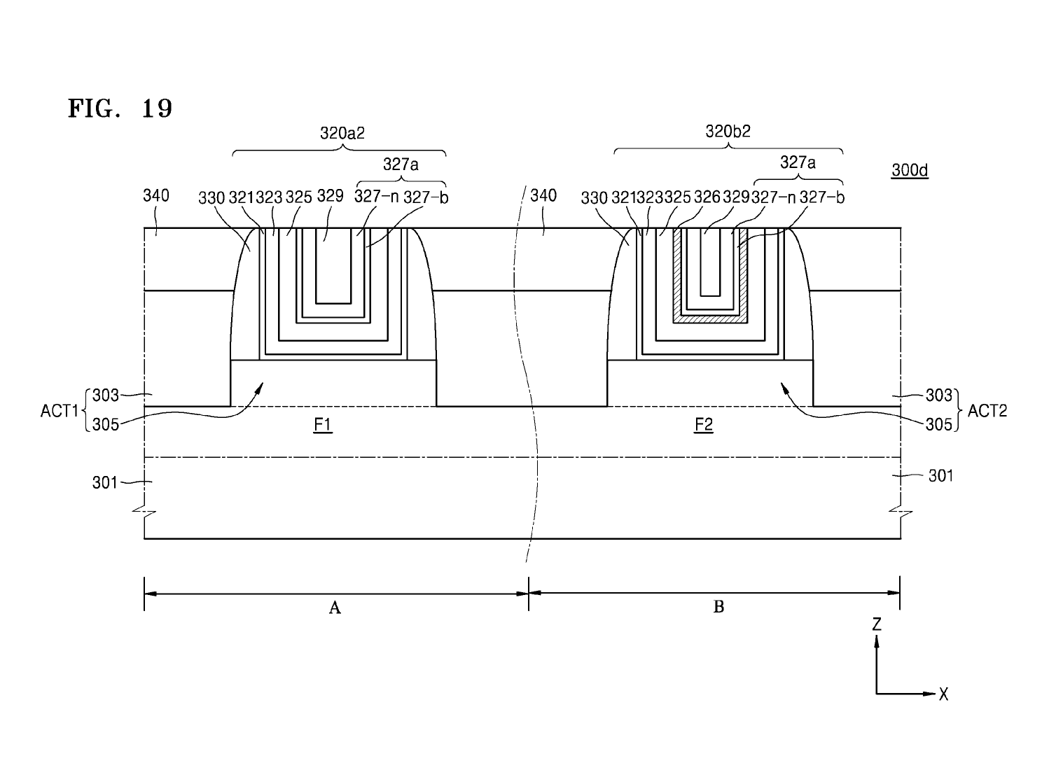

Referring to FIG. 19, a semiconductor device 300d according to the present embodiment may be different from the semiconductor device 300 of FIG. 15A in that a work function metal layer 327a of a first gate structure 320a2 includes a barrier metal layer 327-b and an n-type metal layer 327-n and a work function metal layer 327a of a second gate structure 320b2 includes a barrier metal layer 327-b and an n-type metal layer 327-n. The semiconductor device 300d according to the present embodiment may be understood to be equivalent to a combination of the first gate structure 320a2 of the semiconductor device 300b of FIG. 17 and the semiconductor gate structure 320b2 of the semiconductor device 300c of FIG. 18.

Thus, the work function metal layer 327a of the first gate structure 320a2 may be the same as the work function metal layer 327a of the first gate structure 320a2 of the semiconductor device 300b disclosed and described in connection with FIG. 17. The work function metal layer 327a of the second gate structure 320b2 may be the same as the work function metal layer 327a of the second gate structure 320b2 of the semiconductor device 300c disclosed and described in connection with FIG. 18.

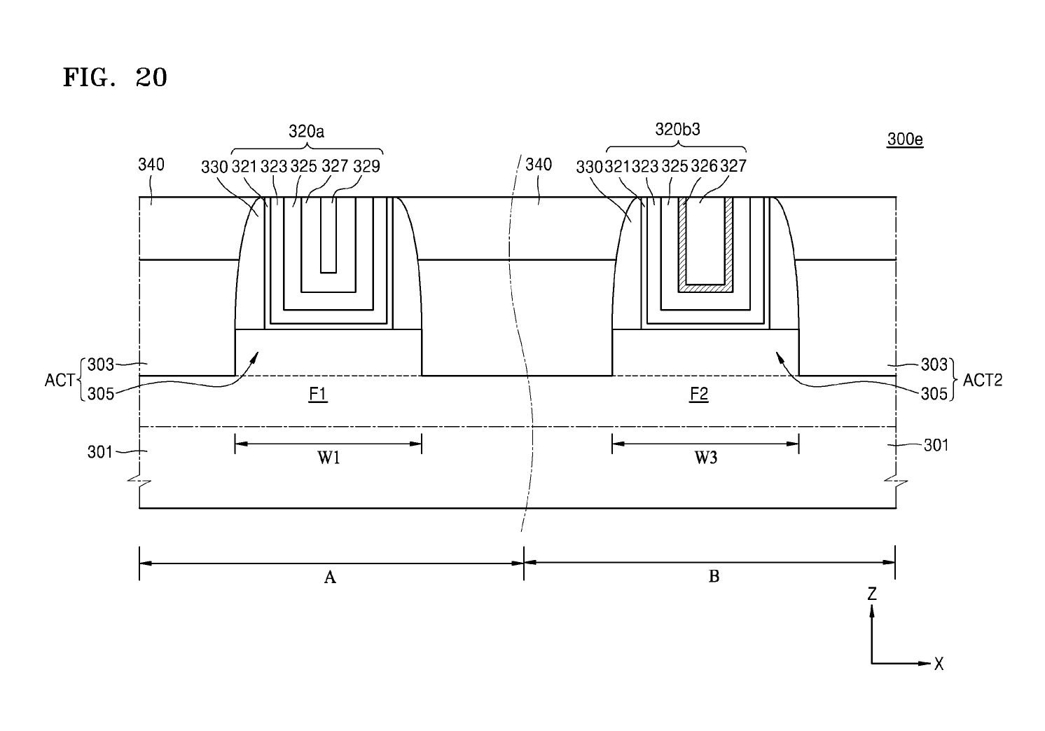

Referring to FIG. 20, a semiconductor device 300e according to the present embodiment may be different from the semiconductor device 300 of FIG. 15A in that a second gate structure 320b3 does not include a gap-fill metal layer. In other words, the second gate structure 320b3 may include an interfacial layer 321, a high-k dielectric layer 323, a capping metal layer 325, a dielectric layer 326, and a work function metal layer 327. Meanwhile, the first gate structure 320a may be the same as the first gate structure 320a of the semiconductor device 300, as disclosed and described in connection with FIG. 15A. Thus, the first gate structure 320a may include a gap-fill metal layer 329.

In the semiconductor device 300e according to the present embodiment, a gate width of the second gate structure 320b3 may have a third width W3. The third width W3 of the second gate structure 320b3 may be less than a first width W1 of a first gate structure 320a. The second gate structure 320b3 may not include a gap-fill metal layer for the same reasons as disclosed and described in connection with the semiconductor device 200e of FIG. 9. For example, since the second gate structure 320b3 further includes the dielectric layer 326, the work function metal layer 327 formed on the dielectric layer 326 may completely fill a gap, and a gap-fill metal layer may not be formed.

In addition, a barrier metal layer may be formed between the work function metal layer 327 of the first gate structure 320a and the gap-fill metal layer 329. In this case, in the second gate structure 320b3, only the barrier metal layer may be present on the work function metal layer 327, and a gap-fill metal layer may not be provided.

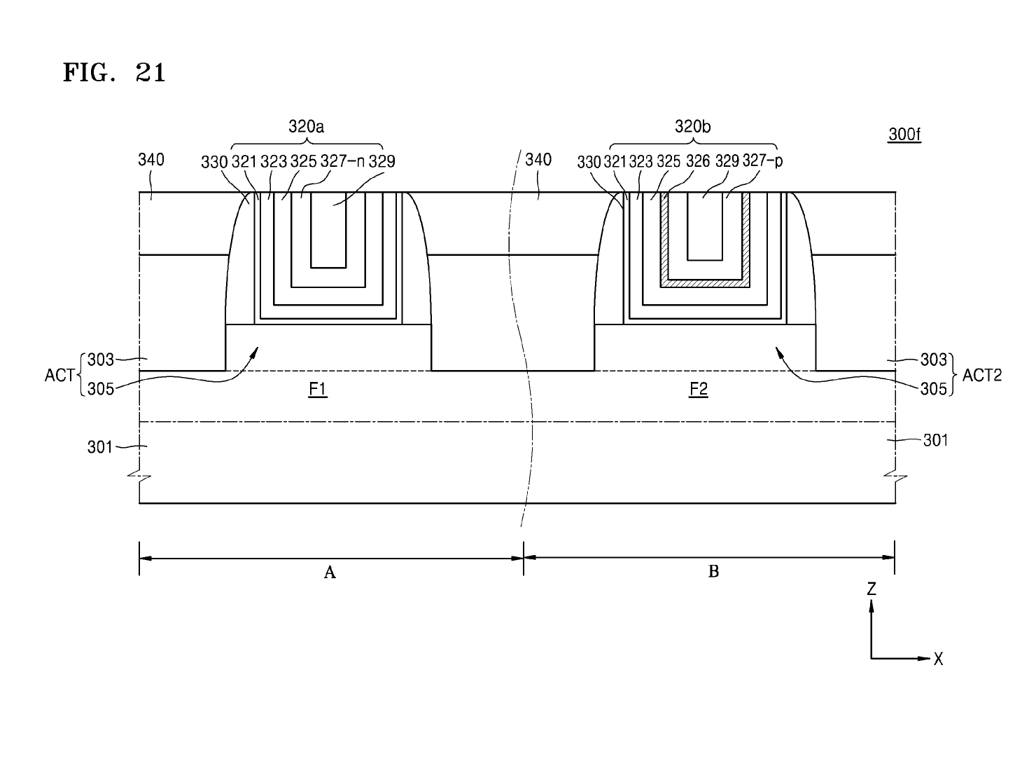

Referring to FIG. 21, in a semiconductor device 300f according to the present embodiment, a work function metal layer 327-n of a first gate structure 320a may be formed of an n-type metal, while a work function metal layer 327-p of a second gate structure 320b may be formed of a p-type metal. Accordingly, the first gate structure 320a may constitute an NMOS transistor, while the second gate structure 320b may constitute a PMOS transistor. Properties or kinds of the n-type metal and the p-type metal may be the same as in the semiconductor device 100 disclosed and described in connection with FIG. 1.

In the semiconductor device 300f, the second gate structure 320b may include a dielectric layer 326 formed between the capping metal layer 325 and the work function metal layer 327-n. Accordingly, a threshold voltage Vth of the second gate structure 320b may be not only different from a threshold voltage Vth of the first gate structure 320a but also different from a threshold voltage Vth of another gate structure constituting a PMOS transistor.

As described above, in the semiconductor device 300f, the work function metal layers 327 of respective gate structures 320a and 320b may be formed of different materials, and each of the gate structures may selectively include the dielectric layer 326 so that transistors having various or multiple threshold voltages may be formed. Thus, the semiconductor device 300f according to the present embodiment may be usefully applied to a logic device that demands transistors having various or multiple threshold voltages.

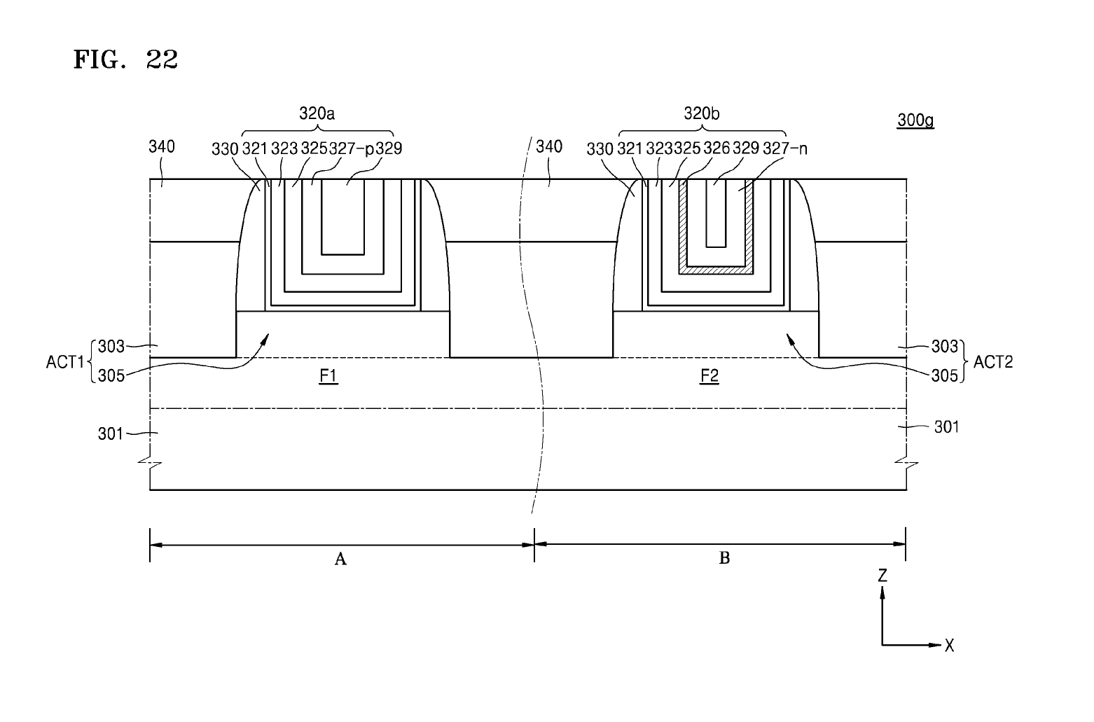

Referring to FIG. 22, a semiconductor device 300g according to the present embodiment may be different from the semiconductor device 300f of FIG. 21 in that a work function metal layer 327-p of a first gate structure 320a is formed of a p-type metal and a work function metal layer 327-n of a second gate structure 320b is formed of an n-type metal. In other words, contrary to the semiconductor device 300f of FIG. 21, in the semiconductor device 300g according to the present embodiment, the first gate structure 320a may constitute a PMOS transistor, while the second gate structure 320b may constitute an NMOS transistor.

The semiconductor device 300g according to the present embodiment may be usefully applied to embody transistors having various or multiple threshold voltages, similar to the semiconductor device 300f of FIG. 21. For example, since the second gate structure 320b includes the dielectric layer 326 interposed between the capping metal layer 325 and the work function metal layer 327-n, a threshold voltage Vth of the second gate structure 320b may be not only different from a threshold voltage Vth of the first gate structure 320a but also different from a threshold voltage Vth of another gate structure constituting an NMOS transistor.

FIGS. 21 and 22 show the semiconductor devices 300f and 300g in which work function metal layers of the first gate structure 320a and the second gate structure 320b are formed of different materials, but the disclosed concepts are not limited thereto. For example, different threshold voltages may be embodied by varying materials of the high-k dielectric layer 323 or the capping metal layer 325.

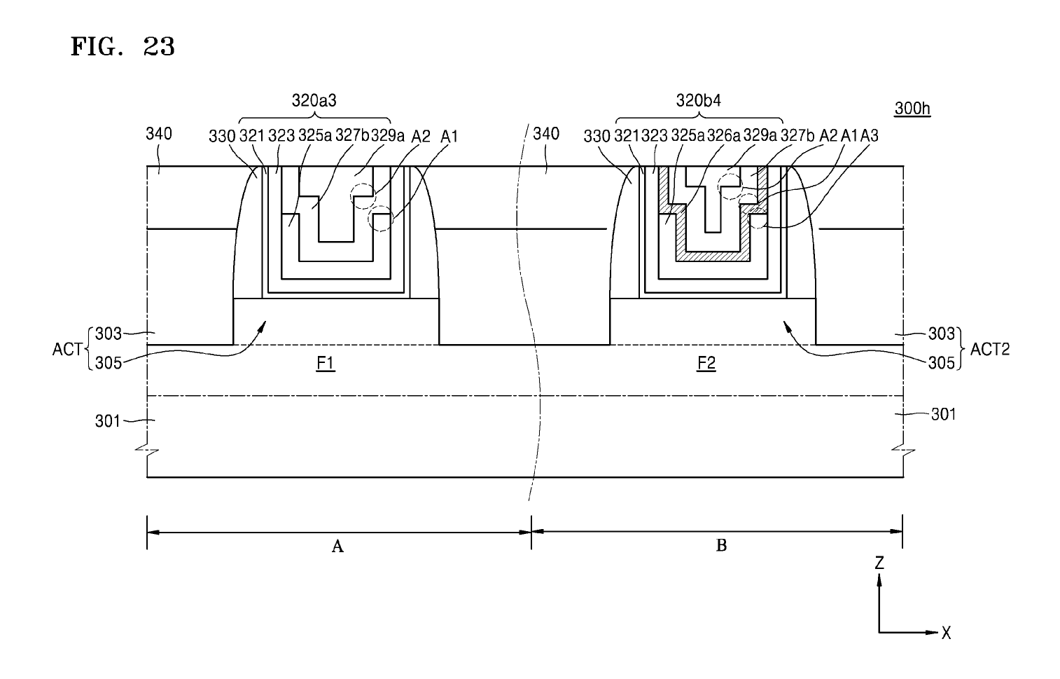

Referring to FIG. 23, a semiconductor device 300h according to the present embodiment may be different from the semiconductor devices including fin active regions according to the above-described embodiments in structures of a first gate structure 320a3 and a second gate structure 320b4. Specifically, a capping metal layer 325a of each of the first gate structure 320a3 and the second gate structure 320b4 may not be formed on the entire bottom and side surfaces of a high-k dielectric layer 323, but may be formed only on portions of bottom and side surfaces of the high-k dielectric layer 323. Thus, a top surface of side portions of the capping metal layer 325a may be at a lower level than a top surface of a side portion of the high-k dielectric layer 323 and, thus, the top surface of the side portions of the capping metal layer 325a may not be exposed.

In the first gate structure 320a3, first and second stepped portions A1 and A2 may be respectively formed on side surfaces of a work function metal layer 327b and a gap-fill metal layer 329a formed on the capping metal layer 325a due to a structure of the capping metal layer 325a. Also, in the second gate structure 320b4, a third stepped portion A3, a first stepped portion A1, and a second stepped portion A2 may be respectively formed on side surfaces of a dielectric layer 326a, the work function metal layer 327b, and the gap-fill metal layer 329a formed on the capping metal layer 325a due to a structure of the capping metal layer 325a. In some embodiments, structures of the work function metal layer 327b and the gap-fill metal layer 329a of the first gate structure 320a3 and the dielectric layer 326a, the work function metal layer 327b, and the gap-fill metal layer 329a of the second gate structure 320b4 may be the same as in the semiconductor device 200h, as disclosed and described in connection with FIG. 12.

In a structure of the semiconductor device 300h, a volume occupied by the gap-fill metal layer 329a in each of the first and second gate structures 320a3 and 320b4 may increase. As a result, resistances of the first and second gate structures 320a3 and 320b4 may be reduced and thereby contribute toward reducing a delay time of a gate electrode. For example, the resistance of the second gate structure 320b4 may increase due to the use of the dielectric layer 326. However, since the second gate structure 320b4 is formed to increase the volume occupied by the gap-fill metal layer 329a, an increase in the delay time of the gate electrode due to an increase in resistance may be solved.

In addition, although the present embodiment describes an example in which a capping metal layer has a buried structure, when a barrier metal layer is present between the high-k dielectric layer 323 and the capping metal layer, the barrier metal layer may have a buried structure, and upper layers including the capping metal layer may have a stepped structure.

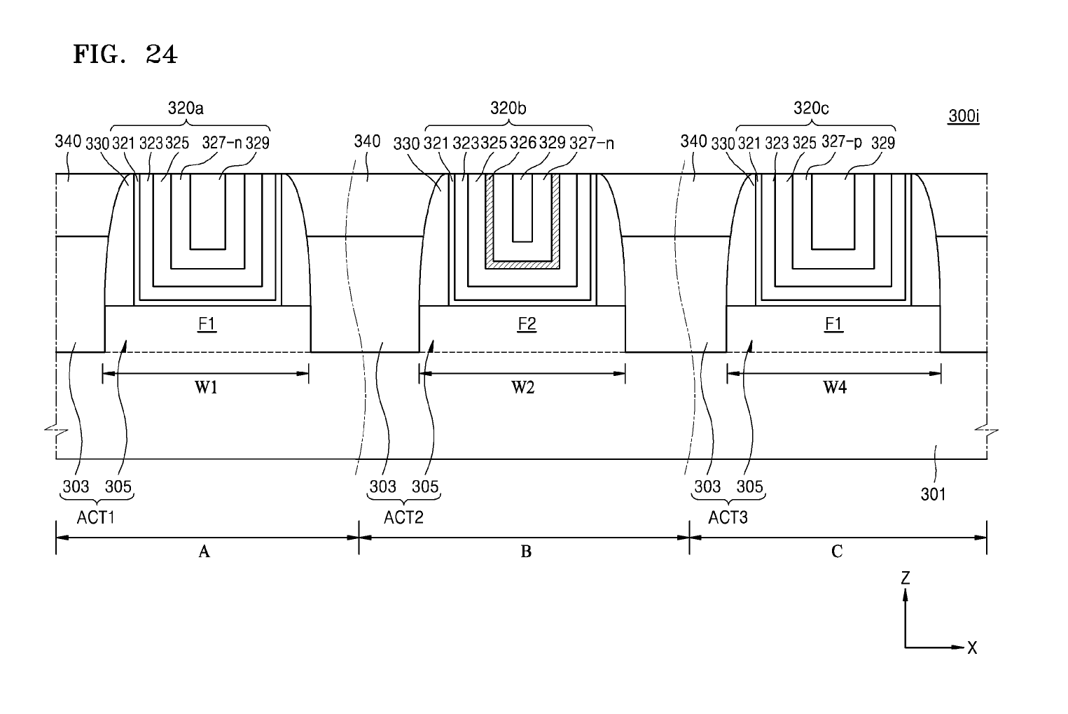

FIG. 24 is a cross-sectional view of a semiconductor device 300i according to an exemplary embodiment.

Referring to FIG. 24, the semiconductor device 300i according to the present embodiment may include a semiconductor substrate 301 and first, second, and third gate structures 320a, 320b, and 320c. The semiconductor substrate 301 may include a first region A, a second region B, and a third region C. Also, first, second, and third active regions ACT1, ACT2, and ACT3, respectively, may be defined by a device isolation layer 310 in an upper region of the semiconductor substrate 301. The first, second, and third active regions ACT1, ACT2, and ACT3 may include the first active region ACT1 of the first region A, the second active region ACT2 of the second region B, and the third active region ACT3 of the third region C.

The first, second, and third gate structures 320a, 320b, and 320c may be positioned on the semiconductor substrate 301 across corresponding first, second, and third active regions ACT1, ACT2, and ACT3. For example, the first, second, and third gate structures 320a, 320b, and 320c may include the first gate structure 320a of the first region A, the second gate structure 320b of the second region B, and the third gate structure 320c of the third region C.

The semiconductor substrate 301 may be the same as the semiconductor substrate 101, as disclosed and described in connection with FIG. 1. Meanwhile, each of the first, second, and third active regions ACT1, ACT2, and ACT3 may include source and drain regions 303 and a channel region. Also, the source and drain regions 303 may include a heavily doped region (e.g., a heavily doped region 203h, such as that disclosed and described in connection with FIG. 4A) and a lightly doped region (e.g., a lightly doped region 203l, such as that disclosed and described in connection with FIG. 4A).

Spacers 330 may be formed on both side surfaces of each of the first gate structure 320a, the second gate structure 320b, and the third gate structure 320c. For example, spacers 330 may be formed on the corresponding side surfaces of the first gate structure 320a, the corresponding side surfaces of the second gate structure 320b, and the corresponding side surfaces of the third gate structure 320c. Also, the spacers 330 may be surrounded by the source and drain regions 303 and an interlayer insulating layer 340. Materials and shapes of the spacers 330 and the interlayer insulating layer 340 may be the same as in the semiconductor device 200, as disclosed and described in connection with FIG. 4A.

The first gate structure 320a may include an interfacial layer 321, a high-k dielectric layer 323, a capping metal layer 325, a work function metal layer 327-n, and a gap-fill metal layer 329. The work function metal layer 327-n of the first gate structure 320a may be formed of an n-type metal. Also, the second gate structure 320b may include the interfacial layer 321, the high-k dielectric layer 323, the capping metal layer 325, the dielectric layer 326, the work function metal layer 327-n, and the gap-fill metal layer 329. The work function metal layer 327-n of the second gate structure 320b may also be formed of an n-type metal. Further, the third gate structure 320c may include the interfacial layer 321, the high-k dielectric layer 323, the capping metal layer 325, a work function metal layer 327-p, and the gap-fill metal layer 329. The third gate structure 320c may be similar to the first gate structure 320a except that the work function metal layer 327-p is formed of a p-type metal.

The first gate structure 320a may have a gate width of a first width W1, the second gate structure 320b may have a gate width of a second width W2, and the third gate structure 320c may have a gate width of a fourth width W4. In some embodiments, the first width W1 of the first gate structure 320a, the second width W2 of the second gate structure 320b, and the fourth width W4 of the third gate structure 320c may be the same. In other embodiments, at least one of the first width W1 of the first gate structure 320a, the second width W2 of the second gate structure 320b, and the fourth width W4 of the third gate structure 320c may be different from the others thereof. For example, the first width W1 of the first gate structure 320a may be equal to the second width W2 of the second gate structure 320b, and the fourth width W4 of the third gate structure 320c may be greater than the first width W1 of the first gate structure 320a.

In the semiconductor device 300i, since the second gate structure 320b further includes the dielectric layer 326, a threshold voltage Vth of the second gate structure 320b may be different from a threshold voltage Vth of the first gate structure 320a. Also, the work function metal layers 327-n of the first gate structure 320a and the second gate structure 320b may be formed of an n-type metal, and the work function metal layer 327-p of the third gate structure 320c may be formed of a p-type metal. Thus, a threshold voltage Vth of the third gate structure 320c may be different from either or both of the threshold voltage Vth of the first gate structure 320a and the second gate structure 320b. Accordingly, in the semiconductor device 300i according to the present embodiment, the first, second, and third gate structures 320a, 320b, and 230c (i.e., transistors) having three different threshold voltages may be embodied depending on whether or not the dielectric layer 326 is used and by varying a material of a work function metal layer.

In the semiconductor device 300i according to the present embodiment, the first, second, and third gate structures 320a, 320b, and 320c having three different threshold voltages may be formed, but the disclosed concepts are not limited thereto. In the semiconductor device 300i according to the present embodiment, gate structures having at least four different threshold voltages may be formed depending on whether or not the dielectric layer 326 is used and by varying a material of a work function metal layer.

The semiconductor devices 300 and 300a to 300i, each disclosing and describing various gate structures positioned on a fin active region, have been described thus far. However, the disclosed concepts are not limited thereto. For example, a gate structure formed in one region in which a fin active region is positioned may not include a dielectric layer 326 between a capping metal layer 325 and a work function metal layer 327, while a gate structure formed in another region in which a fin active region is positioned may include the dielectric layer 326 between the capping metal layer 325 and the work function metal layer 327. In this case, it will be understood that both the gate structures may be formed according to the disclosed concepts irrespective of specific inner structures or materials of the gate structures. Also, since a capping metal layer 325 and a work function metal layer 327 are distinguished from each other only in the functional aspects, it will be understood that a structure of a gate structure in which a dielectric layer 326 is provided between two metal layers irrespective of the names of the metal layers may correspond to a second gate structure according to the disclosed concepts.

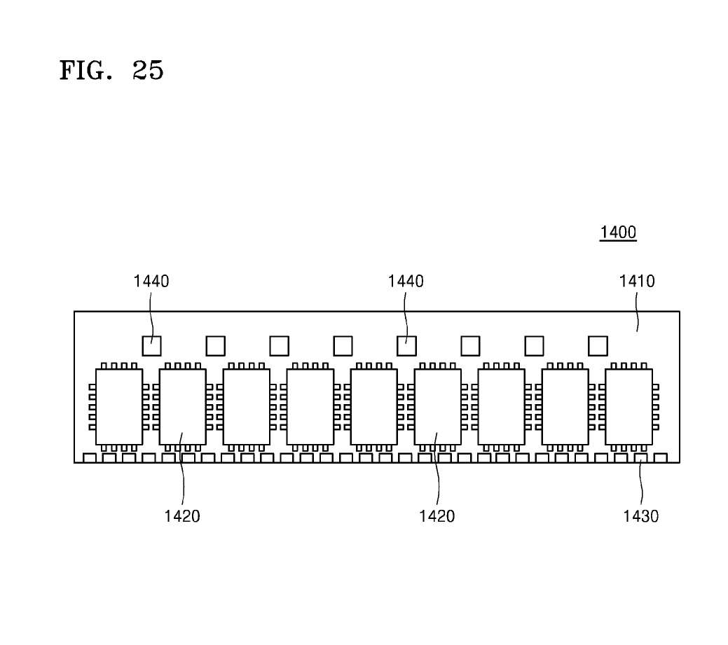

FIG. 25 is a plan view of a memory module 1400 according to an exemplary embodiment.

Referring to FIG. 25, the memory module 1400 may include a module substrate 1410 and a plurality of semiconductor chips 1420 adhered to the module substrate 1410.

Each of the semiconductor chips 1420 may include a semiconductor device according to the exemplary embodiments disclosed herein. For example, each of the semiconductor chips 1420 may include at least one of the semiconductor devices 100, 200 to 200i, and 300 to 300i, as disclosed and described in connection with FIGS. 1 to 24.

Connectors 1430, which may be inserted into sockets of a motherboard, may be positioned on one side of the module substrate 1410, in some exemplary embodiments. A ceramic decoupling capacitor 1440 may be positioned on the module substrate 1410. The memory module 1400 according to an exemplary embodiment is not limited to the shape and configuration shown in FIG. 23, however, and may be manufactured in various shapes and configurations.

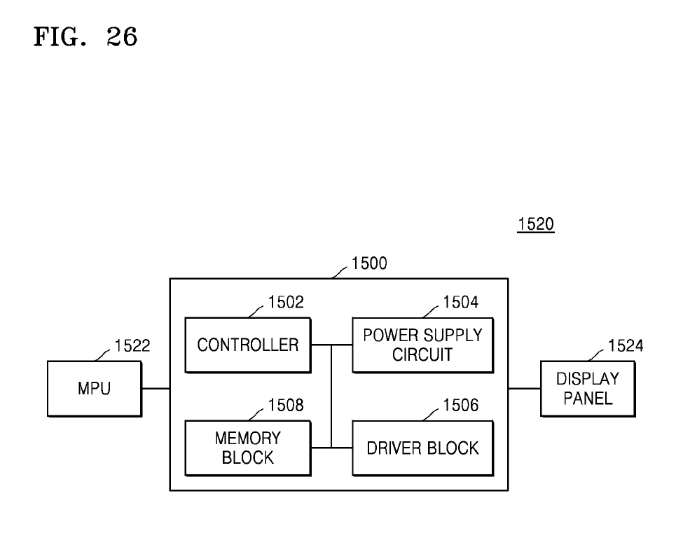

FIG. 26 is a schematic block diagram of an exemplary display device 1520 including a display driver IC (DDI) 1500, according to exemplary embodiments.

Referring to FIG. 26, the DDI 1500 may include a controller 1502, a power supply circuit 1504, a driver block 1506, and a memory block 1508. The controller 1502 may receive a command from a main processing unit (MPU) 1522, decode the command and control respective blocks of the DDI 1500 to embody an operation in response to the command. The power supply circuit 1504 may generate a driving voltage under the control of the controller 1502. The driver block 1506 may drive a display panel 1524 by using a driving voltage generated by the power supply circuit 1504 under the control of the controller 1502. The display panel 1524 may be a liquid crystal display (LCD) panel or a plasma display panel (PDP). The memory block 1508 may be a block configured to temporarily store commands input to the controller 1502 or control signals output by the controller 1502 or store required data. The memory block 1508 may include a memory, such as a random access memory (RAM) or a read-only memory (ROM). At least one of the controller 1502, the power supply circuit 1504 and the driver block 1506 may include at least one of the semiconductor devices 100, 200 to 200i, and 300 to 300i, as disclosed and described in connection with FIGS. 1 to 24.

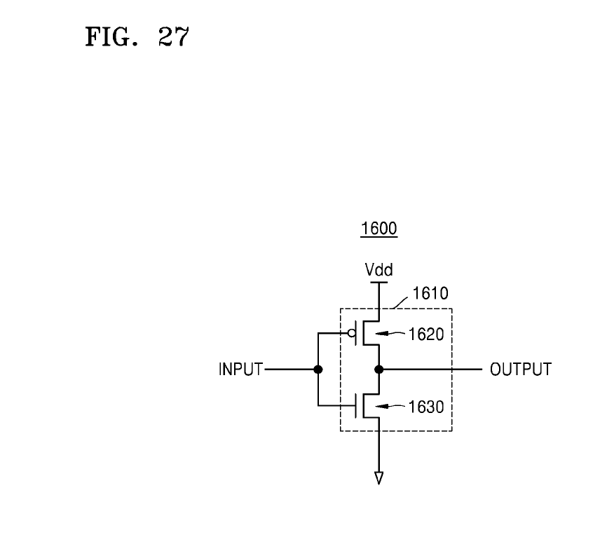

FIG. 27 is a circuit diagram of a complementary metal-oxide semiconductor (CMOS) inverter 1600 according to an exemplary embodiment.

Referring to FIG. 27, the CMOS inverter 1600 may include a CMOS transistor 1610. The CMOS transistor 1610 may include a PMOS transistor 1620 and an NMOS transistor 1630 connected between a power terminal Vdd and a ground terminal. The CMOS transistor 1610 may include at least one of the semiconductor devices 100, 200 to 200i, and 300 to 300i, as disclosed and described in connection with to FIGS. 1 to 24.

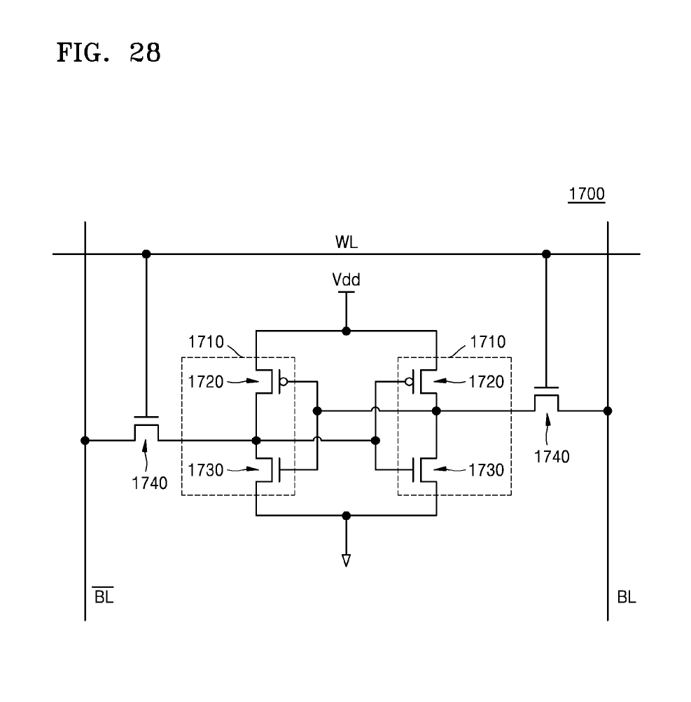

FIG. 28 is a circuit diagram of a CMOS SRAM device 1700 according to an exemplary embodiment.

Referring to FIG. 28, the CMOS SRAM device 1700 may include one pair of driving transistors 1710. The one pair of driver transistors 1710 may include a PMOS transistor 1720 and an NMOS transistor 1730 connected between a power supply terminal Vdd and a ground terminal. The CMOS SRAM device 1700 may further include one pair of transfer transistors 1740. A source of the transfer transistor 1740 may be cross-connected to a common node of the PMOS transistor 1720 and the NMOS transistor 1730, which may constitute the driver transistor 1710. The power supply terminal Vdd may be connected to a source of the PMOS transistor 1720, and the ground terminal may be connected to a source of the NMOS transistor 1730. A word line WL may be connected to gates of the one pair of transfer transistors 1740, and a bit line BL and an inverted bit line may be respectively connected to drains of the one pair of transfer transistors 1740.

At least one of the driving transistor 1710 and the transmission transistor 1740 of the CMOS SRAM device 1700 may include at least one of the semiconductor devices 100, 200 to 200i, and 300 to 300i, as disclosed and described in connection with FIGS. 1 to 24.

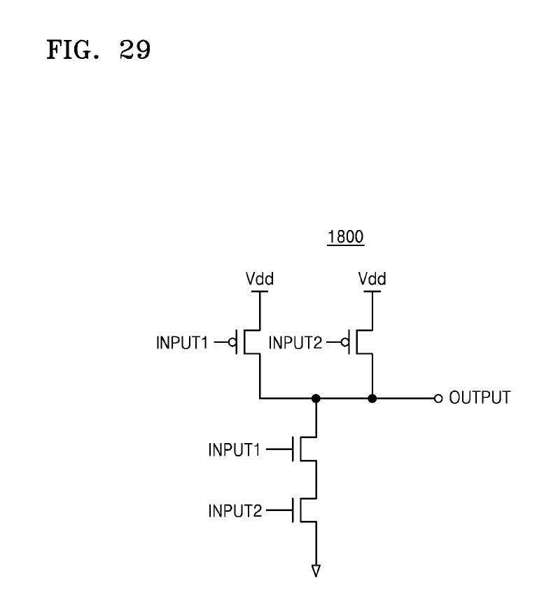

FIG. 29 is a circuit diagram of a CMOS NAND circuit 1800 according to an exemplary embodiment.

Referring to FIG. 29, the CMOS NAND circuit 1800 may include a pair of CMOS transistors to which different input signals are transmitted. The CMOS NAND circuit 1800 may include at least one of the semiconductor devices 100, 200 to 200i, and 300 to 300i described in connection with FIGS. 1 to 24.

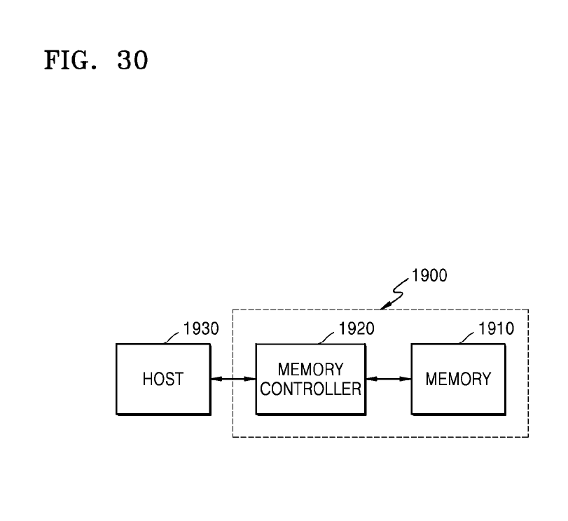

FIG. 30 is a block diagram of an electronic system 1900 according to an exemplary embodiment.

Referring to FIG. 30, the electronic system 1900 may include a memory 1910 and a memory controller 1920. The memory controller 1920 may control the memory 1910 to read data from the memory 1910 and/or write data to the memory 1910 in response to requests from a host 1930. Host 1930 may be any electronic device that is capable and configured to communicate with memory 1920 to store/retrieve data to/from memory 1920. Electronic system 1900, memory 1910, and memory controller 1920, and host 1930 may be connected to and/or in communication with one another by any means known to one of skill in the art. At least one of the memory 1910 and the memory controller 1920 may include at least one of the semiconductor devices 100, 200 to 200i, and 300 to 300i, as disclosed and described in connection with FIGS. 1 to 24.

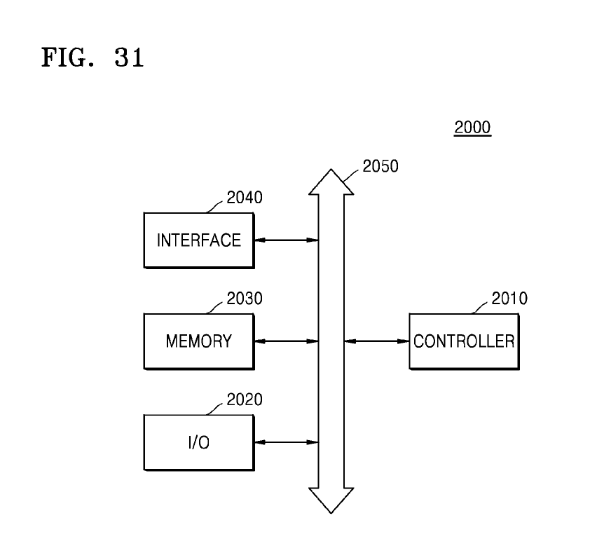

FIG. 31 is a block diagram of an electronic system 2000 according to an exemplary embodiment.

Referring to FIG. 31, the electronic system 2000 may include a controller 2010, an input/output (I/O) device 2020, a memory 2030, and an interface 2040, each of which may be connected to and/or in communication with one another by a bus 2050. In some embodiments, electronic system 2000, controller 2010, input/output (I/O) device 2020, memory 2030, and interface 2040 may be in communication with one another via any combination of bus 2050 or any other means known to one of skill in the art.

The controller 2010 may include, for example, at least one of a microprocessor (MP), a digital signal processor (DSP), and any other processing unit configured to execute computer program instructions to perform various processes and methods, including storing/retrieving data to/from memory. The I/O device 2020 may include, for example, at least one of a microphone, a speaker, a mouse, a keypad, a keyboard, or a display. The memory 2030 may be used to store commands executed by the controller 2010. For example, the memory 2030 may be used to store user data or data input by the user.

The electronic system 2000 may be, for example, a wireless communication device or a device capable of transmitting and/or receiving information in wireless environments. The interface 2040 may include a wireless interface so that the electronic system 2000 may transmit and/or receive data through a wireless communication network. The interface 2040 may include an antenna and/or a wireless transceiver. In some exemplary embodiments, the electronic system 2000 may be used for a communication interface protocol of a third-generation communication system, such as, for example, code division multiple access (CDMA), global system for mobile communications (GSM), north American digital cellular (NADC), extended-time division multiple access (E-TDMA), wide band code division multiple access (WCDMA), etc. The electronic system 2000 may include at least one of the semiconductor devices 100, 200 to 200i, and 300 to 300i, as disclosed and described in connection with FIGS. 1 to 24.

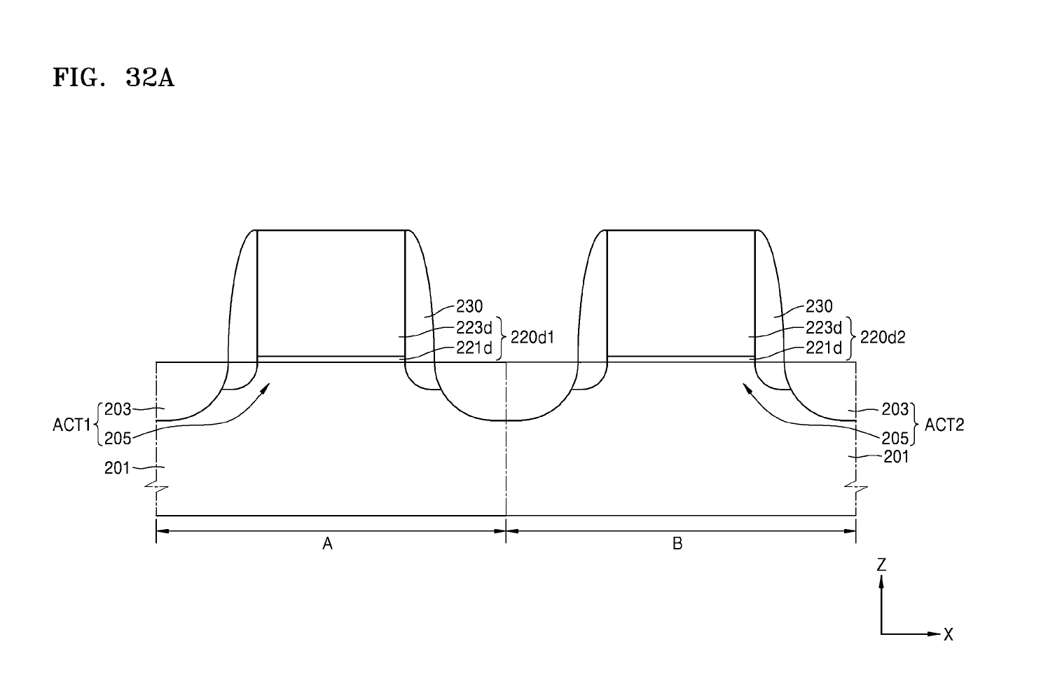

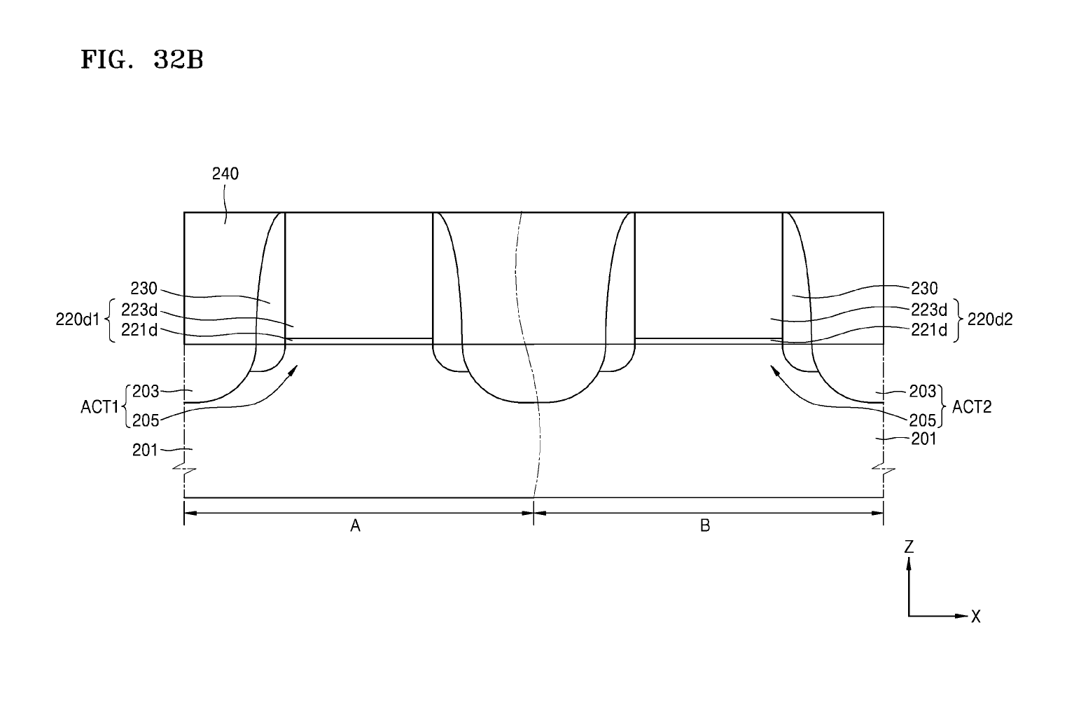

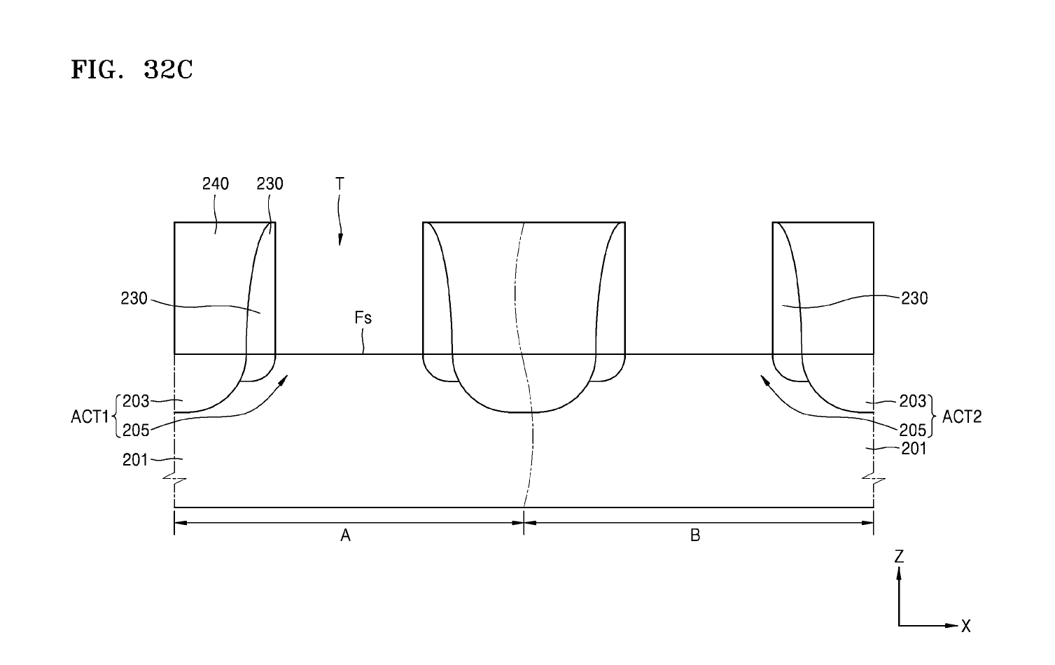

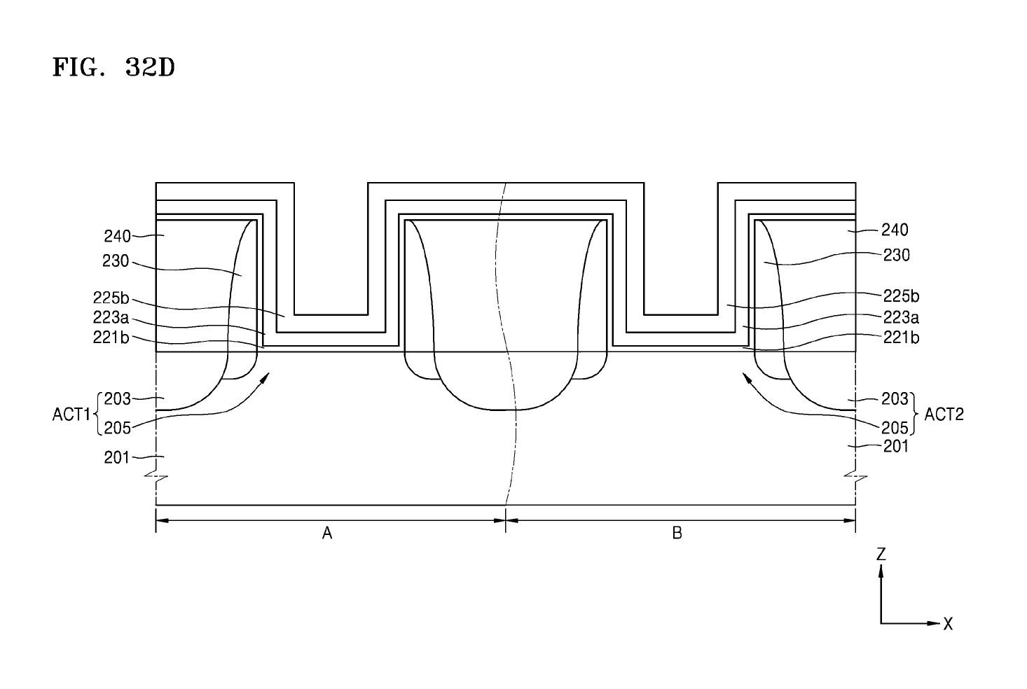

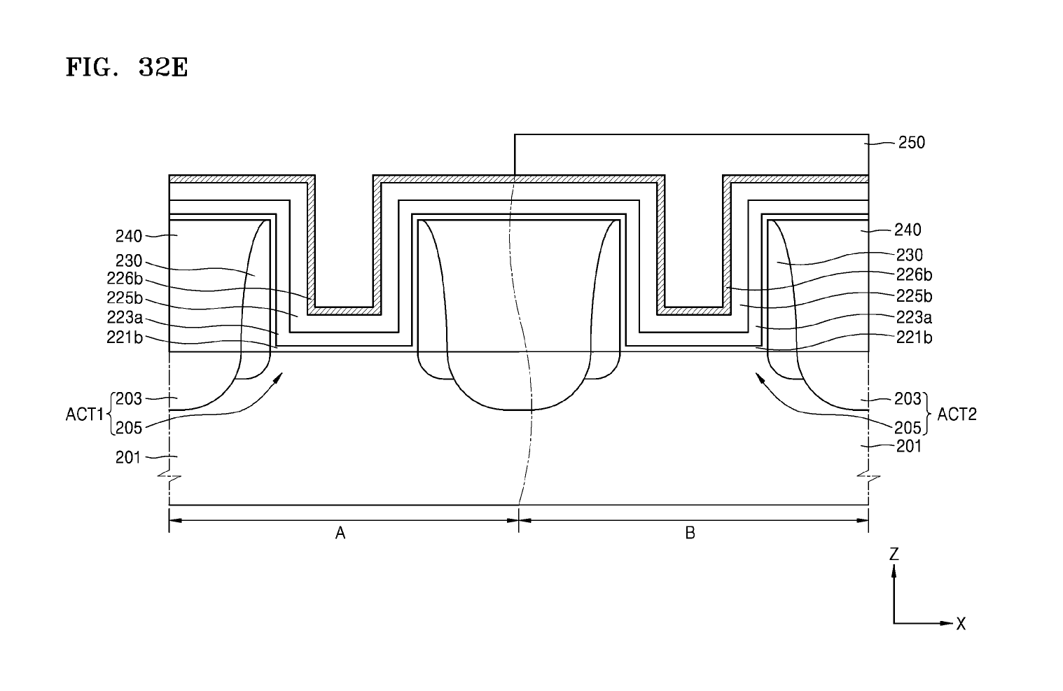

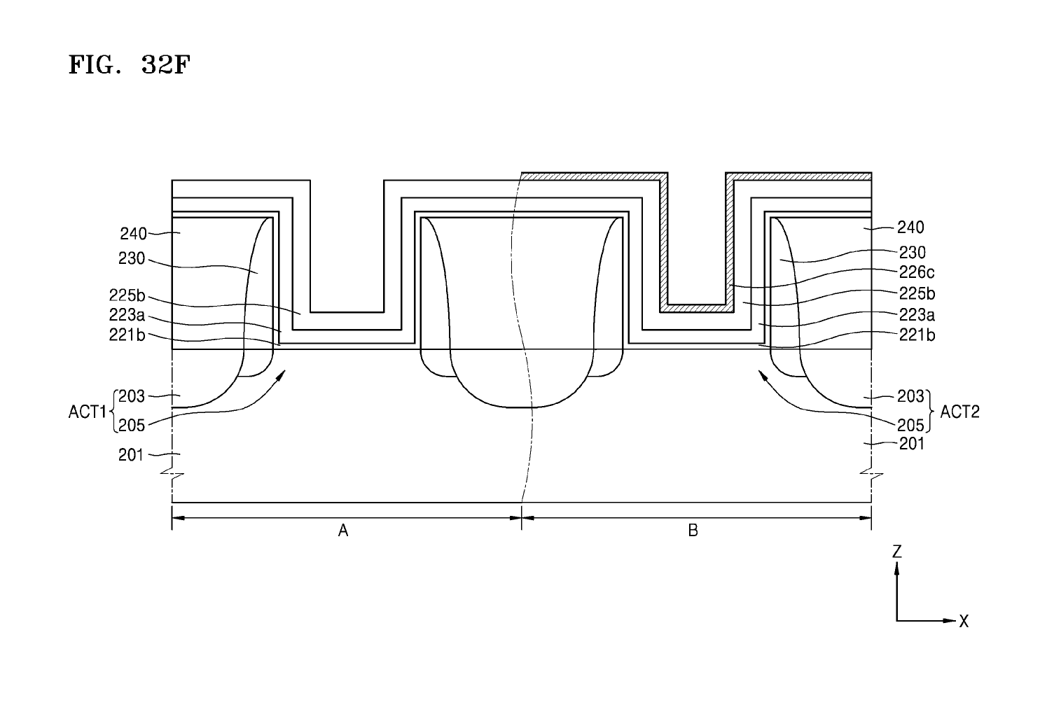

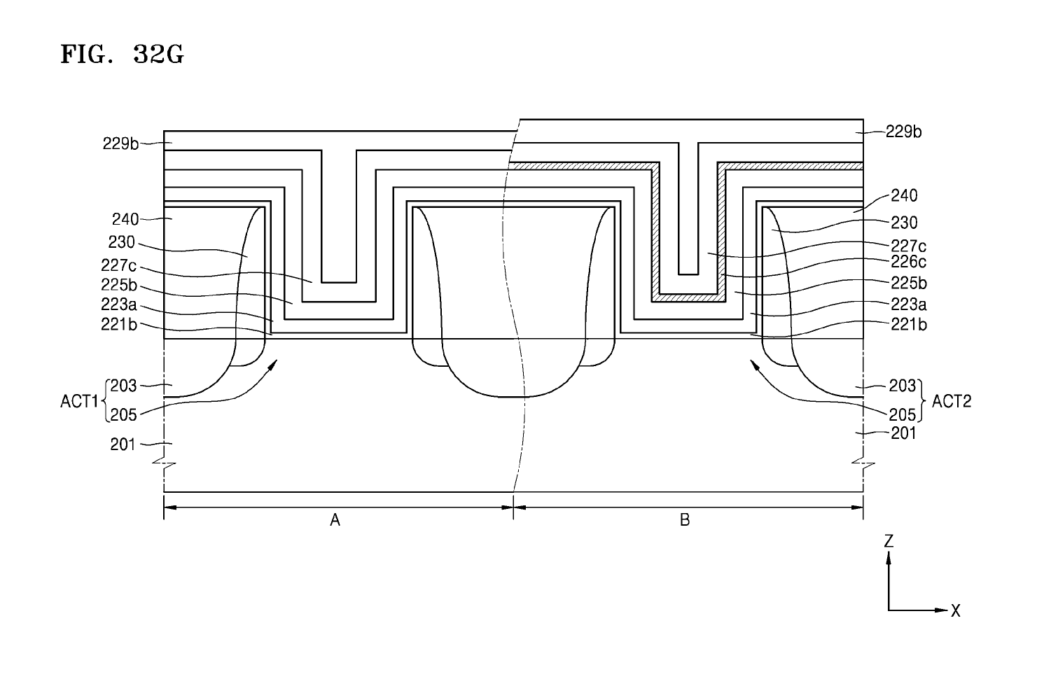

FIGS. 32A to 32G are cross-sectional views of a method of manufacturing the semiconductor device, such as, for purposes of example, the semiconductor device 200 of FIG. 4A, according to an exemplary embodiment.

Referring to FIG. 32A, a first dummy gate structure 220d1 may be formed on a first region A of a semiconductor substrate 201, and a second dummy gate structure 220d2 may be formed on a second region B of the semiconductor substrate 201. Also, spacers 230 may be formed on both sidewalls of each of the first dummy gate structure 220d1 and the second dummy gate structure 220d2. More specifically, a sacrificial insulating layer and a sacrificial gate layer may be formed on the semiconductor substrate 201 and patterned using a photolithography process, thereby forming a dummy insulating layer 221d and a dummy gate electrode 223d. The first dummy gate structure 220d1 may be formed on the first region A, and the second dummy gate structure 220d2 may be formed on the second region B. The sacrificial insulating layer may be formed of a carbon (C)-rich amorphous carbon layer (ACL) or hardmask C-SOH, and the sacrificial gate layer may be formed of polysilicon (poly-Si). However, materials of the sacrificial insulating layer and the sacrificial gate layer are not limited to the above-described materials, and it is anticipated that suitable alternative materials may be used. Meanwhile, the dummy insulating layer 221d may subsequently function as an etch stop layer during a subsequent process of removing the dummy gate electrode 223d.

After the first dummy gate structure 220d1 and the first dummy gate structure 220d1 are formed, the spacers 230 may be formed on both sidewalls of each of the first dummy gate structure 220d1 and the first dummy gate structure 220d1. The formation of the spacers 230 may include forming an insulating layer to uniformly cover the resultant structure on the semiconductor substrate 201, removing the insulating layer from a top surface of the dummy gate structure 223d and a top surface of the semiconductor substrate 201 by using a dry etching process and/or an etchback process to leave the insulating layer on both sidewalls of each of the dummy insulating layer 221d and the dummy gate electrode 223d. The spacers 230 may be formed of an insulating material, such as a nitride layer or an oxynitride layer. For example, the spacers 230 may include a silicon nitride layer or a silicon oxynitride layer.

After the spacers 230 are formed, an ion implantation process may be performed using the dummy gate structure 220d and the spacers 230 as masks so that impurity regions (e.g., source and drain regions 203) may be formed in an upper region of the semiconductor substrate 201. Also, before the spacers 230 are formed, an ion implantation process may be performed to form the lightly doped region (e.g., a lightly doped regions 203l, such as that disclosed and described in connection with FIG. 4A).

Referring to FIG. 32B, an insulating layer may be formed to cover the resultant structure formed on the semiconductor substrate 201. The insulating layer may be planarized to form an interlayer insulating layer 240. In some embodiments, the planarization of the insulating layer may be performed using a chemical-mechanical planarization (CMP) process. For example, the insulating layer may be planarized to expose top surfaces of the dummy gate structures 220d1 and 220d2. The interlayer insulating layer 240 may include at least one of a silicon oxide layer, a silicon nitride layer, a silicon oxynitride layer, and a combination thereof, and may be formed of a material having an etch selectivity with respect to the spacers 230.

Referring to FIG. 32C, after the interlayer insulating layer 240 is formed, the first and second dummy gate structures 220d1 and 220d2 may be removed. A top surface Fs of the semiconductor substrate 201 may be exposed via a trench T formed by removing the first and second dummy gate structures 220d1 and 220d2. The spacers 230 and the interlayer insulating layer 240 may have an etch selectivity with respect to the first and second dummy gate structures 220d1 and 220d2. Thus, the first and second dummy gate structures 220d1 and 220d2 may be removed by using, for example, a wet etching process. Also, the removal of the first and second dummy gate structures 220d1 and 220d2 may be performed by sequentially removing the dummy gate electrode 223d and the dummy insulating layer 221d.

Referring to FIG. 32D, an interfacial layer 221b, a high-k dielectric layer 223a, and a capping metal layer 225b may be sequentially and conformally formed on the resultant structure formed on the semiconductor substrate 201. Materials forming the interfacial layer 221b, the high-k dielectric layer 223a, and the capping metal layer 225b may be the same as in the semiconductor device 100, as disclosed and described in connection with FIG. 1. The interfacial layer 221b, the high-k dielectric layer 223a, and the capping metal layer 225b may be formed by using various deposition methods, such as an atomic layer deposition (ALD) process, a chemical layer deposition (CVD) process, or a physical vapor deposition (PVD) process.

In some embodiments, a film structure and a thickness of the high-k dielectric layer 223a may be adjusted by controlling process conditions. For instance, the film structure and thickness of the high-k dielectric layer 223a may be adjusted by appropriately selecting a process temperature, a process time, and/or source materials. For example, by controlling process conditions, the high-k dielectric layer 223a may be formed to have a columnar grain boundary structure.

Similarly, a film structure, metal content, and thickness of the capping metal layer 225b may be adjusted by controlling process conditions. For example, by controlling process conditions, such as a process temperature and a process time, the capping metal layer 225b may have a columnar grain boundary structure. Further, the capping metal layer 225b may include silicon (Si) as a source material so that the film structure of the capping metal layer 225b may be similar to an amorphous structure.

Referring to FIG. 32E, a dielectric layer 226b may be conformally formed on the resultant structure formed on the semiconductor substrate 201. The dielectric layer 226b may be formed by using various deposition methods, such as an ALD process, a CVD process, or a PVD process. A material or thickness of the dielectric layer 226b may be the same as in the semiconductor device 100, as disclosed and described in connection with FIG. 1.

After the dielectric layer 226b is formed, a mask pattern 250 may be formed to cover the second region B. The mask pattern 250 may be formed by using a photolithography process. The mask pattern 250 may be formed of a material having an etch selectivity with respect to the dielectric layer 226b, and may include a single layer or a multilayer structure. For example, a mask layer may be formed to cover the dielectric layer 226b. In this case, the mask layer may be formed to completely fill a gap that remains after the dielectric layer 226b is formed. In some cases, a planarization process may be performed on the mask layer. After the mask layer is formed, a photoresist (PR) layer may be formed on the mask layer. Subsequently, the PR layer may be patterned using a photolithography process to form a PR pattern covering the second region B. The underlying mask layer may be etched by using the PR pattern to form the mask pattern 250 covering the second region B.

Alternatively, after the dielectric layer 226b is formed, if the remaining gap is too wide to be filled with the mask layer, a sacrificial layer may be further formed to fill the gap, and the mask layer may be formed on the sacrificial layer. In this case, an etching process may be performed twice to subsequently remove the dielectric layer 226b from the first region A.

Referring to FIG. 32F, after the mask pattern 250 is formed, a portion of the dielectric layer 226b of the first region A may be removed by performing an etching process using the mask pattern 250 as an etch mask. As described above, the mask pattern 250 may have an etch selectivity with respect to the dielectric layer 226b. Accordingly, a portion of the dielectric layer 226b of the second region B, which is covered with the mask pattern 250, may not be removed, but may remain. After the portion of the dielectric layer 226b of the first region A is removed, the mask pattern 250 may be removed so that a dielectric layer 226c remains only on the first region B.

Meanwhile, since the capping metal layer 225b is present under the dielectric layer 226b, when the dielectric layer 226b is etched, damage to the underlying high-k dielectric layer 223a may be prevented due to the presence of the capping metal layer 225b. Thus, reliability and performance of the semiconductor device 200 may be improved. Generally, to form a metal electrode having different work functions, a plurality of metal layers may be formed and some of the metal layers may be patterned. However, due to a low etch selectivity between the metal layers, it may be difficult to pattern the metal layers to preclude forming a metal layer having a required structure. In the semiconductor device 200, it may be possible to pattern the dielectric layer 226b without patterning metal layers so that problems caused by the patterning of the metal layers may be solved.

Referring to FIG. 32G, after the dielectric layer 226c is left only on the second region B, a work function metal layer 227c and a gap-fill metal layer 229b may be sequentially formed on the resultant structure formed on the semiconductor substrate 201. Since the dielectric layer 226c is further formed in the second region B, as shown in FIG. 32G, top surfaces of the work function metal layer 227c and the gap-fill metal layer 229b in the second region B may be at a higher level than top surfaces of the work function metal layer 227c and a gap-fill metal layer 229b in the first region A. Materials forming the work function metal layer 227c and the gap-fill metal layer 229b may be the same as in the semiconductor device 100, as disclosed and described in connection with FIG. 1. Also, the work function metal layer 227c and the gap-fill metal layer 229b may be formed using various deposition methods, such as an ALD process, a CVD process, or a PVD process.

After the work function metal layer 227c and the gap-fill metal layer 229b are formed, a planarization process may be performed. The planarization process may be performed using, for example, a CMP process, and material layers formed on the interlayer insulating layer 240 may be removed to expose a top surface of the interlayer insulating layer 240. Thus, the material layers formed on the interlayer insulating layer 240 may be removed using the planarization process so that gate structures may be electrically isolated from one another. Thus, a first gate structure 220a and a second gate structure 220b may be formed like in the semiconductor device 200, as disclosed and described in connection with FIG. 4A.

After the first and second gate structures 220a and 220b are formed, a subsequent semiconductor process may be performed. The subsequent semiconductor process may include various processes. For example, the subsequent semiconductor process may include a deposition process, an etching process, an ion process, and/or a cleaning process. Here, the deposition process may include various processes (e.g., a CVD process, a sputtering process, or a spin coating process) of forming material layers. The etching process may be an etching process using plasma or a typical plasma-free etching process. The ion process may include an ion implantation process, a diffusion process, or an annealing process. By performing the subsequent semiconductor process, ICs and interconnections for a desired semiconductor device may be formed.

Meanwhile, the subsequent semiconductor process may include a packaging process, including mounting the semiconductor device on a printed circuit board (PCB) and encapsulating the resultant structure with an encapsulant. Also, the subsequent semiconductor process may include a test process during which the semiconductor device and/or a semiconductor package is/are tested. The subsequent semiconductor processes may be performed, thereby completing manufacture of the semiconductor device or the semiconductor package.

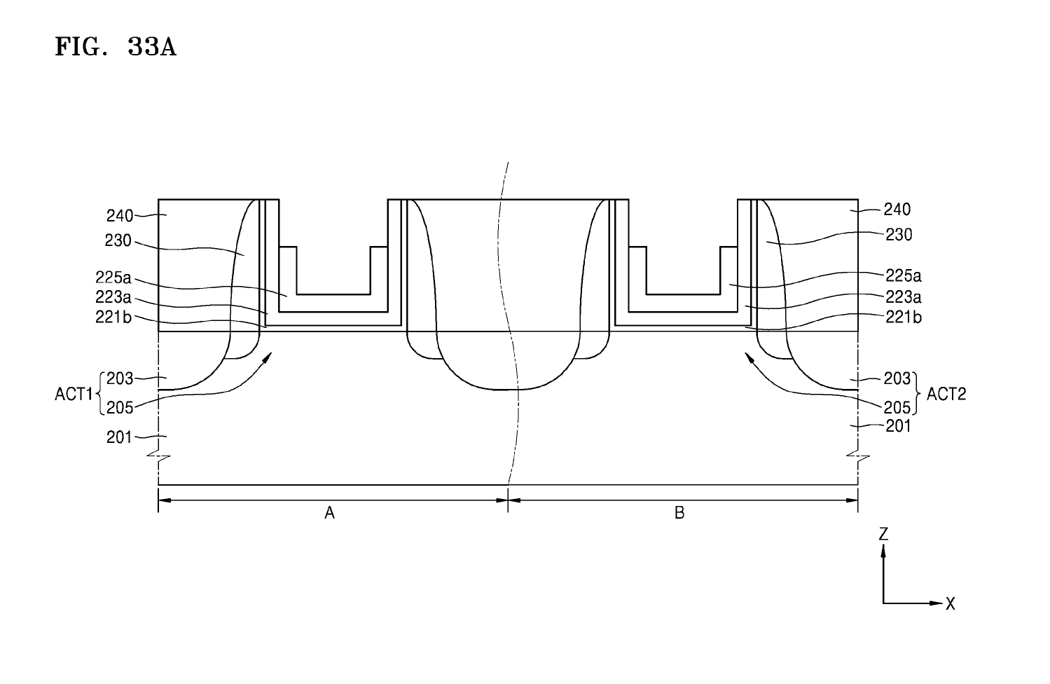

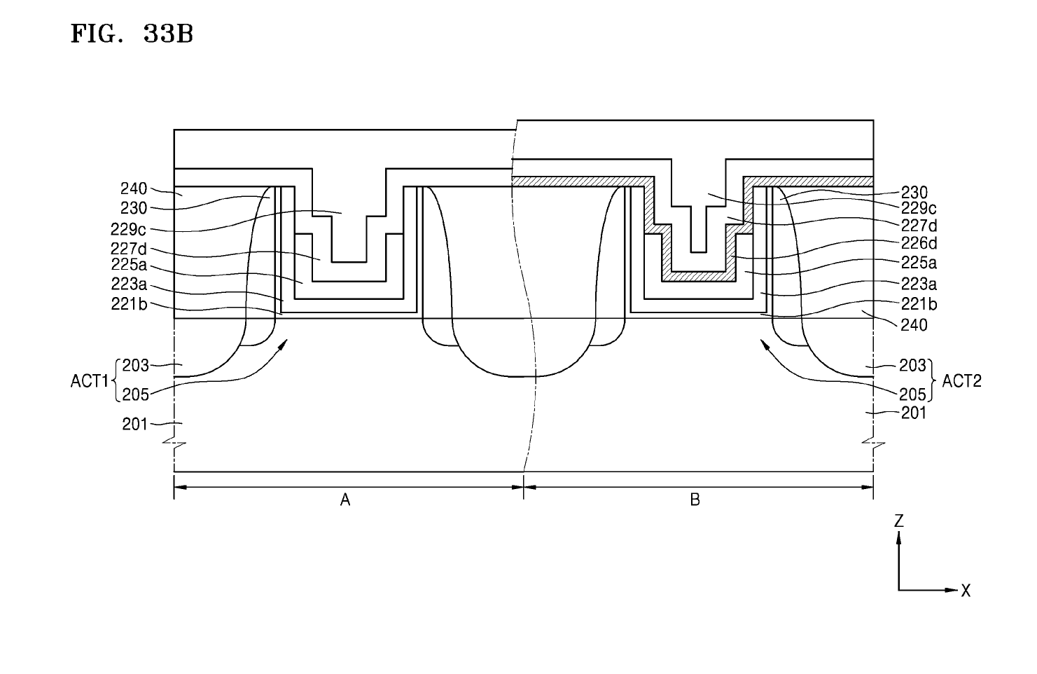

FIGS. 33A and 33B are cross-sectional views of a method of manufacturing the semiconductor device of FIG. 12.

Referring to FIG. 33A, the processes described with reference to FIGS. 32A to 32C may be performed to remove the dummy gate structures 220d1 and 220d2 and expose a top surface Fs of the semiconductor substrate 201 via a trench T. Thereafter, as described with reference to FIG. 32D, an interfacial layer 221b, a high-k dielectric layer 223a, and a capping metal layer may be sequentially and conformally formed on the resultant structure formed on the semiconductor substrate 201.

Thereafter, to remove a partial upper portion of the capping metal layer 225a, a mold material layer (not shown) may be formed to fill the gap in which the capping metal layer 225a is formed, and cover the resultant structure formed on the semiconductor substrate 201. Thereafter, a planarization process may be performed by a CMP process to expose the interlayer insulating layer 240. An upper portion of the capping metal layer 225a, which is exposed by using the planarization process and formed on upper side portions of the high-k dielectric layer 223, may be removed to form a buried capping metal layer 225a as shown in FIG. 33A. After the buried capping metal layer 225a is formed, the remaining mold material layer may be completely removed.

In addition, as described with reference to FIG. 12, when a barrier metal layer is formed between the high-k dielectric layer 223a and the capping metal layer 225a, a buried barrier metal layer may be formed by using the above-described method. Thereafter, a capping metal layer 225a may be formed on the buried barrier metal layer, and a process to be described with reference to FIG. 33b may be performed.

Referring to FIG. 33B, after the capping metal layer 225a is formed, a dielectric layer 226d may be left only in the second region B using the process described with reference to FIGS. 32E to 32F. Thereafter, a work function metal layer 227d and a gap-fill metal layer 229c may be formed on the resultant structure formed on the semiconductor substrate 201. Also, since the dielectric layer 226d is further present in the second region B, top surfaces of the work function metal layer 227d and the gap-fill metal layer 229c in the second region B may be at higher levels than top surfaces of the work function metal layer 227d and the gap-fill metal layer 229c in the first region A.

Subsequently, a planarization process may be performed to expose a top surface of the interlayer insulating layer 240 and electrically isolate gate structures from one another. Thus, a first gate structure 220a3 and a second gate structure 220b4 may be formed like in the semiconductor device 200h, as disclosed and described in connection with FIG. 12.

FIGS. 34A to 41C are perspective views and cross-sectional views of a method of manufacturing the semiconductor device of FIG. 14, according to exemplary embodiments. FIGS. 34A, 35A, 36A, 37A, 38A, 39A, 40A, and 41A are perspective views corresponding to FIG. 14. FIGS. 34B, 35B, 36B, 37B, 38B, 39B, 40B, and 41B are cross-sectional views corresponding to FIG. 15A. FIGS. 34C, 35C, 36C, 37C, 38C, 39C, 40C, and 41C are cross-sectional views corresponding to FIG. 15B.

Referring to FIGS. 34A to 34C, an upper portion of a semiconductor substrate 301 may be etched to form a fin 305a protruding from the semiconductor substrate 301. The fin 305a may extend on the semiconductor substrate 301 in a first direction (e.g., x-direction). As shown, the fin 305a may include a lower fin portion 305d and an upper fin portion 305u. The lower fin portion 305d may be a portion that will be subsequently covered with a device isolation layer.

Meanwhile, fins 305a may be respectively formed in a first region A and a second region B on the semiconductor substrate 301. FIG. 34A illustrates an example in which the fins 305a, respectively formed in the first region A and the second region B, extend in the same direction. However, in other examples, the fin 305a of the first region A may extend in a different direction from the fin 305a of the second region B.

In addition, structures and materials of the semiconductor substrate 301 and the fin 305a may be the same as in the semiconductor device 300, as disclosed and described in connection with FIGS. 14 to 15B.

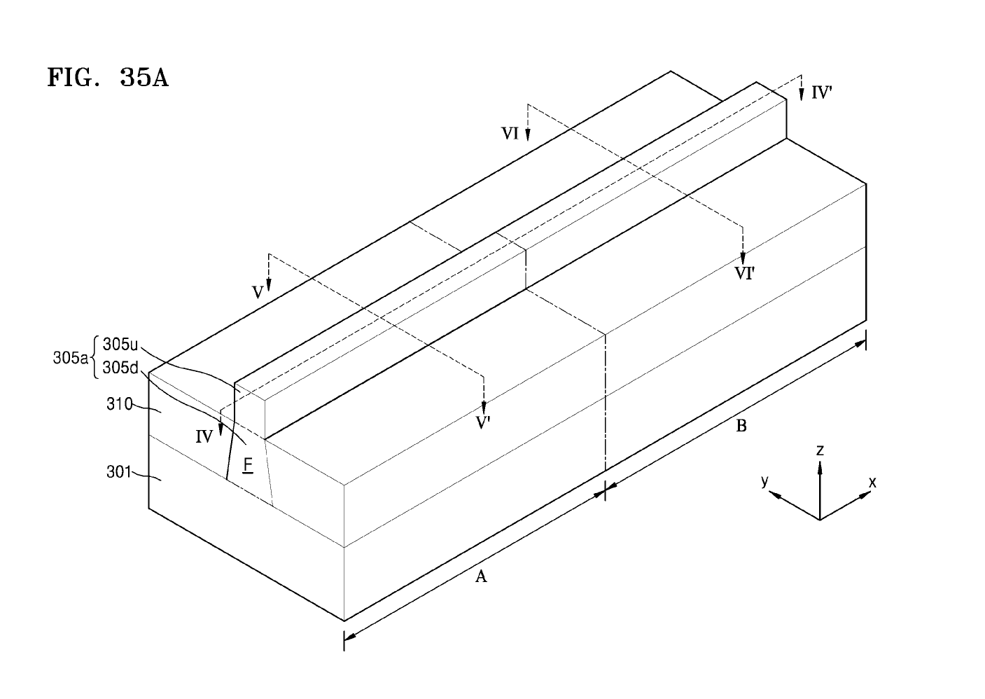

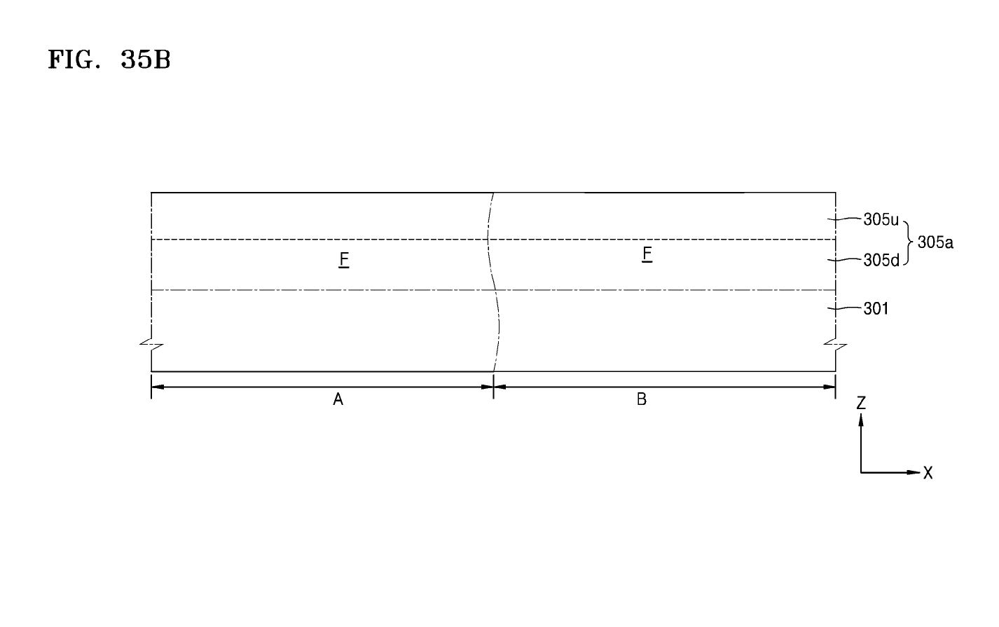

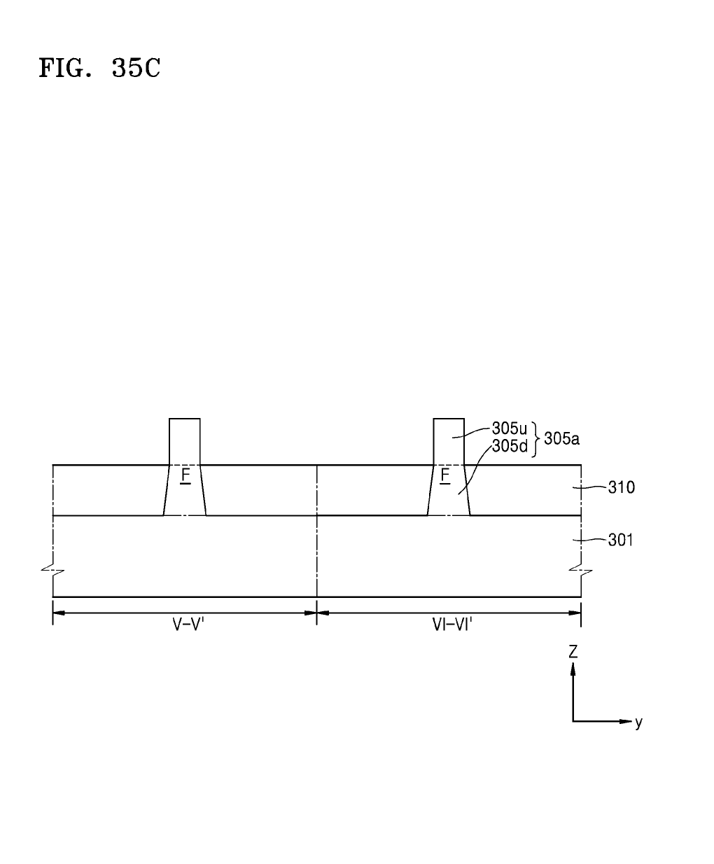

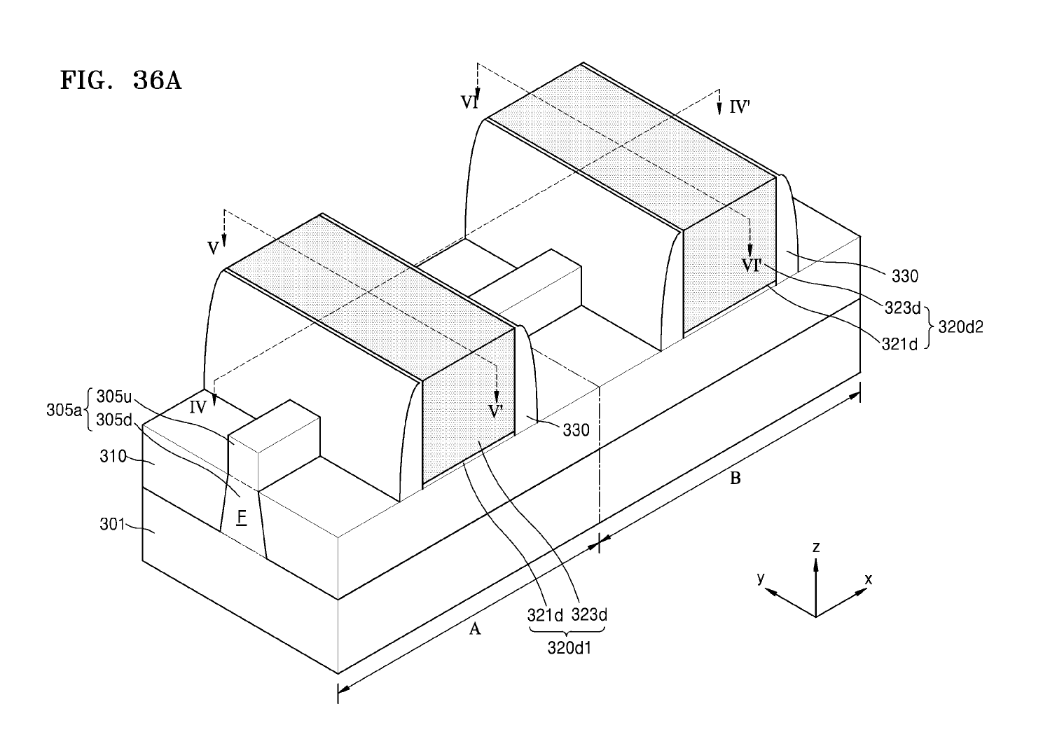

Referring to FIGS. 35A to 35C, after the fin 305a is formed, a device isolation layer 310 may be formed to cover lower portions of both side surfaces of the fin 305a. By forming the device isolation layer 310, an upper portion (i.e., an upper fin portion 305u) of the fin 305a may protrude from the device isolation layer 310.

The formation of the device isolation layer 310 may include forming an insulating layer to cover the resultant structure formed on a semiconductor substrate 301, planarizing the insulating layer, and removing an upper portion of the device isolation layer 310 so that the upper portion of the fin 305a may protrude. In addition, a material of the device isolation layer 310 may be the same as in the semiconductor device 300, as disclosed and described in connection with FIGS. 14 to 15B.

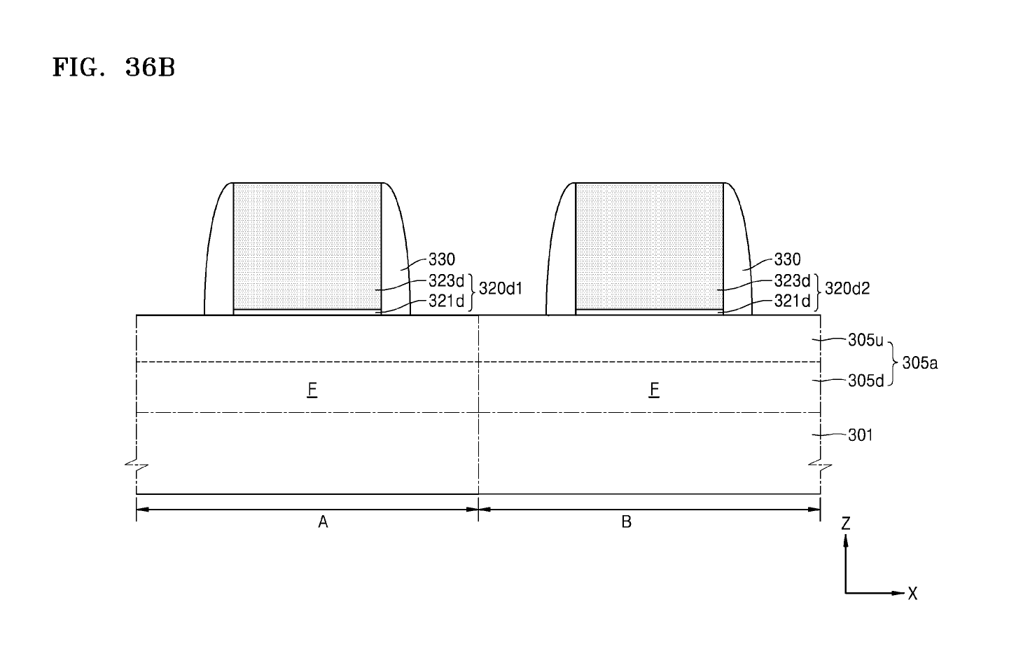

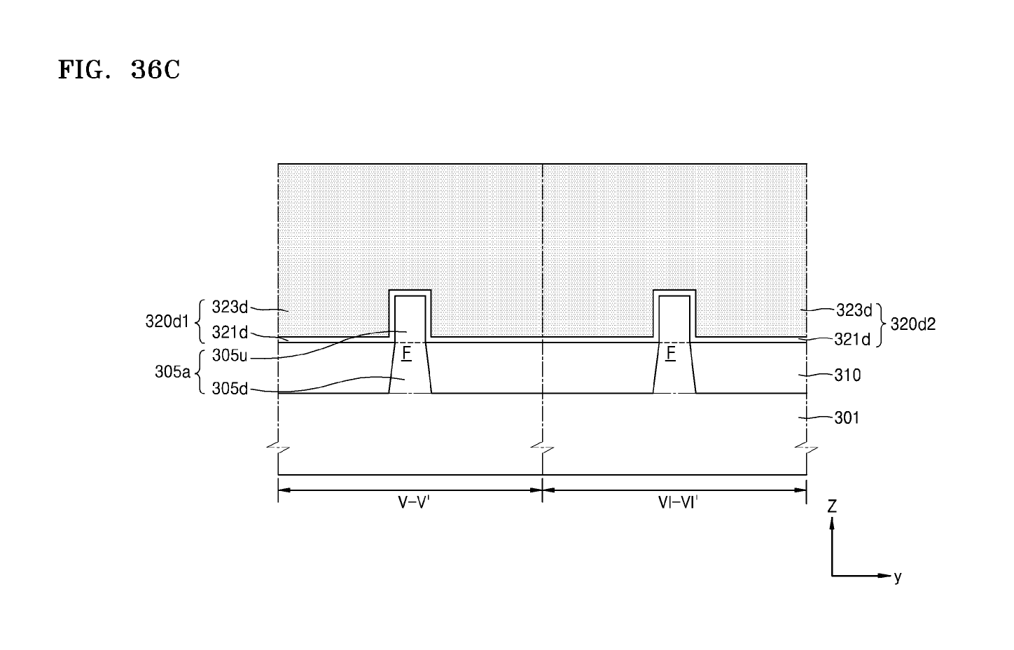

Referring to FIGS. 36A to 36C, after the device isolation layer 310 is formed, first and second dummy gate structures 320d1 and 320d2 may be formed, each of which includes a dummy insulating layer 321d and a dummy gate electrode 323d, and spacers 330 may be formed on both side surfaces of each of the first and second dummy gate structures 320d1 and 320d2. In some embodiments, the first and second dummy gate structures 320d1 and 320d2 may extend in a second direction (e.g., y-direction). As shown in FIGS. 36A to 36C, the first and second dummy gate structure 320d1 and 320d2 may include a first dummy gate structure 320d1 of a first region A and a second dummy gate structure 320d2 of a second region B.

A process of forming the first and second dummy gate structures 320d1 and 320d2 and the spacers 330 may be similar to that disclosed and described in connection with FIG. 32A. However, since the fin 305a protruding from the semiconductor substrate 301 is formed and the device isolation layer 310 is formed to surround two side surfaces of the lower fin portion 305d of the fin 305a, the first and second dummy gate structures 320d1 and 320d2 and the spacers 330 may be formed on the device isolation layer 310 and surround top and side portions of the upper fin portion 305u of the fin 305a.

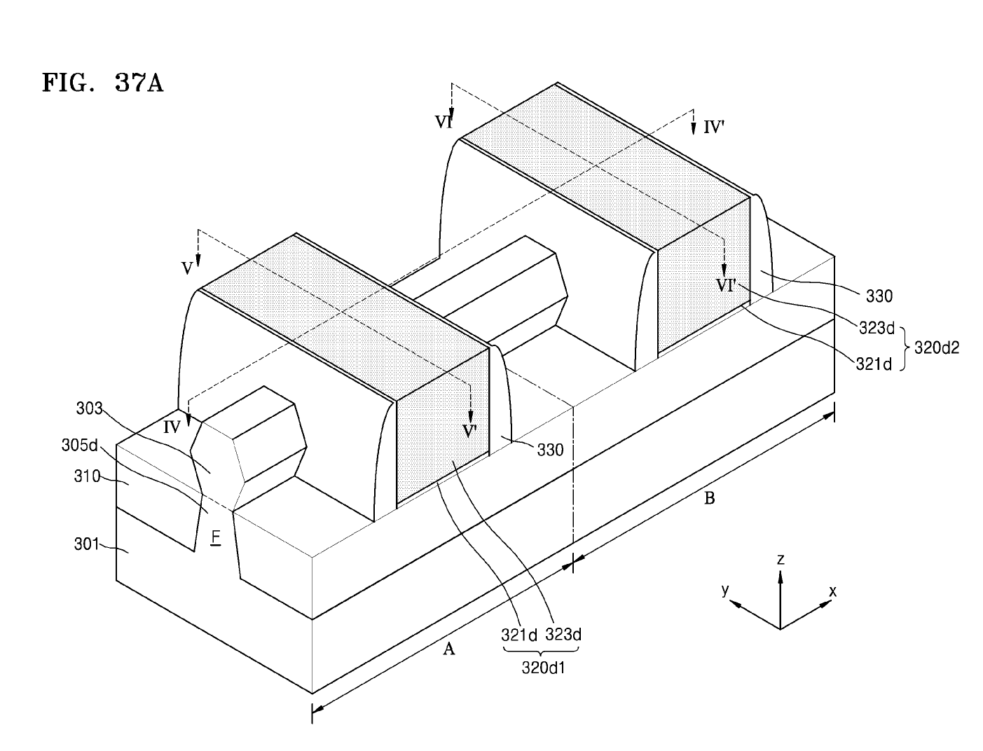

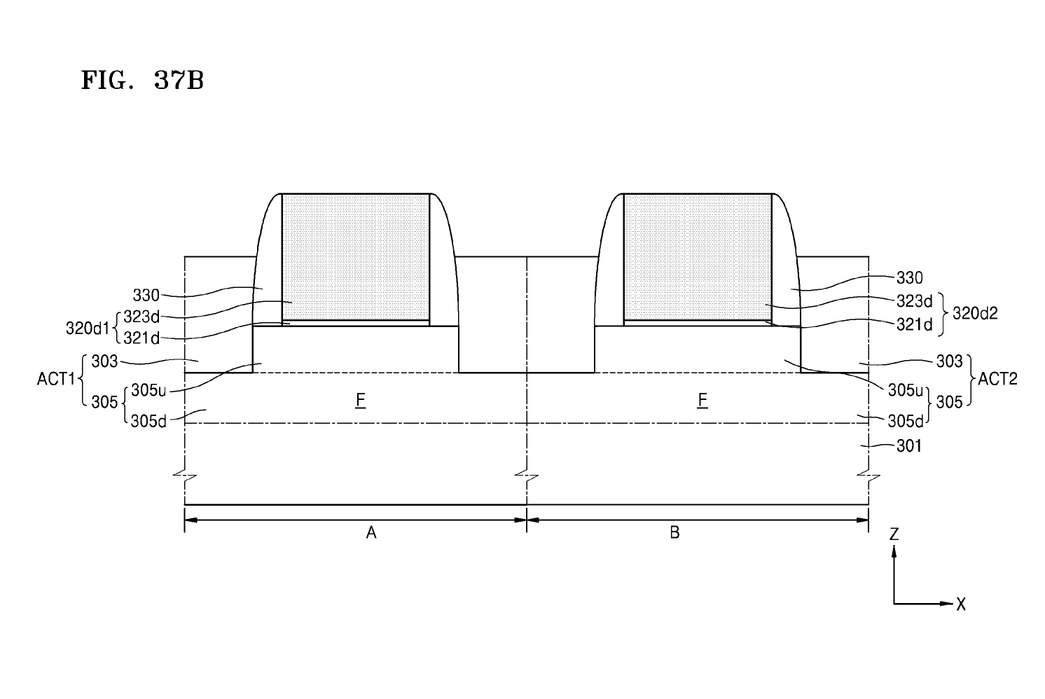

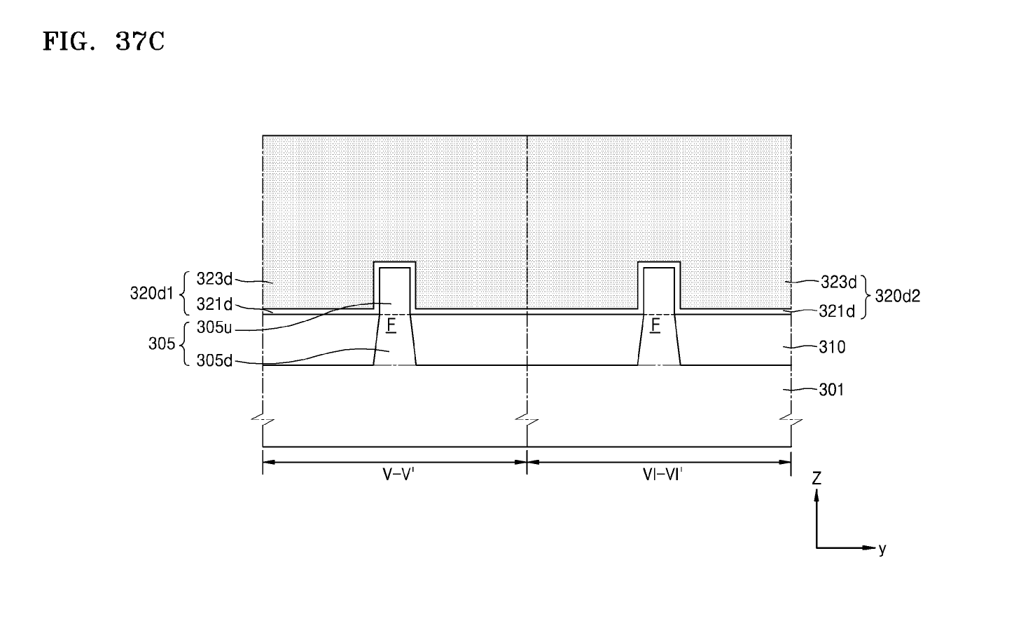

Referring to FIGS. 37A to 37C, the upper fin portions 305u, which protrude from the device isolation layer 310 on both sides of each of the first and second dummy gate structures 320d1 and 320d2, may be removed, and source and drain regions 303 may be formed. For example, the formation of the source and drain regions 303 may include removing the upper fin portions 305u that protrudes from the device isolation layer 310 and growing an epi-layer on the lower fin portions 305d. The source and drain regions 303 may include at least one of silicon germanium (SiGe), germanium (Ge), silicon (Si), and silicon carbide (SiC), which may be epitaxially grown on the lower fin portions 305d. Meanwhile, during or after the process of growing the epi-layer, impurities may be doped into the source and drain regions 303. By forming the source and drain regions 303, the first fin active region ACT1 of the first region A and the second fin active region ACT2 of the second region B may be completed. The first and second fin active regions ACT1 and ACT2 may be the same as that disclosed and described in connection with FIGS. 14 to 15B.

As shown in FIG. 37B, top surfaces of the source and drain regions 303 may be at higher levels than top surfaces of the upper fin portions 305u positioned under the first and second dummy gate structures 320d1 and 320d2. Also, the source and drain regions 303 may cover lower side portions of the spacers 330.

In some cases, the upper fin portions 305u may not be removed, and the source and drain regions 303 may be formed based on the upper fin portions 305u. In this case, the source and drain regions 303 may maintain an original shape of the upper fin portions 305u or have a different shape from the original upper fin portions 305u by growing an epi-layer.

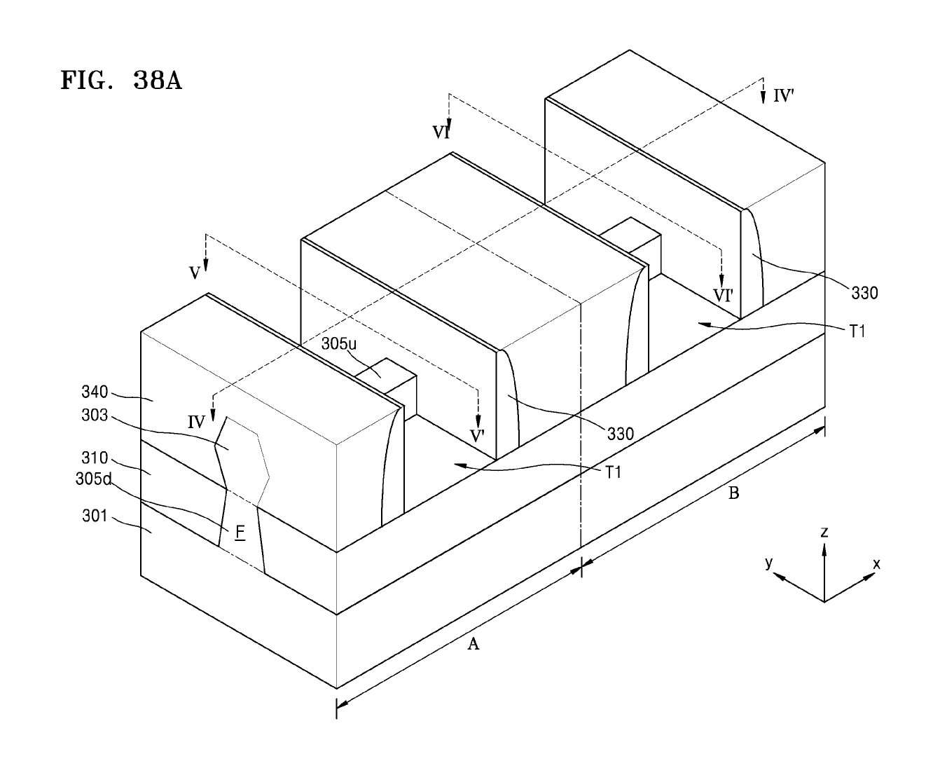

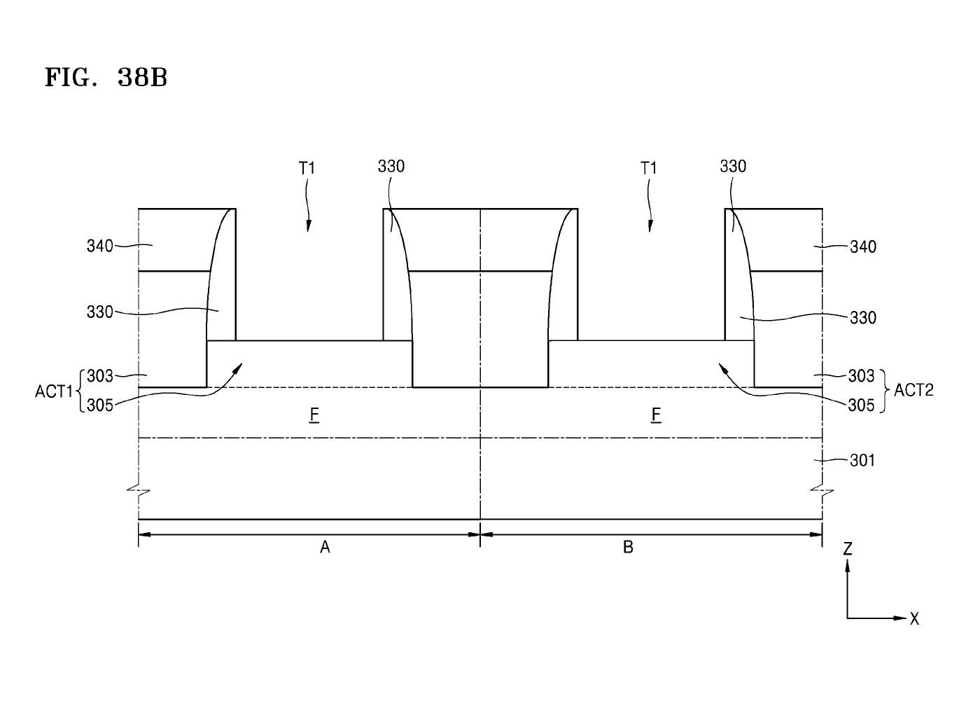

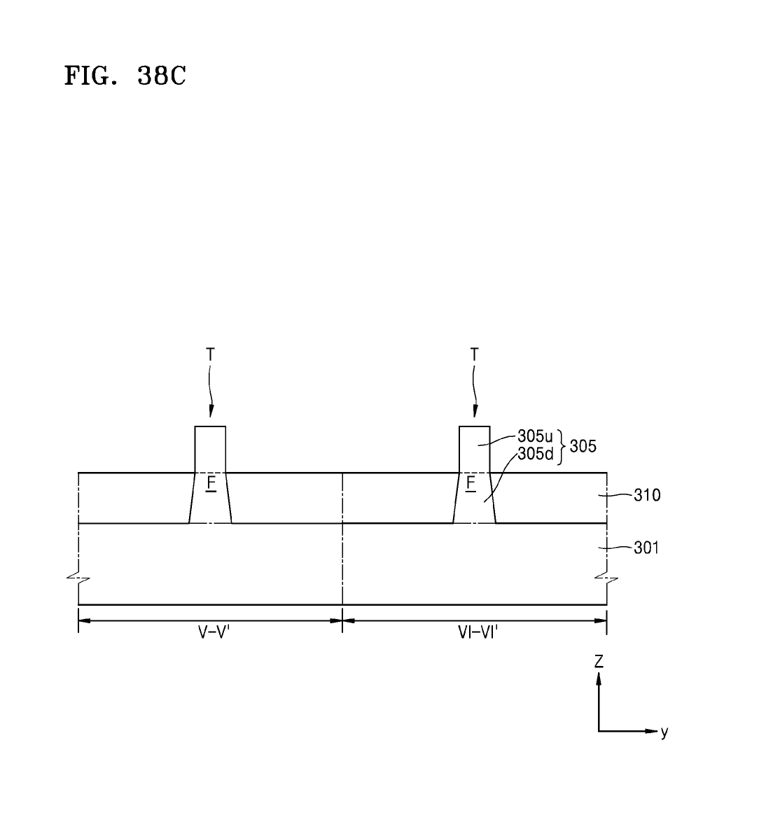

Referring to FIGS. 38A to 38C, after the source and drain regions 303 are formed, an insulating layer may be formed to cover the resultant structure formed on the semiconductor substrate 301 and planarized to form an interlayer insulating layer 340. A material of the interlayer insulating layer 340 may be the same as in the semiconductor device 300, as disclosed and described in connection with FIGS. 14 to 15B.

After the interlayer insulating layer 340 is formed, the first and second dummy gate structures 320d1 and 320d2 may be removed. The process of removing the first and second dummy gate structures 320d1 and 320d2 may be the same as disclosed and described in connection with FIG. 32C. As shown in FIG. 38C, a top surface and side surfaces of the upper fin portion 305u may be exposed by a trench T1 that is formed by removing the first and second dummy gate structures 320d1 and 320d2.

In addition, although not shown in FIG. 38C, after the dummy gate structures 320d1 and 320d2 are removed, side surfaces of the spacers 330 may be seen outside top and side surfaces of the upper fin portions 305u in the sectional structures taken along the lines V-V and VI-VI′.

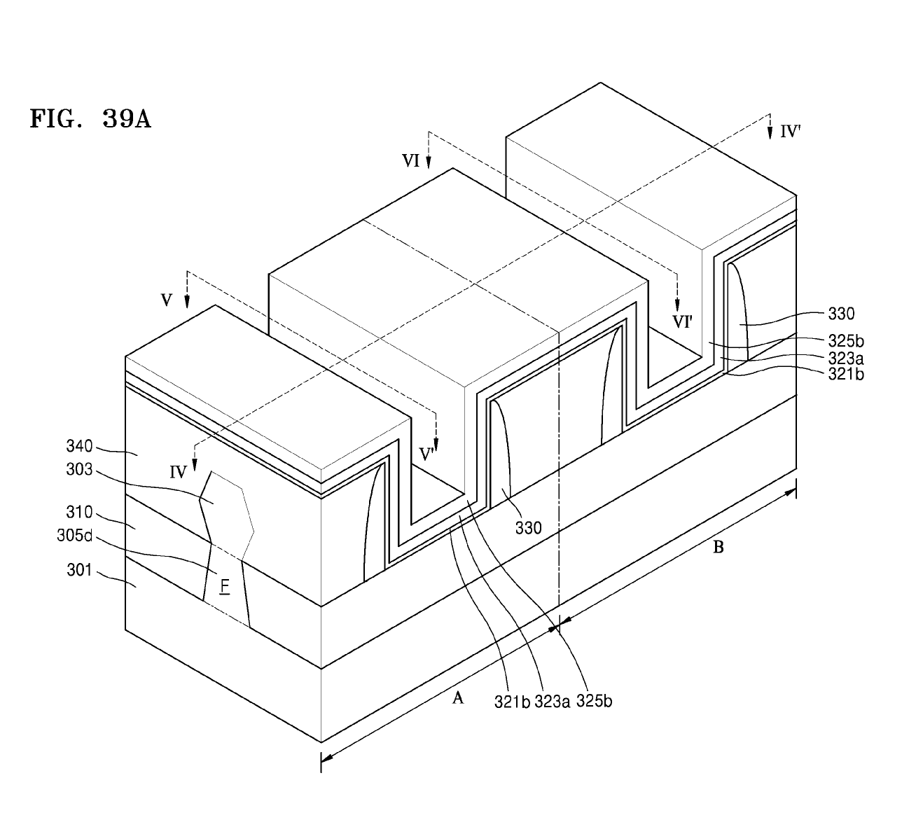

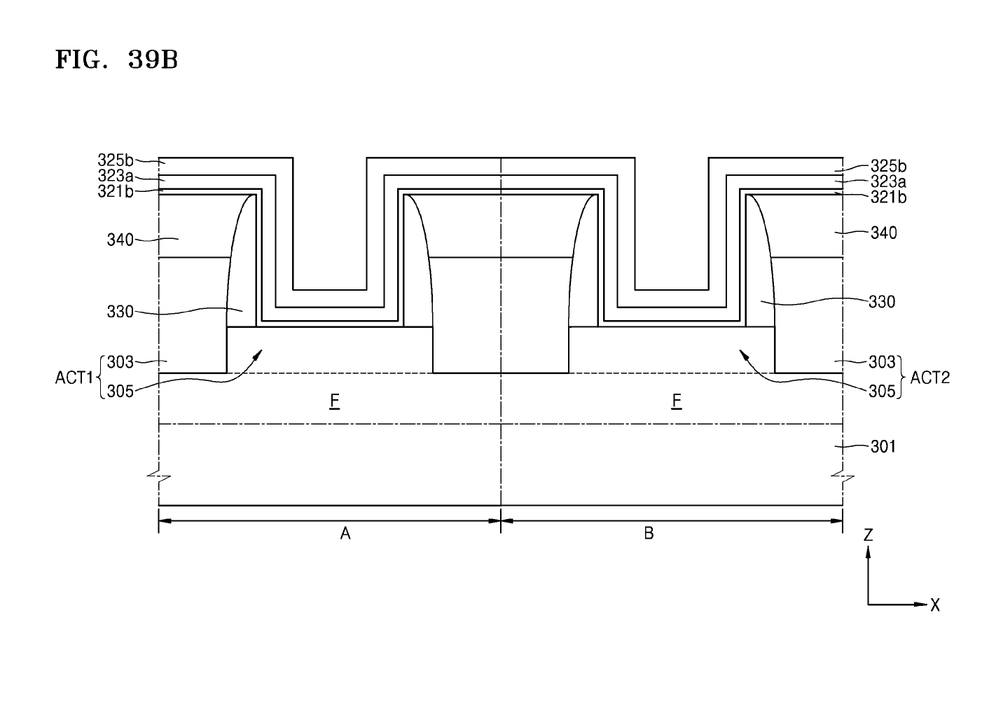

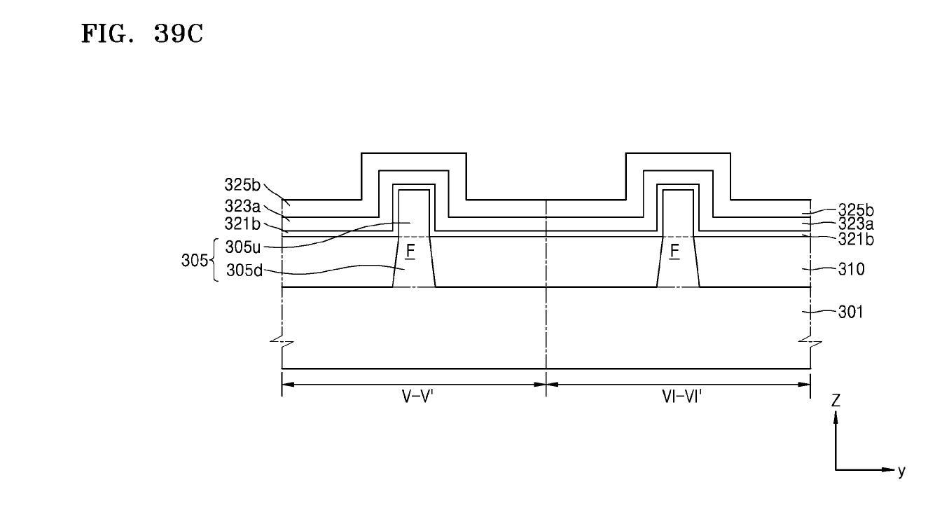

Referring to FIGS. 39A to 39C, an interfacial layer 321b, a high-k dielectric layer 323a, and a capping metal layer 325b may be sequentially and conformally formed on the resultant structure formed on a semiconductor substrate 301. Materials or methods of forming the interfacial layer 321b, the high-k dielectric layer 323a, and the capping metal layer 325b may be the same as those disclosed and described in connection with FIG. 32D.

Although not shown in FIG. 39C, side portions of the capping metal layer 325b may be seen outside, similar to that disclosed and described in connection with FIG. 38C.

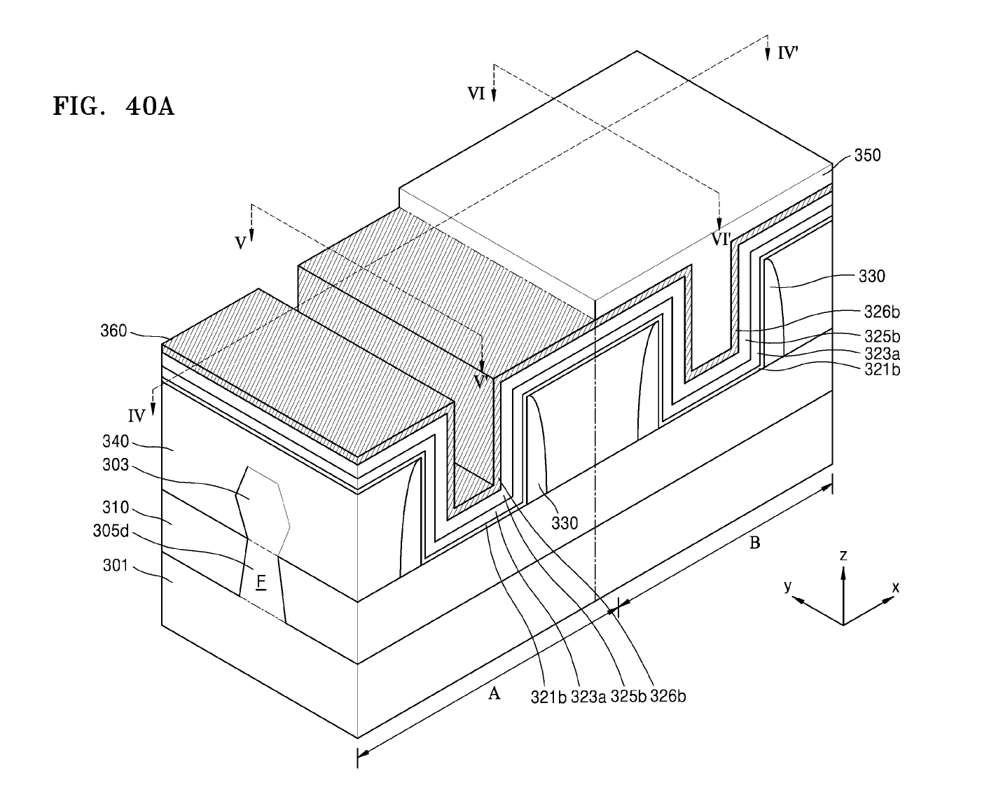

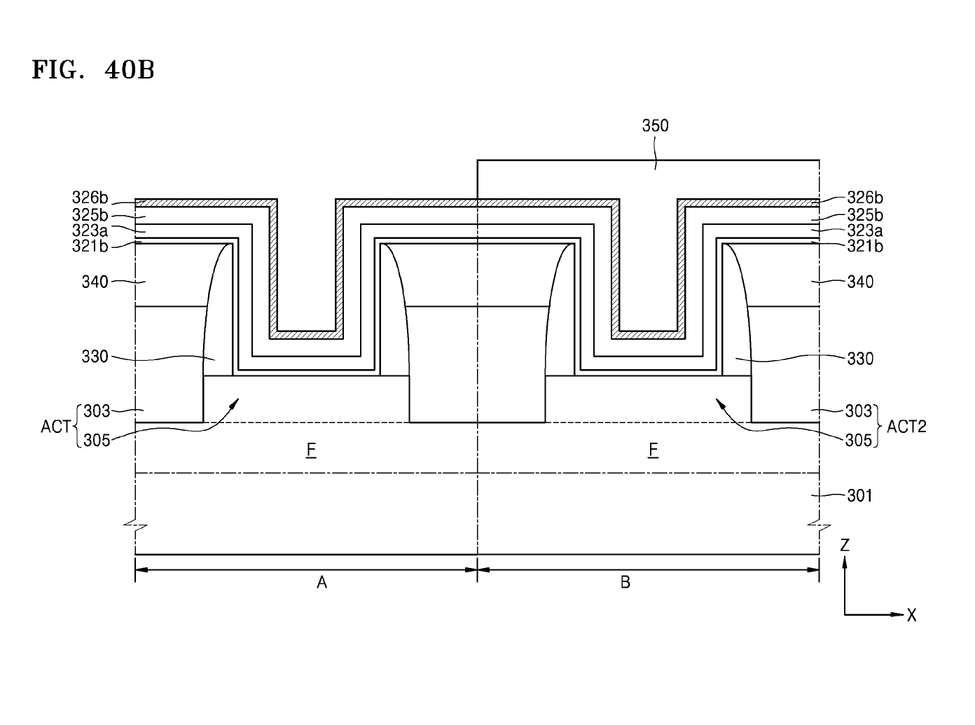

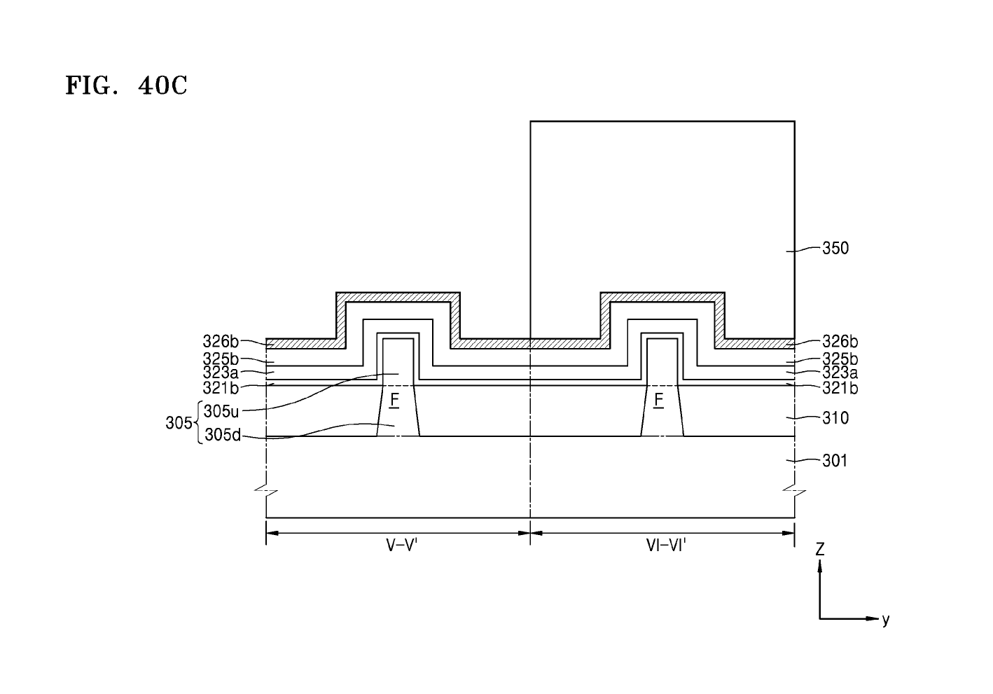

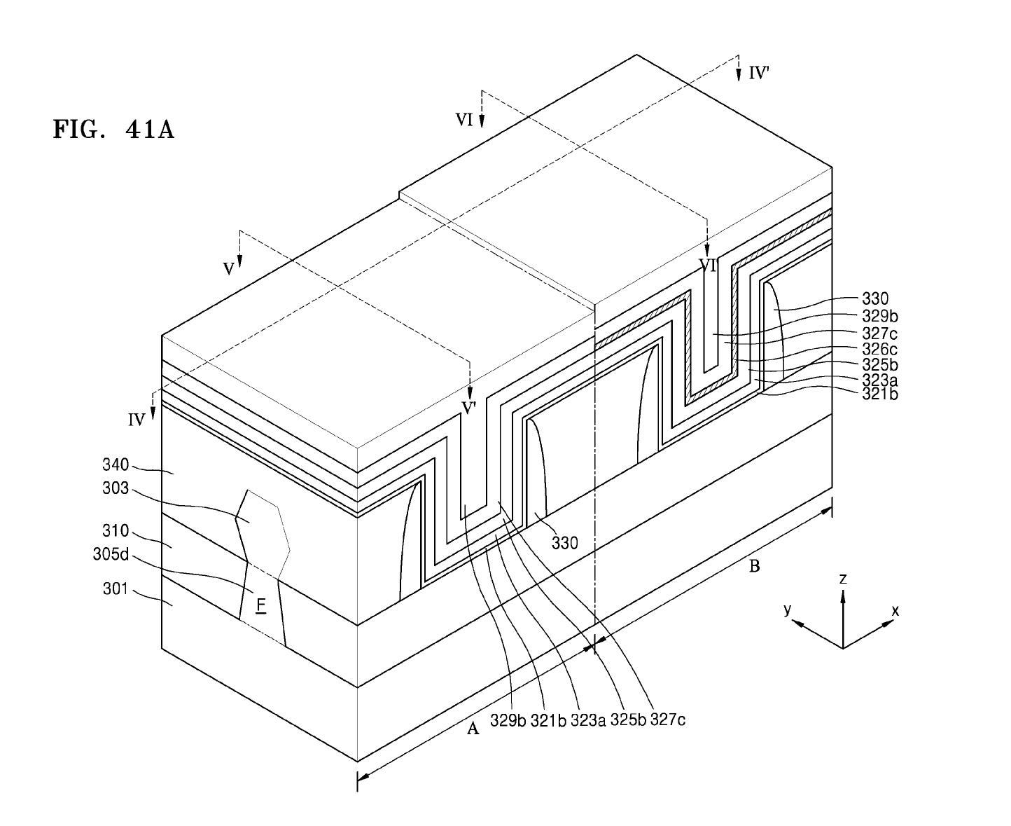

Referring to FIGS. 40A to 40C, a dielectric layer 326b may be conformally formed on the resultant structure formed on the semiconductor substrate 301. The dielectric layer 326b may be formed using various deposition methods, such as, for example, an ALD process, a CVD process, or a PVD process. A material or thickness of the dielectric layer 326b may be the same as in the semiconductor device 100, as disclosed and described in connection with FIG. 1.

After the dielectric layer 326b is formed, a mask pattern 350 may be formed to cover the dielectric layer 326b formed in the second region B. The mask pattern 350 may be formed using a photolithography process. The mask pattern 350 may be formed of a material having an etch selectivity with respect to the dielectric layer 326b and may include a single layer or a multilayer structure. A detailed method of forming the mask pattern 350 may be the same as that disclosed and described in connection with FIG. 32E. Alternatively, after the dielectric layer 326b is formed, if the remaining gap is excessively wide, a sacrificial layer may be further formed on the dielectric layer 326b before the mask pattern 350 is formed. In this case, as described above, an etching process may be performed twice to subsequently remove the dielectric layer 326b from the first region A.

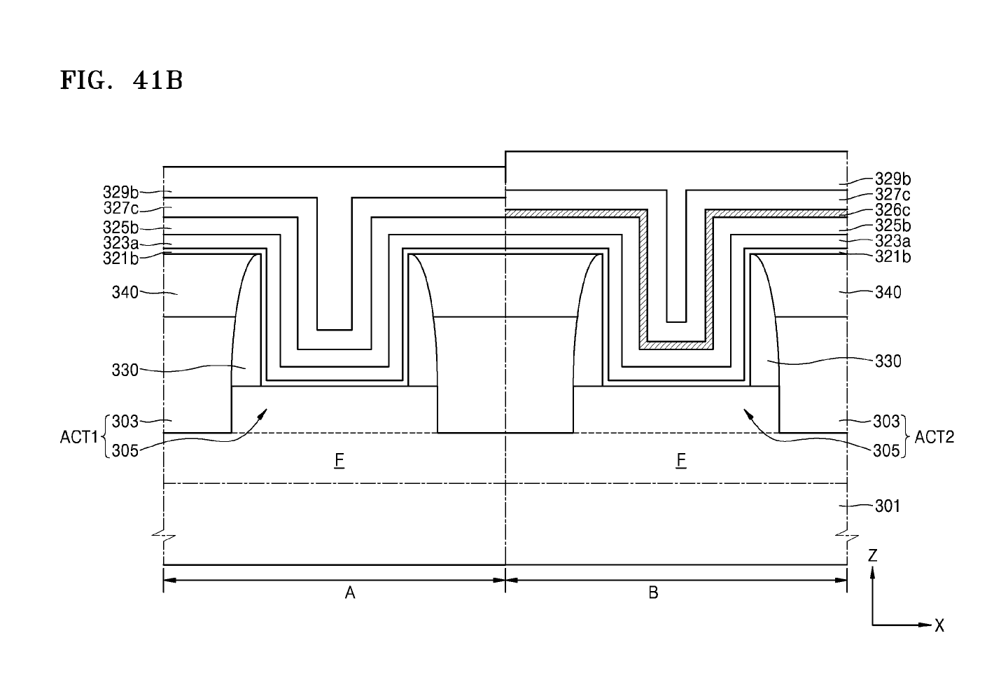

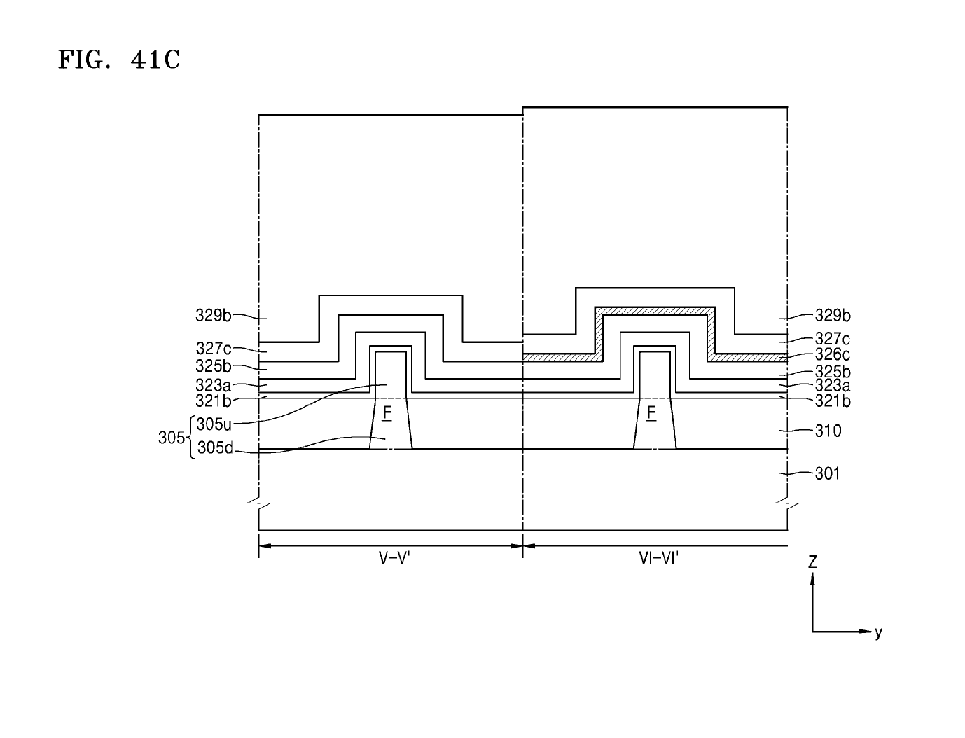

Referring to FIGS. 41A to 41C, after the mask pattern 350 is formed, the dielectric layer 326b of the first region A may be removed by performing an etching process using the mask pattern 350 as an etch mask. The process of removing the dielectric layer 326b of the first region A and the effects of the removal process may be the same as that disclosed and described with reference to FIG. 32F.

When a dielectric layer 326c is maintained only in the second region B, a work function metal layer 327c and a gap-fill metal layer 329b may be sequentially formed on the resultant structure formed on the semiconductor substrate 301. Since the dielectric layer 326c is further formed in the second region B, as shown, top surfaces of the work function metal layer 327c and the gap-fill metal layer 329b in the second region B may be at higher levels than the work function metal layer 327c and the gap-fill metal layer 329b in the first region A. Materials of the work function metal layer 327c and the gap-fill metal layer 329b may be the same as in the semiconductor device 100, as disclosed and described in connection with FIG. 1.

After the work function metal layer 327c and the gap-fill metal layer 329b are formed, a planarization process may be performed. The planarization process may be formed using, for example, a CMP process, and material layers formed on the interlayer insulating layer 340 may be removed to expose a top surface of the interlayer insulating layer 340. Thus, the material layers formed on the interlayer insulating layer 340 may be removed due to the planarization process so that gate structures may be electrically isolated from one another. Thus, a first gate structure 320a and a second gate structure 320b may be formed like in the semiconductor device 300 of FIGS. 14 to 15B.

After the first and second gate structures 320a and 320b are formed, a subsequent semiconductor process may be performed. The subsequent semiconductor process may be the same as described with reference to FIG. 32G.

While the disclosed concepts have been particularly shown and described with reference to exemplary embodiments thereof, it will be understood that various changes in form and details may be made therein without departing from the spirit and scope of the following claims.

1. A semiconductor device comprising:
a semiconductor substrate including a first region and a second region;
a first active region formed in an upper portion of the first region of the semiconductor substrate;
a second active region formed in an upper portion of the second region of the semiconductor substrate;
a first gate structure on the semiconductor substrate extending across the first active region, the first gate structure comprising a high-k dielectric layer, a capping metal layer on the high-k dielectric layer, and a work function metal layer on the capping metal layer; and
a second gate structure on the semiconductor substrate extending across the second active region, the second gate structure comprising the high-k dielectric layer, the capping metal layer on the high-k dielectric layer, a dielectric layer, and the work function metal layer on the dielectric layer,
wherein the first gate structure does not include the dielectric layer interposed between the high-k dielectric layer and the work function metal layer.

2. The semiconductor device of claim 1, wherein the dielectric layer of the second gate structure is formed of a material that inhibits migration of electrons between the capping metal layer of the second gate structure and the work function metal layer of the second gate structure.

3. (canceled)

4. The semiconductor device of claim 1, wherein the dielectric layer of the second gate structure is formed to have a thickness that inhibits migration of electrons between the capping metal layer of the second gate structure and the work function metal layer of the second gate structure and minimizes a resistance of the second gate structure.

5. The semiconductor device of claim 1, wherein the dielectric layer of the second gate structure has a thickness of 2 nm or less.

6. The semiconductor device of claim 1, wherein the dielectric layer extends over topmost portions of the capping metal layer.

7. The semiconductor device of claim 1, wherein the capping metal layer of the second gate structure has a thickness of 3 nm or less.

8. The semiconductor device of claim 1, wherein the capping metal layer of the second gate structure is formed of a material having a larger work function than the work function metal layer of the second gate structure.

9. The semiconductor device of claim 1, wherein the capping metal layer includes at least one of a metal nitride, a metal carbide, a metal silicide, a metal silicon nitride, and a metal silicon carbide, which contains at least one of titanium (Ti) and tantalum (Ta).

10. The semiconductor device of claim 1, wherein the work function metal layer comprises a combination of:
an aluminum (Al) compound containing titanium and/or tantalum, and
at least one of Mo, Pd, Ru, Pt, TiN, WN, TaN, Ir, TaC, RuN, and MoN.

11. The semiconductor device of claim 10, further comprising:
a third gate structure comprising the high-k dielectric layer, the capping metal layer on the high-k dielectric layer, and the work function metal layer on the capping metal layer, wherein the first gate structure does not include the dielectric layer interposed between the high-k dielectric layer and the work function metal layer; and
a fourth gate structure comprising the high-k dielectric layer, the capping metal layer on the high-k dielectric layer, the dielectric layer on the capping metal layer, and the work function metal layer on the dielectric layer,
wherein the first and third gate structures and/or the second and fourth gate structures are parts of transistors having two different threshold voltages.

12. The semiconductor device of claim 1, wherein the work function metal layers of the first gate structure and the second gate structure comprise one of the following:
respective portions of first and second NMOS transistor gate electrodes, and
respective portions of first and second PMOS transistor gate electrodes.

13. The semiconductor device of claim 1, wherein at least one of the first gate structure and the second gate structure comprises a work function metal layer comprising an aluminum (Al) compound containing titanium and/or tantalum, and a barrier metal comprising at least one of Mo, Pd, Ru, Pt, TiN, WN, TaN, Ir, TaC, RuN, and MoN.

14. The semiconductor device of claim 1, wherein each of the first active region and second active region has a fin shape protruding from the semiconductor substrate,
wherein the first gate structure covers a top surface and side surfaces of a portion of the first active region, and
wherein the second gate structure covers a top surface and side surfaces of a portion of the second active region.

15. A semiconductor device comprising:
a semiconductor substrate including a first region and a second region;
at least one fin protruding on the semiconductor substrate and extending in a first direction;
a first gate structure formed in the first region of the semiconductor substrate and extending in a second direction to cover top and side surfaces of the at least one fin, the first gate structure comprising a high-k dielectric layer, a capping metal layer on the high-k dielectric layer, and a work function metal layer on the capping metal layer; and
a second gate structure formed in the second region of the semiconductor substrate and extending in the second direction to cover the top and side surfaces of the at least one fin, the second gate structure comprising the high-k dielectric layer, the capping metal layer on the high-k dielectric layer, a dielectric layer on the capping metal layer, and the work function metal layer on the dielectric layer,
wherein the first gate structure does not include the dielectric layer interposed between the high-k dielectric layer and the work function metal layer.

16. The semiconductor device of claim 15, wherein the dielectric layer of the second gate structure is formed of a material that inhibits migration of electrons between the capping metal layer of the second gate structure and the work function metal layer of the second gate structure or reduces a variation in work function of the work function metal layer of the second gate structure caused by the capping metal layer.

17. The semiconductor device of claim 15, wherein the dielectric layer of the second gate structure is formed to have a thickness that minimizes a resistance of the second gate structure.

18. The semiconductor device of claim 15, wherein the dielectric layer of the second gate structure has a bandgap that inhibits migration of electrons between the capping metal layer of the second gate structure and the work function metal layer of the second gate structure.

19. The semiconductor device of claim 15, wherein the dielectric layer extends over topmost portions of the capping metal layer of the second gate structure, and
wherein each of the work function metal layer and a gap-fill metal layer formed on the capping metal layer of the second gate structure includes a stepped portion.

20. The semiconductor device of claim 15, wherein the capping metal layer of the second gate structure has a larger work function than the work function metal layer and includes any one of a metal nitride, a metal carbide, a metal silicide, a metal silicon nitride, and a metal silicon carbide, which contains at least one of titanium and tantalum.

21. The semiconductor device of claim 15, further comprising:
a third gate structure comprising the high-k dielectric layer, the capping metal layer on the high-k dielectric layer, and the work function metal layer on the capping metal layer, wherein the first gate structure does not include the dielectric layer interposed between the high-k dielectric layer and the work function metal layer; and
a fourth gate structure comprising the high-k dielectric layer, the capping metal layer on the high-k dielectric layer, the dielectric layer on the capping metal layer, and the work function metal layer on the dielectric layer,
wherein the first and third gate structures and/or the second and fourth gate structures are parts of transistors having two different threshold voltages.

22.-41. (canceled)
